(19) United States
(12) Patent Application Publication
(10) Pub. No.: US 2017/0166599 A1
(43) Pub. Date: Jun. 15, 2017

(54) METAL COMPLEX AND LIGHT EMITTING DEVICE USING THE SAME

(71) Applicant: Sumitomo Chemical Company, Limited, Tokyo (JP)

(72) Inventors: Taichi ABE, Tsukuba-shi, Ibaraki (JP); Kohei ASADA, Tsukuba-shi, Ibaraki (JP); Kazuei OHUCHI, Tsukuba-shi, Ibaraki (JP)

(73) Assignee: Sumitomo Chemical Company, Limited, Tokyo (JP)

(21) Appl. No.: 15/324,450

(22) PCT Filed: Jul. 2, 2015
(86) PCT No.: PCT/JP2015/069108

§ 371 Date: Jan. 6, 2017

(30) Foreign Application Priority Data
Jul. 8, 2014 (JP) 2014-140241

(51) Int. Cl. C07F 15/00; H01L 51/00; C09K 11/06

(52) U.S. Cl. CPC C07F 15/0033; C09K 11/06; H01L 51/0085; C09K 2211/185; H01L 51/5056

(57) ABSTRACT

Provided is a metal complex excellent in light emission stability. The metal complex is represented by the formula (1):

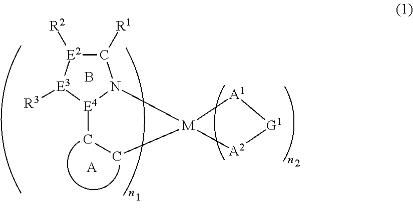

wherein M represents an iridium atom or the like, n₁ represents an integer of 1 to 3, n₂ represents an integer of 0 to 2, E² to E⁴ represent a nitrogen atom or a carbon atom where two selected from among E² to E⁴ are nitrogen atoms and the remaining one is a carbon atom, R¹ represents an aryl group or the like, R² and R³ represent a hydrogen atom, an alkyl group, an aryl group or the like, the ring B represents a triazole ring, the ring A represents an aromatic hydrocarbon ring or the like, and A¹-G¹-A² represents an anionic bidentate ligand.

### TECHNICAL FIELD

The present invention relates to a metal complex, a composition comprising the metal complex, and a light emitting device produced by using the metal complex.

### BACKGROUND ART

As a light emitting material used in a light emitting layer of a light emitting device, a phosphorescent compound showing light emission from the triplet excited state, and the like, are under study. For example, Patent document 1 discloses metal complex A represented by the following formula. Patent document 2 discloses metal complex B and metal complex C represented by the following formulae. These metal complexes are metal complexes the ligand of which has a phenyltriazole structure.

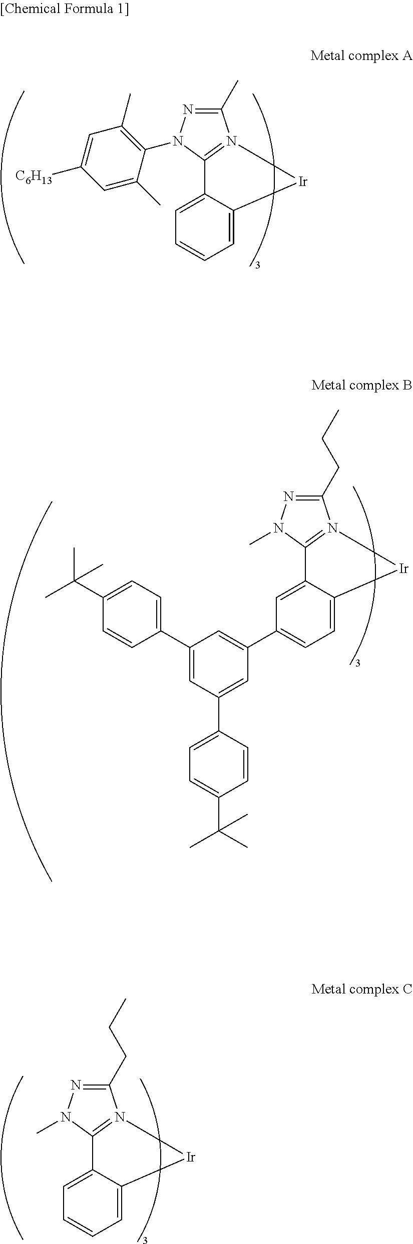

### PRIOR ART DOCUMENT

### Patent Document

[Patent document 1] US Patent Application Publication No. 2014/0151659

[Patent document 2] JP-A No. 2013-147551

### SUMMARY OF THE INVENTION

### Problem to be Solved by the Invention

However, the above-described metal complexes had no sufficient light emission stability.

Then, the present invention has an object of providing a metal complex excellent in light emission stability. Further, the present invention has an object of providing a composition comprising the metal complex and a light emitting device produced by using the metal complex.

In this specification, “a metal complex excellent in light emission stability” means that when a metal complex is excited continuously under certain excitation conditions, the luminance of light emission from the triplet excited state of the metal complex is less likely to low. The method for exciting a metal complex may be any of photoexcitation and current excitation.

### Means for Solving the Problem

[1] A metal complex represented by the following formula (1):

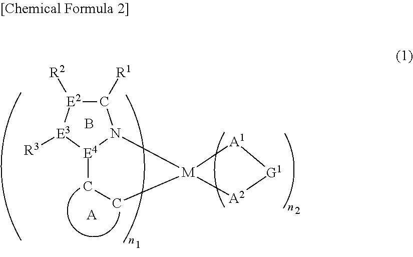

[wherein,

M represents an iridium atom or a platinum atom.

n₁ represents 1, 2 or 3. n₂ represents 0, 1 or 2. n₁+n₂ is 3 when M is an iridium atom, while n₁+n₂ is 2 when M is a platinum atom.

E², E³ and E⁴ each independently represent a nitrogen atom or a carbon atom. When a plurality of E², E³ and E⁴ are present, they may be the same or different at each occurrence. R² and R³ may be either present or not present when E² and E³ are nitrogen atoms. Two selected from the group consisting of E², E³ and E⁴ are nitrogen atoms, and the remaining one is a carbon atom.

R¹ represents an aryl group or a monovalent heterocyclic group, and these groups each optionally have a substituent. When a plurality of R¹ are present, they may be the same or different.

R² and R³ each independently represent a hydrogen atom, an alkyl group, a cycloalkyl group, an alkoxy group, a cycloalkoxy group, an aryl group, an aryloxy group, a monovalent heterocyclic group or a halogen atom, and these groups each optionally have a substituent. When a plurality of R² and R³ are present, they may be the same or different at each occurrence.

The ring B represents a triazole ring.

The ring A represents an aromatic hydrocarbon ring or an aromatic heterocyclic ring, and these rings each optionally have a substituent.

A¹-G¹-A² represents an anionic bidentate ligand. A¹ and A² each independently represent a carbon atom, an oxygen atom or a nitrogen atom, and these atoms each may be an atom constituting a ring. G¹ represents a single bond or an atomic group constituting the bidentate ligand together with A¹ and A². When a plurality of A¹-G¹-A² are present, they may be the same or different.].

[2] The metal complex according to [1] represented by the following formula (1-a):

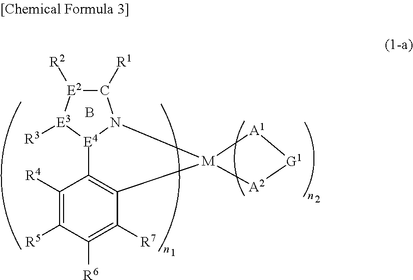

[wherein,

M, n₁, n₂, E², E³, E⁴, R¹, R², R³, the ring B and A¹-G¹-A² represent the same meaning as described above.

R⁴, R⁵, R⁶ and R⁷ each independently represent a hydrogen atom, an alkyl group, a cycloalkyl group, an alkoxy group, a cycloalkoxy group, an aryl group, an aryloxy group, a monovalent heterocyclic group or a halogen atom, and these groups each optionally have a substituent. When a plurality of R⁴, R⁵, R⁶ and R⁷ are present, they may be the same or different at each occurrence. R⁴ and R⁵ may be combined together to form a ring together with the carbon atoms to which they are attached, R⁵ and R⁶ may be combined together to form a ring together with the carbon atoms to which they are attached, and R⁶ and R⁷ may be combined together to form a ring together with the carbon atoms to which they are attached.].

[3] The metal complex according to [2] represented by the following formula (1-b):

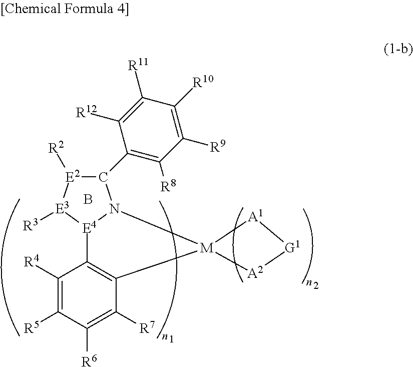

[wherein,

M, n₁, n₂, E², E³, E⁴, R², R³, R⁴, R⁵, R⁶, R⁷, the ring B and A¹-G¹-A² represent the same meaning as described above.

R⁸, R⁹, R¹⁰, R¹¹ and R¹² each independently represent a hydrogen atom, an alkyl group, a cycloalkyl group, an alkoxy group, a cycloalkoxy group, an aryl group, an aryloxy group, a monovalent heterocyclic group or a halogen atom, and these groups each optionally have a substituent. When a plurality of R⁸, R⁹, R¹⁰, R¹¹ and R¹² are present, they may be the same or different at each occurrence. R⁶ and R⁹ may be combined together to form a ring together with the carbon atoms to which they are attached, R⁹ and R¹⁰ may be combined together to form a ring together with the carbon atoms to which they are attached, R¹⁰ and R¹¹ may be combined together to form a ring together with the carbon atoms to which they are attached, and R¹¹ and R¹² may be combined together to form a ring together with the carbon atoms to which they are attached.].

[4] The metal complex according to [3] represented by the following formula (1-c):

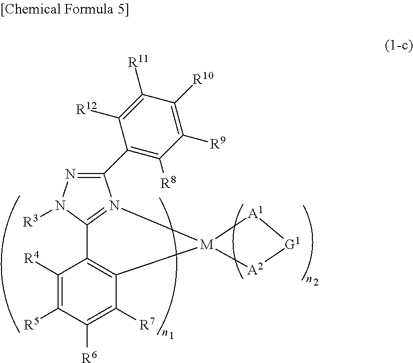

[wherein, M, n₁, n₂, R³, R⁴, R⁵, R⁶, R⁷, R⁸, R⁹, R¹⁰, R¹¹, R¹² and A¹-G¹-A² represent the same meaning as described above.].

[5] The metal complex according to [3] represented by the following formula (1-d):

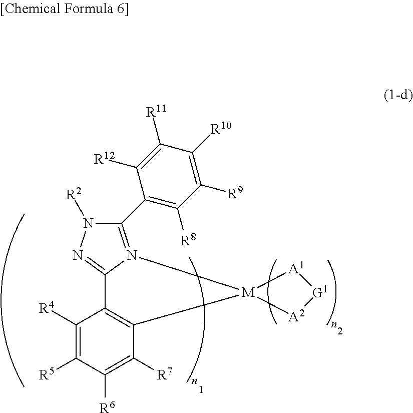

[wherein, M, n₁, n₂, R², R⁴, R⁵, R⁶, R⁷, R⁸, R⁹, R¹⁰, R¹¹, R¹² and A¹-G¹-A² represent the same meaning as described above.].

[6] The metal complex according to [4] represented by the following formula (1-e):

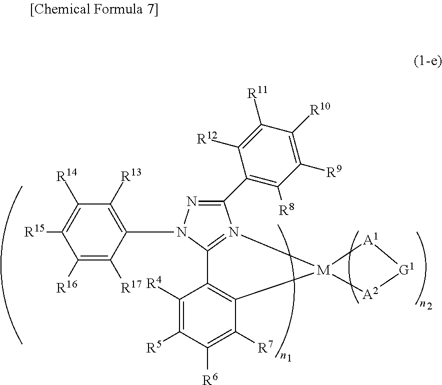

[wherein,

M, n₁, n₂, R⁴, R⁵, R⁶, R⁷, R⁸, R⁹, R¹⁰, R¹¹, R¹² and A¹-G¹-A² represent the same meaning as described above.

R¹³, R¹⁴, R¹⁵, R¹⁶ and R¹⁷ each independently represent a hydrogen atom, an alkyl group, a cycloalkyl group, an alkoxy group, a cycloalkoxy group, an aryl group, an aryloxy group, a monovalent heterocyclic group or a halogen atom, and these groups each optionally have a substituent. When a plurality of R¹³, R¹⁴, R¹⁵, R¹⁶ and R¹⁷ are present, they may be the same or different at each occurrence. R¹³ and R¹⁴ may be combined together to form a ring together with the carbon atoms to which they are attached, R¹⁴ and R¹⁵ s may be combined together to form a ring together with the carbon atoms to which they are attached, R¹⁵ and R¹⁶ may be combined together to form a ring together with the carbon atoms to which they are attached, and R¹⁶ and R¹⁷ may be combined together to form a ring together with the carbon atoms to which they are attached.].

[7] The metal complex according to any one of [3] to [6], wherein R⁹ and R¹¹ represent an alkyl group or an aryl group.

[8] The metal complex according to any one of [1] to [6], wherein at least one selected from the group consisting of R¹, R², R³, R⁵, R⁶, R¹⁰ and R¹⁵ is a dendron.

[9] The metal complex according to [8], wherein at least one selected from the group consisting of R¹, R², R³, R⁵, R⁶, R¹⁰ and R¹⁵ is a group represented by the following formula (D-A) or (D-B):

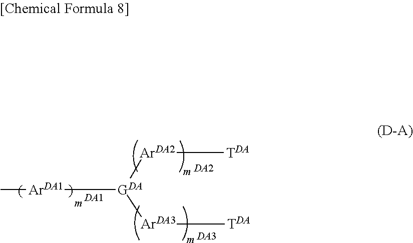

[wherein,
m^{DA1}, m^{DA2} and m^{DA3} each independently represent an integer of 0 or more.

G^{DA} represents an aromatic hydrocarbon group or a heterocyclic group, and these groups each optionally have a substituent.

Ar^{DA1}, Ar^{DA2} and Ar^{DA3} each independently represent an arylene group or a divalent heterocyclic group, and these groups each optionally have a substituent. When a plurality of Ar^{DA1}, Ar^{DA2} and Ar^{DA3} are present, they may be the same or different at each occurrence.

T^{DA} represents an aryl group or a monovalent heterocyclic group, and these groups each optionally have a substituent. The plurality of T^{DA} may be the same or different.]

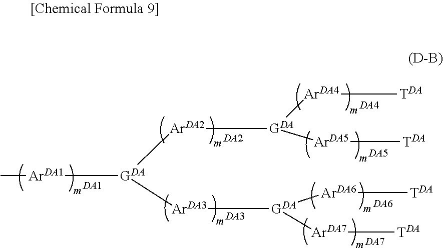

[wherein,

m^{DA1}, m^{DA2}, m^{DA3}, m^{DA4}, m^{DA5}, m^{DA6} and m^{DA7} each independently represent an integer of 0 or more.

G^{DA} represents an aromatic hydrocarbon group or a heterocyclic group, and these groups each optionally have a substituent. The plurality of G^{DA} may be the same or different.

Ar^{DA1}, Ar^{DA2}, Ar^{DA3}, Ar^{DA4}, Ar^{DA5}, Ar^{DA6} and Ar^{DA7} each independently represent an arylene group or a divalent heterocyclic group, and these groups each optionally have a substituent. When a plurality of Ar^{DA1}, Ar^{DA2}, Ar^{DA3}, Ar^{DA4}, Ar^{DA5}, Ar^{DA6} and Ar^{DA7} are present, they may be the same or different at each occurrence.

T^{DA} represents an aryl group or a monovalent heterocyclic group, and these groups each optionally have a substituent. The plurality of T^{DA} may be the same or different.].

[10] The metal complex according to [9], wherein the group represented by the formula (D-A) is a group represented by the following formula (D-A1), (D-A2) or (D-A3):

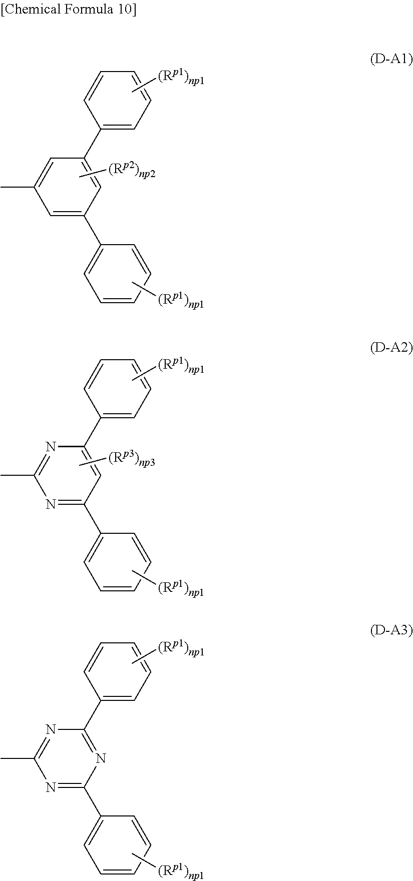

[wherein,

R^{p1}, R^{p2} and R^{p3} each independently represent an alkyl group, a cycloalkyl group or a halogen atom. When a plurality of R^{p1} and R^{p2} are present, they may be the same or different at each occurrence. At least one selected from among a plurality of R^{p1} is an alkyl group having 4 or more carbon atoms.

np1 represents an integer of 1 to 5, np2 represents an integer of 0 to 3, and np3 represents 0 or 1. The plurality of np1 may be the same or different.].

[11] The metal complex according to [10], wherein the group represented by the formula (D-A) is a group represented by the formula (D-A1).

[12] The metal complex according to any one of [1] to [11], wherein M is an iridium atom.

[13] The metal complex according to [12], wherein n₁ is 3.

[14] A composition comprising the metal complex according to any one of [1] to [13] and a compound represented by the following formula (H-1):

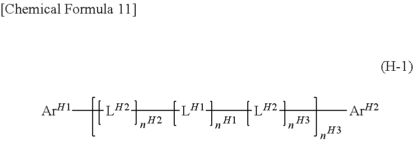

[wherein,

Ar^{H1} and Ar^{H2} each independently represent an aryl group or a monovalent heterocyclic group, and these groups each optionally have a substituent.

n^{H1} and n^{H2} each independently represent 0 or 1. When a plurality of n^{H1} are present, they may be the same or different. The plurality of n^{H2} may be the same or different.

n^{H3} represents an integer of 0 or more.

L^{H1} represents an arylene group, a divalent heterocyclic group or a group represented by —[C(R^{H11})₂]n^{H11}-, and these groups each optionally have a substituent. When a plurality of L^{H1} are present, they may be the same or different.

n^{H11} represents an integer of 1 to 10. R^{H11} represents a hydrogen atom, an alkyl group, a cycloalkyl group, an alkoxy group, a cycloalkoxy group, an aryl group or a monovalent heterocyclic group, and these groups each optionally have a substituent. The plurality of R^{H11} may be the same or different and may be combined together to form a ring together with the carbon atoms to which they are attached.

L^{H2} represents a group represented by —N(-L^{H21}-R^{H21})—. When a plurality of L^{H2} are present, they may be the same or different.

L^{H21} represents a single bond, an arylene group or a divalent heterocyclic group, and these groups each optionally have a substituent. R^{H21} represents a hydrogen atom, an alkyl group, a cycloalkyl group, an aryl group or a monovalent heterocyclic group, and these groups each optionally has a substituent.].

[15] A composition comprising the metal complex according to any one of [1] to [13] and a polymer compound comprising a constitutional unit represented by the following formula (Y):

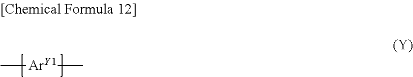

[in the formula (Y), Ar^{Y1} represents an arylene group, a divalent heterocyclic group or a divalent group in which at least one arylene group and at least one divalent heterocyclic group are bonded directly, and these groups each optionally have a substituent.].
[16] A composition comprising the metal complex according to any one of [1] to [13] and at least one material selected from the group consisting of a hole transporting material, a hole injection material, an electron transporting material, an electron injection material, a light emitting material, an antioxidant and a solvent.
[17] A light emitting device produced by using the metal complex according to any one of [1] to [13].

### Effect of the Invention

According to the present invention, a metal complex excellent in light emission stability can be provided. Further, according to the present invention, a composition comprising the metal complex and a light emitting device produced by using the metal complex can be provided. A light emitting device produced by using the metal complex is excellent in luminance life because the metal complex of the present invention is excellent in light emission stability.

### MODES FOR CARRYING OUT THE INVENTION

Suitable embodiments of the present invention will be illustrated in detail below.

### <Explanation of Common Term>

Terms commonly used in the present specification have the following meanings unless otherwise stated.

Me represents a methyl group, Et represents an ethyl group, Bu represents a butyl group, i-Pr represents an isopropyl group, and t-Bu represents a tert-butyl group.

A hydrogen atom may be a heavy hydrogen atom or a light hydrogen atom.

A solid line representing a bond to a central metal in a formula representing a metal complex denotes a covalent bond or a coordinate bond.

“Polymer compound” denotes a polymer having molecular weight distribution and having a polystyrene-equivalent number average molecular weight of 1×10³ to 1×10⁸.

A polymer compound may be any of a block copolymer, a random copolymer, an alternating copolymer and a graft copolymer, and may also be another embodiment.

An end group of a polymer compound is preferably a stable group because if a polymerization active group remains intact at the end, when the polymer compound is used for fabrication of a light emitting device, the light emitting property or luminance life possibly becomes lower. This end group is preferably a group having a conjugated bond to the main chain, and includes, for example, groups bonding to an aryl group or a monovalent heterocyclic group via a carbon-carbon bond.

“Low molecular weight compound” denotes a compound having no molecular weight distribution and having a molecular weight of 1×10′ or less.

“Constitutional unit” denotes a unit structure found once or more in a polymer compound.

“Alkyl group” may be any of linear or branched. The number of carbon atoms of the linear alkyl group is, not including the number of carbon atoms of a substituent, usually 1 to 50, preferably 3 to 30, more preferably 4 to 20. The number of carbon atoms of the branched alkyl groups is, not including the number of carbon atoms of a substituent, usually 3 to 50, preferably 3 to 30, more preferably 4 to 20.

The alkyl group optionally has a substituent, and examples thereof include a methyl group, an ethyl group, a propyl group, an isopropyl group, a butyl group, an isobutyl group, a tert-butyl group, a pentyl group, an isoamyl group, a 2-ethylbutyl group, a hexyl group, a heptyl group, an octyl group, a 2-ethylhexyl group, a 3-propylheptyl group, a decyl group, a 3,7-dimethyloctyl group, a 2-ethyloctyl group, a 2-hexyldecyl group and a dodecyl group, and groups obtained by substituting a hydrogen atom in these groups with a cycloalkyl group, an alkoxy group, a cycloalkoxy group, an aryl group, a fluorine atom or the like, and the alkyl group having a substituent includes a trifluoromethyl group, a pentafluoroethyl group, a perfluorobutyl group, a perfluorohexyl group, a perfluorooctyl group, a 3-phenylpropyl group, a 3-(4-methylphenyl)propyl group, a 3-(3,5-di-hexylphenyl) propyl group and a 6-ethyloxyhexyl group.

The number of carbon atoms of “Cycloalkyl group” is, not including the number of carbon atoms of a substituent, usually 3 to 50, preferably 3 to 30, more preferably 4 to 20.

The cycloalkyl group optionally has a substituent, and examples thereof include a cyclohexyl group, a cyclohexylmethyl group and a cyclohexylethyl group.

“Aryl group” denotes an atomic group remaining after removing from an aromatic hydrocarbon one hydrogen atom linked directly to a carbon atom constituting the ring. The number of carbon atoms of the aryl group is, not including the number of carbon atoms of a substituent, usually 6 to 60, preferably 6 to 20, more preferably 6 to 10.

The aryl group optionally has a substituent, and examples thereof include a phenyl group, a 1-naphthyl group, a 2-naphthyl group, a 1-anthracenyl group, a 2-anthracenyl group, a 9-anthracenyl group, a 1-pyrenyl group, a 2-pyrenyl group, a 4-pyrenyl group, a 2-fluorenyl group, a 3-fluorenyl group, a 4-fluorenyl group, a 2-phenylphenyl group, a 3-phenylphenyl group, a 4-phenylphenyl group, and groups obtained by substituting a hydrogen atom in these groups with an alkyl group, a cycloalkyl group, an alkoxy group, a cycloalkoxy group, an aryl group, a fluorine atom or the like.

“Alkoxy group” may be any of linear or branched. The number of carbon atoms of the linear alkoxy group is, not including the number of carbon atoms of a substituent, usually 1 to 40, preferably 4 to 10. The number of carbon atoms of the branched alkoxy group is, not including the number of carbon atoms of a substituent, usually 3 to 40, preferably 4 to 10.

The alkoxy group optionally has a substituent, and examples thereof include a methoxy group, an ethoxy group, a propyloxy group, an isopropyloxy group, a butyloxy group, an isobutyloxy group, a tert-butyloxy group, a pentyloxy group, a hexyloxy group, a heptyloxy group, an octyloxy group, a 2-ethylhexyloxy group, a nonyloxy group, a decyloxy group, a 3,7-dimethyloctyloxy group and a lauryloxy group, and groups obtained by substituting a hydrogen atom in these groups with a cycloalkyl group, an alkoxy group, a cycloalkoxy group, an aryl group, a fluorine atom or the like.

The number of carbon atoms of “Cycloalkoxy group” is, not including the number of carbon atoms of a substituent, usually 3 to 40, preferably 4 to 10.

The cycloalkoxy group optionally has a substituent, and examples thereof include a cyclohexyloxy group.

The number of carbon atoms of “Aryloxy group” is, not including the number of carbon atoms of a substituent, usually 6 to 60, preferably 7 to 48.

The aryloxy group optionally has a substituent, and examples thereof include a phenoxy group, a 1-naphthyloxy group, a 2-naphthyloxy group, a 1-anthracenyloxy group, a 9-anthracenyloxy group, a 1-pyrenyloxy group, and groups obtained by substituting a hydrogen atom in these groups with an alkyl group, a cycloalkyl group, an alkoxy group, a cycloalkoxy group, a fluorine atom or the like.

“p-Valent heterocyclic group” (p represents an integer of 1 or more) denotes an atomic group remaining after removing from a heterocyclic compound p hydrogen atoms among hydrogen atoms directly linked to a carbon atom or a hetero atom constituting the ring. Of p-valent heterocyclic groups, “p-valent aromatic heterocyclic groups” as an atomic group remaining after removing from an aromatic heterocyclic compound p hydrogen atoms among hydrogen atoms directly linked to a carbon atom or a hetero atom constituting the ring are preferable.

“Aromatic heterocyclic compound” denotes a compound in which the heterocyclic ring itself shows aromaticity such as oxadiazole, thiadiazole, thiazole, oxazole, thiophene, pyrrole, phosphole, furan, pyridine, pyrazine, pyrimidine, triazine, pyridazine, quinoline, isoquinoline, carbazole and dibenzophosphole, and a compound in which an aromatic ring is condensed to the heterocyclic ring even if the heterocyclic ring itself shows no aromaticity such as phenoxazine, phenothiazine, dibenzoborole, dibenzosilole and benzopyran.

The number of carbon atoms of the monovalent heterocyclic group is, not including the number of carbon atoms of a substituent, usually 2 to 60, preferably 4 to 20.

The monovalent heterocyclic group optionally has a substituent, and examples thereof include a thienyl group, a pyrrolyl group, a furyl group, a pyridyl group, a piperidyl group, a quinolinyl group, an isoquinolinyl group, a pyrimidinyl group, a triazinyl group, and groups obtained by substituting a hydrogen atom in these groups with an alkyl group, a cycloalkyl group, an alkoxy group, a cycloalkoxy group or the like.

“Halogen atom” denotes a fluorine atom, a chlorine atom, a bromine atom or an iodine atom.

“Amino group” optionally has a substituent, and a substituted amino group is preferable. The substituent which an amino group has is preferably an alkyl group, a cycloalkyl group, an aryl group or a monovalent heterocyclic group.

The substituted amino group includes, for example, a dialkylamino group, a dicycloalkylamino group and a diarylamino group.

The amino group includes, for example, a dimethylamino group, a diethylamino group, a diphenylamino group, a bis(4-methylphenyl)amino group, a bis(4-tert-butylphenyl)amino group and a bis(3,5-di-tert-butylphenyl)amino group.

“Alkenyl group” may be any of linear or branched. The number of carbon atoms of the linear alkenyl group, not including the number of carbon atoms of the substituent, is usually 2 to 30, preferably 3 to 20. The number of carbon atoms of the branched alkenyl group, not including the number of carbon atoms of the substituent, is usually 3 to 30, preferably 4 to 20.

The number of carbon atoms of “Cycloalkenyl group”, not including the number of carbon atoms of the substituent, is usually 3 to 30, preferably 4 to 20.

The alkenyl group and cycloalkenyl group each optionally have a substituent, and examples thereof include a vinyl group, a 1-propenyl group, a 2-propenyl group, a 2-butenyl group, a 3-butenyl group, a 3-pentenyl group, a 4-pentenyl group, a 1-hexenyl group, a 5-hexenyl group, a 7-octenyl group, and these groups having a substituent.

“Alkynyl group” may be any of linear or branched. The number of carbon atoms of the alkynyl group, not including the number of carbon atoms of the substituent, is usually 2 to 20, preferably 3 to 20. The number of carbon atoms of the branched alkynyl group, not including the number of carbon atoms of the substituent, is usually 4 to 30, preferably 4 to 20.

The number of carbon atoms of “Cycloalkynyl group”, not including the number of carbon atoms of the substituent, is usually 4 to 30, preferably 4 to 20.

The alkynyl group and cycloalkynyl group each optionally have a substituent, and examples thereof include an ethynyl group, a 1-propynyl group, a 2-propynyl group, a 2-butynyl group, a 3-butynyl group, a 3-pentynyl group, a 4-pentynyl group, a 1-hexynyl group, a 5-hexynyl group, and these groups having a substituent.

“Arylene group” denotes an atomic group remaining after removing from an aromatic hydrocarbon two hydrogen atoms linked directly to carbon atoms constituting the ring. The number of carbon atoms of the arylene group is, not including the number of carbon atoms of a substituent, usually 6 to 60, preferably 6 to 30, more preferably 6 to 18.

The arylene group optionally has a substituent, and examples thereof include a phenylene group, a naphthalenediyl group, an anthracenediyl group, a phenanthrenediyl group, a dihydrophenanthrenediyl group, a naphthacenediyl group, a fluorenediyl group, a pyrenediyl group, a perylenediyl group, a chrysenediyl group, and these groups having a substituent, preferably, groups represented by the formulae (A-1) to (A-20). The arylene group includes groups obtained by linking a plurality of these groups.

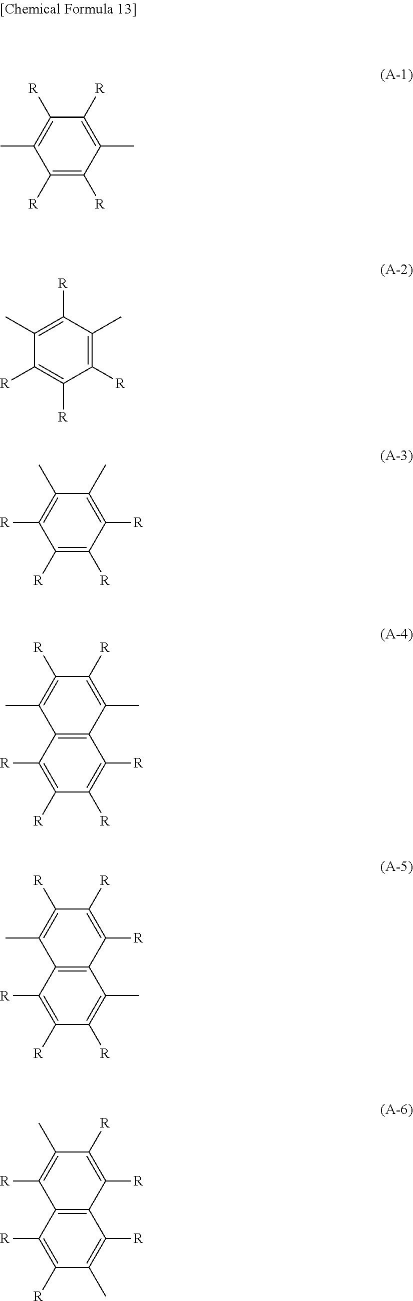

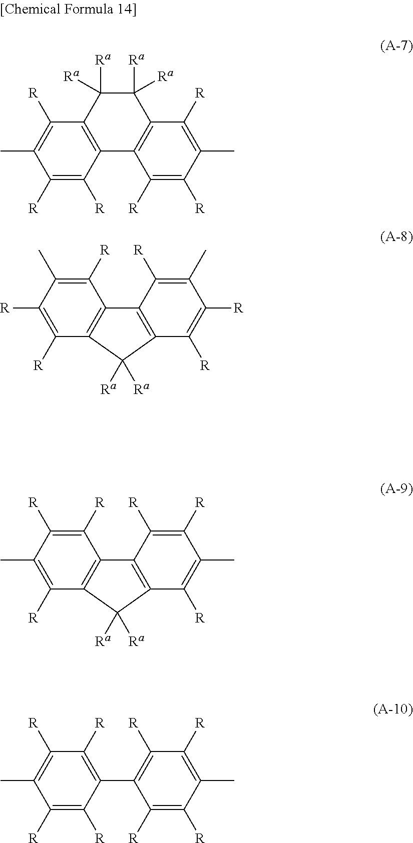

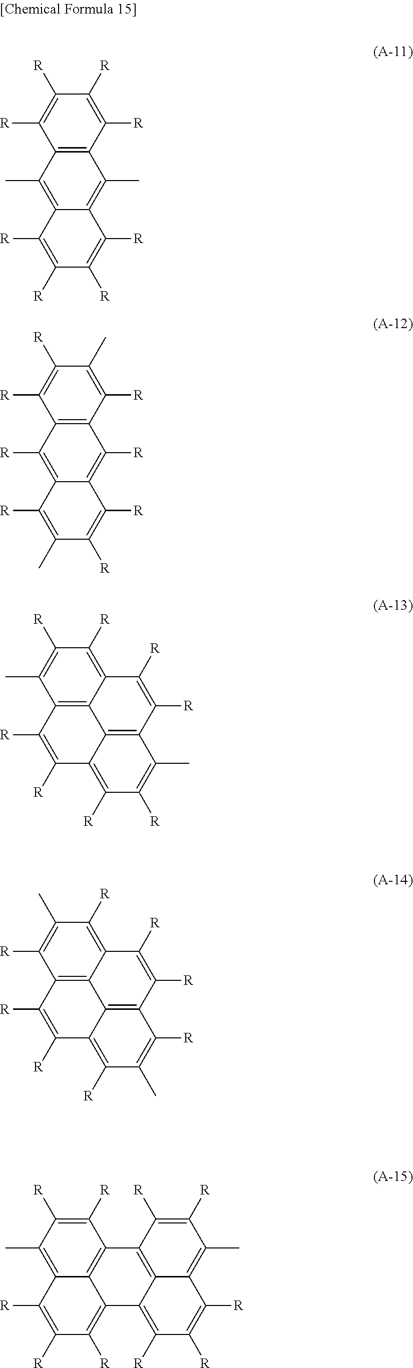

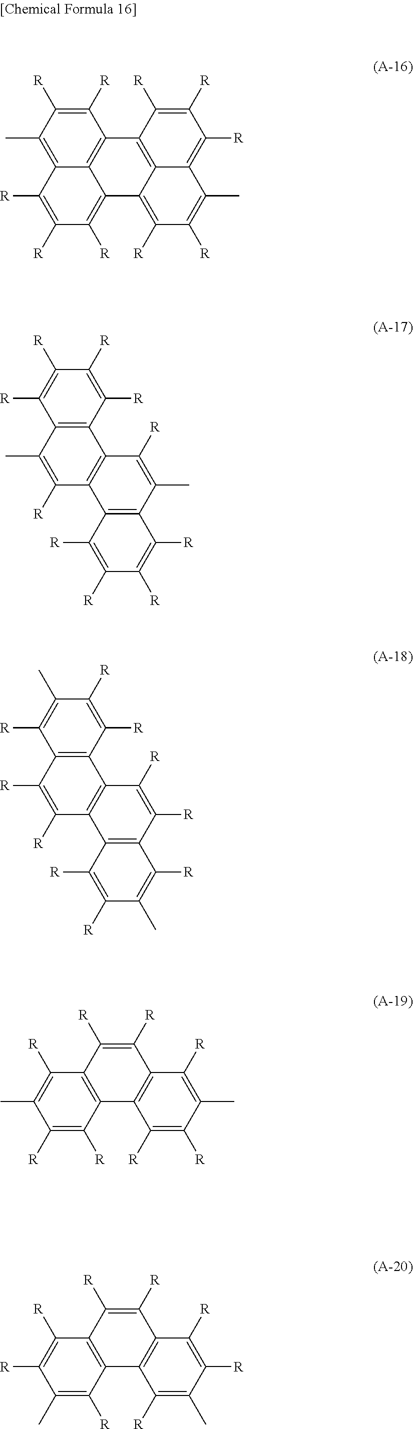

[wherein, R and R^{a} each independently represent a hydrogen atom, an alkyl group, a cycloalkyl group, an aryl group or a monovalent heterocyclic group. The plurality of R and R^{a} each may be the same or different, and groups R^{a} may be combined together to form a ring together with the atoms to which they are attached.]

The number of carbon atoms of the divalent heterocyclic group is, not including the number of carbon atoms of a substituent, usually 2 to 60, preferably 3 to 20, more preferably 4 to 15.

The divalent heterocyclic group optionally has a substituent, and examples thereof include divalent groups obtained by removing from pyridine, diazabenzene, triazine, azanaphthalene, diazanaphthalene, carbazole, dibenzofuran, dibenzothiophene, dibenzosilole, phenoxazine, phenothiazine, acridine, dihydroacridine, furan, thiophene, azole, diazole and triazole two hydrogen atoms among hydrogen atoms linking directly to a carbon atom or a hetero atom constituting the ring, preferably groups represented by the formulae (AA-1) to (AA-34). The divalent heterocyclic group includes groups obtained by linking a plurality of these groups.

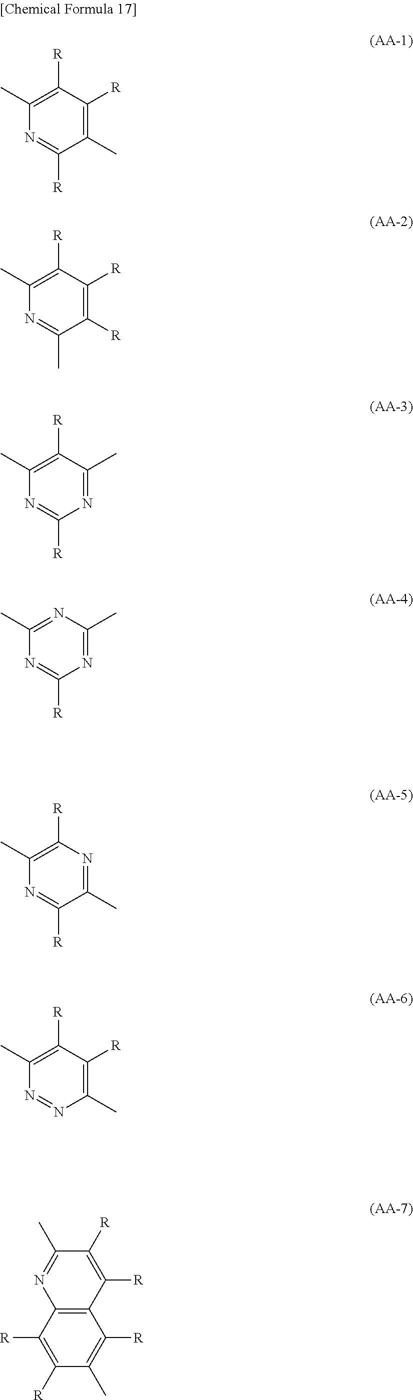

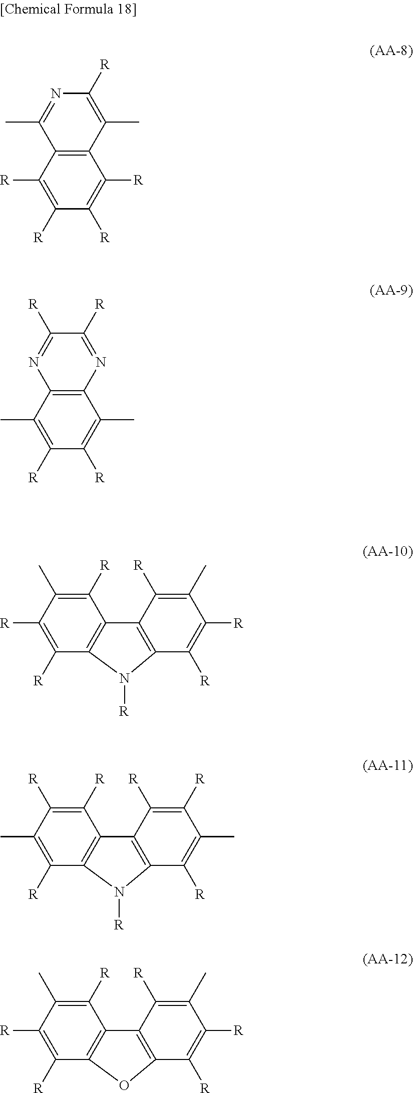

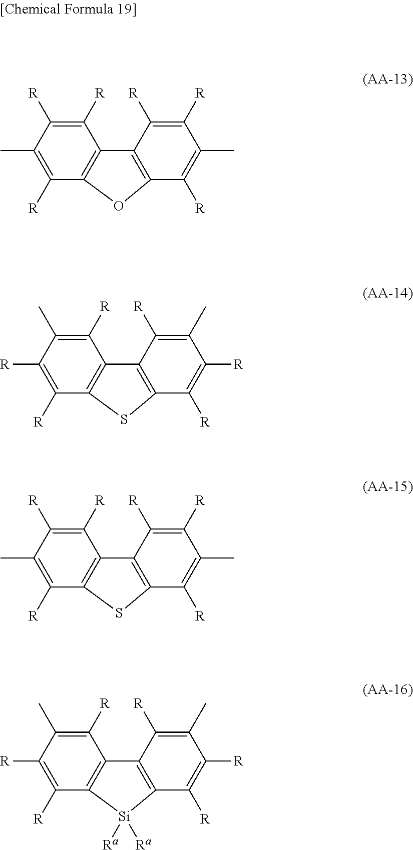

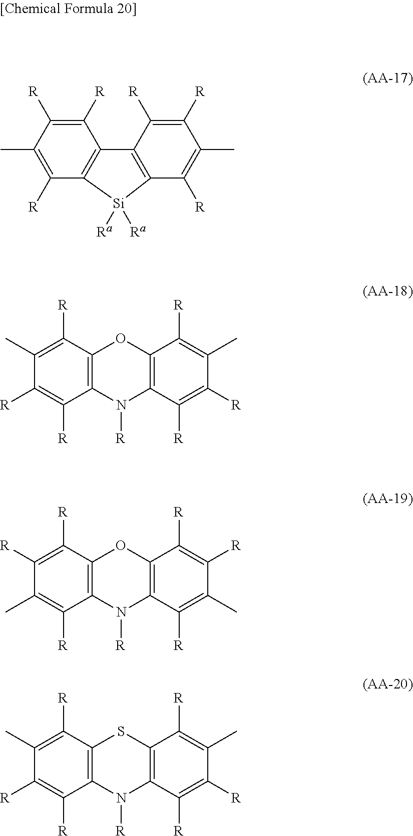

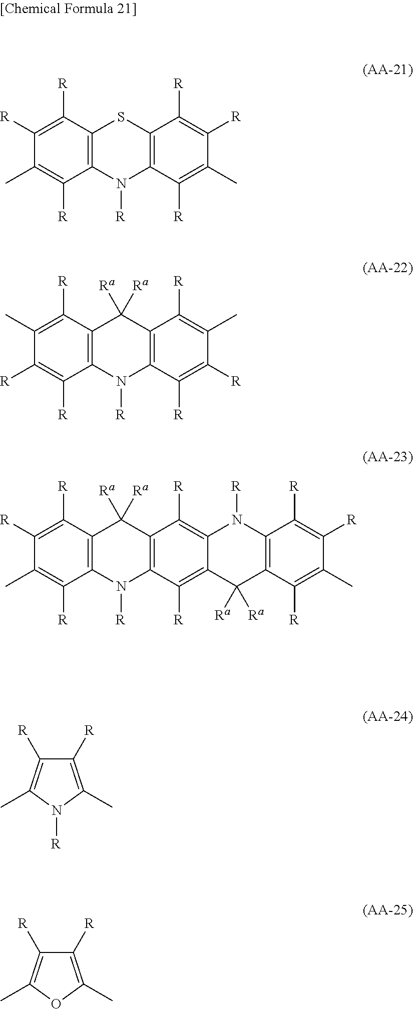

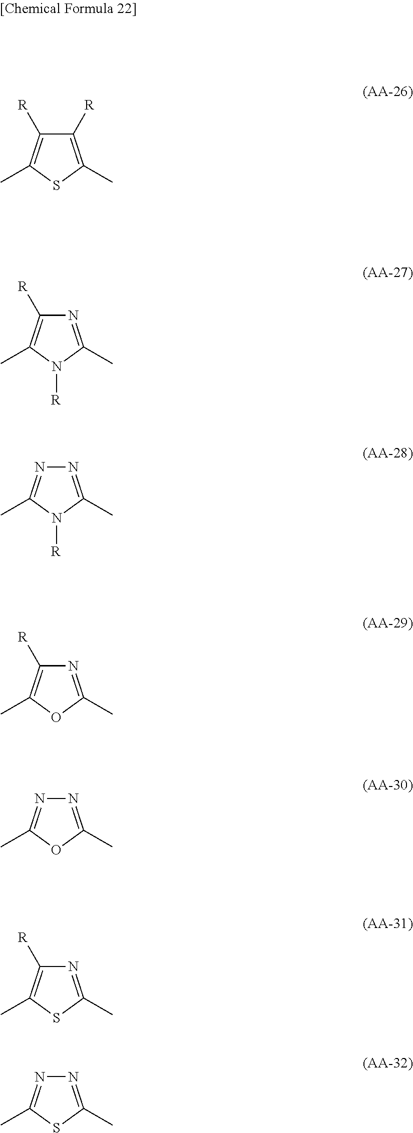

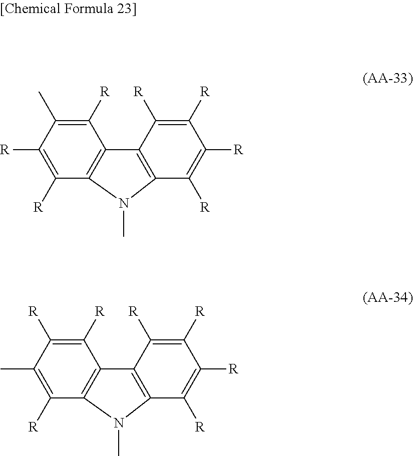

[wherein, R and R^{a} represent the same meaning as described above.]

“Crosslinkable group” is a group capable of forming a new bond by being subjected to a heating treatment, an ultraviolet irradiation treatment, a radical reaction and the like, and the crosslinkable group is preferably any one of groups represented by the formulae (B-1) to (B-17). These groups each optionally have a substituent.

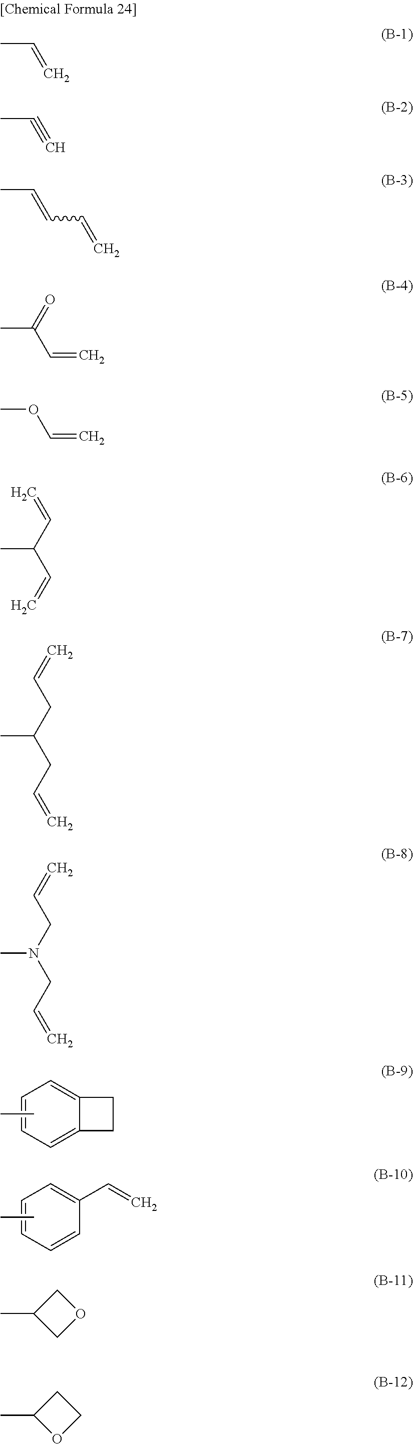

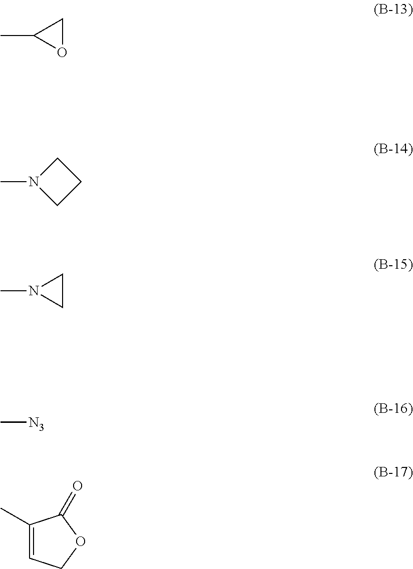

“Substituent” represents a halogen atom, a cyano group, an alkyl group, a cycloalkyl group, an aryl group, a monovalent heterocyclic group, an alkoxy group, a cycloalkoxy group, an aryloxy group, an amino group, a substituted amino group, an alkenyl group, a cycloalkenyl group, an alkynyl group or a cycloalkynyl group. The substutuent may be a crosslinkable group.

“Dendron” is a group having a regular dendritic branched structure having a branching point at an atom or ring (that is, a dendrimer structure). A compound having a dendron (hereinafter, referred to as “dendrimer”.) includes, for example, structures described in literatures such as International Publication WO 02/067343, JP-A No. 2003-231692, International Publication WO 2003/079736, and International Publication WO 2006/097717.

The dendron is preferably a group represented by the formula (D-A) or (D-B).

m^{DA1}, m^{DA2}, m^{DA3}, m^{DA4}, m^{DA5}, m^{DA6}, and m^{DA7} are usually an integer of 10 or less, preferably an integer of 5 or less, more preferably 0 or 1. It is preferable that m^{DA1}, m^{DA2}, m^{DA3}, m^{DA4} m^{DA5}, m^{DA6} and m^{DA7} are the same integer.

G^{DA} is preferably a group represented by the formula (GDA-11) to (GDA-15), and these groups each optionally have a substituent.

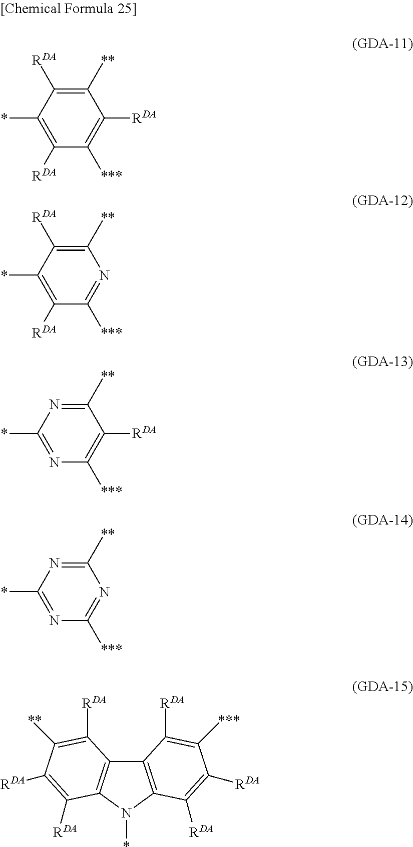

[wherein,

* represents a linkage to Ar^{DA1} in the formula (D-A), Ar^{DA1} in the formula (D-B), Ar^{DA2} in the formula (D-B) or Ar^{DA3} in the formula (D-B).

** represents a linkage to Ar^{DA2} in the formula (D-A), A r^{DA2} in the formula (D-B), Ar^{DA4} in the formula (D-B) or Ar^{DA 6} in the formula (D-B).

*** represents a linkage to Ar^{DA3} in the formula (D-A), A³ in the formula (D-B), Ar^{DA5} in the formula (D-B) or Ar^{DA7} in the formula (D-B).

R^{DA} represents a hydrogen atom, an alkyl group, a cycloalkyl group, an alkoxy group, a cycloalkoxy group, an aryl group or a monovalent heterocyclic group, and these groups each optionally have a substituent. When a plurality of R^{DA} are present, they may be the same or different.]

R^{DA} is preferably a hydrogen atom, an alkyl group, a cycloalkyl group, an alkoxy group or a cycloalkoxy group, more preferably a hydrogen atom, an alkyl group or cycloalkyl group, and these groups each optionally have a substituent.

It is preferable that Ar^{DA1}, Ar^{DA2}, Ar^{DA3}, Ar^{DA4}, Ar^{DA5}, Ar^{DA6} and Ar^{DA7} are groups represented by the formulae (ArDA-1) to (ArDA-3).

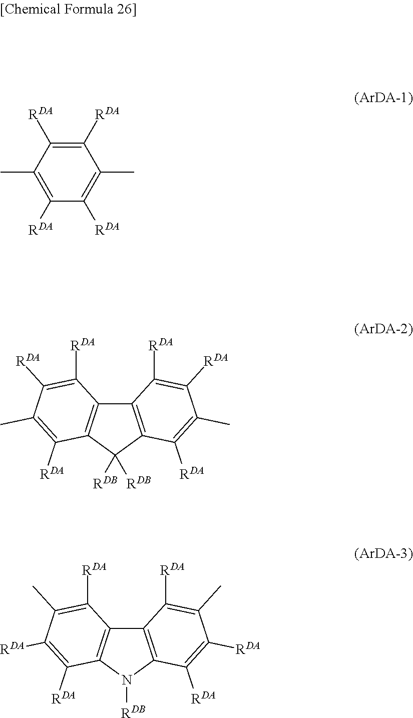

[wherein,

R^{DA} represents the same meaning as described above.

R^{DB} represents a hydrogen atom, an alkyl group, a cycloalkyl group, an aryl group or a monovalent heterocyclic group, and these groups each optionally have a substituent. When a plurality of R^{DB} are present, they may be the same or different at each occurrence.]

R^{DB} is preferably an alkyl group, a cycloalkyl group, an aryl group or a monovalent heterocyclic group, more preferably an aryl group or a monovalent heterocyclic group, further preferably an aryl group.

T^{DA} is preferably groups represented by the formulae (TDA-1) to (TDA-3).

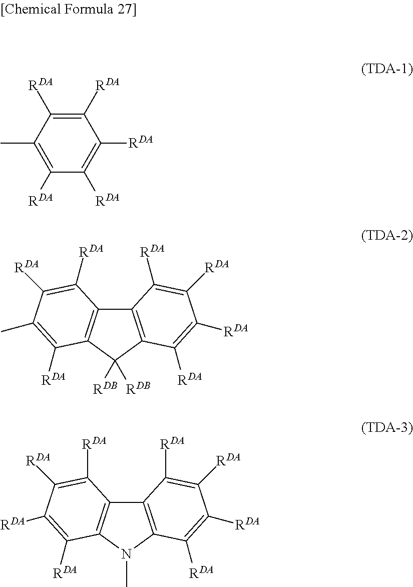

### (TDA-2) (TDA4)

[wherein, R^{DA} and R^{DB} represent the same meaning described above.]

In the groups represented by the formulae (TDA-1) to (TDA-3), at least one selected from among the plurality of R^{DA} and R^{DB} is preferably an alkyl group having 4 or more carbon atoms or a cycloalkyl group having 4 or more carbon atoms, and at least one selected from among the plurality of R^{DA} is preferably an alkyl group having 4 or more carbon atoms or a cycloalkyl group having 4 or more carbon atoms.

The group represented by the formula (D-A) is preferably a group represented by the formula (D-A1) to (D-A3).

The group represented by the formula (D-B) is preferably a group represented by the formula (D-B1) to (D-B3).

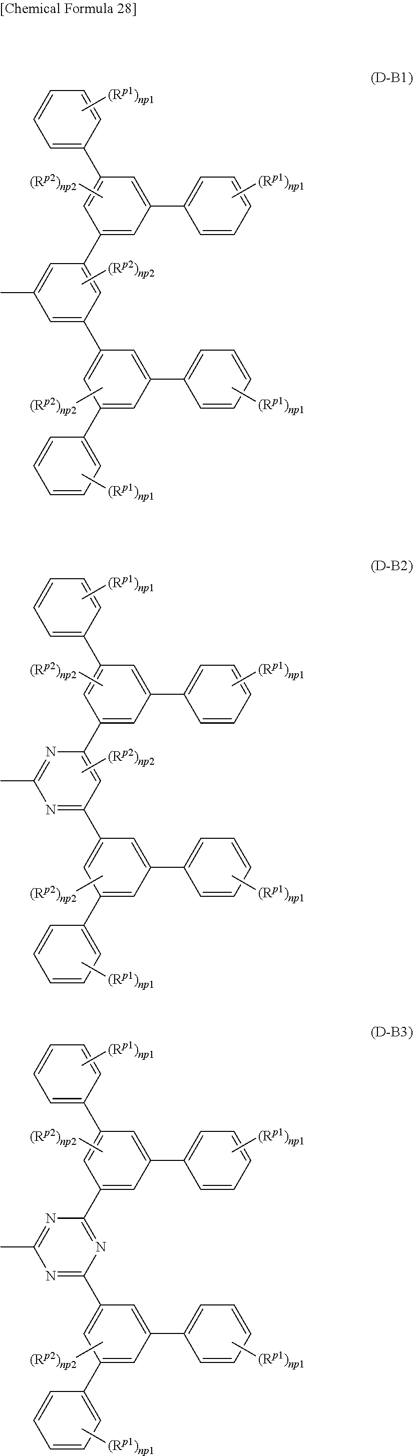

[wherein,

R^{p1}, R^{p2} and R^{p3} each independently represent an alkyl group, a cycloalkyl group, an alkoxy group, a cycloalkoxy group or a halogen atom. When a plurality of R^{p1} and R^{p2} are present, they may be the same or different at each occurrence.

np1 represents an integer of 0 to 5, np2 represents an integer of 0 to 3, and np3 represents 0 or 1. When a plurarity of np1 and np2 are present, they may be the same or different at each occurrence.

np1 is preferably 0 or 1, more preferably 1. np2 is preferably 0 or 1, more preferably 0. np3 is preferably 0.

R^{p1}, R^{p2} and R^{p3} are preferably an alkyl group or a cycloalkyl group.

### <Metal Complex>

Next, the metal complex of the present invention will be explained. The metal complex of the present invention is a metal complex represented by the formula (1).

The metal complex represented by the formula (1) is constituted of M (an iridium atom or a platinum atom), a ligand the number of which is prescribed by a subscript n₁ and a ligand the number of which is prescribed by a subscript n₂.

In the formula (1), M is preferably an iridium atom.

In the formula (1), n₁ is preferably 2 or 3, more preferably 3, when M is an iridium atom.

In the formula (1), n₁ is preferably 2, when M is a platinum atom.

In the formula (1), the combination of E¹, E³ and E⁴ is preferably a combination in which E² and E³ are nitrogen atoms and E⁴ is a carbon atom or a combination in which E² and E⁴ are nitrogen atoms and E³ is a carbon atom, more preferably a combination in which E² and E³ are nitrogen atoms and E⁴ is a carbon atom.

In the formula (1), R¹ is preferably an aryl group, because synthesis of the metal complex of the present invention is easy.

In the formula (1), the aryl group or monovalent heterocyclic group represented by R¹ includes, for example, groups represented by the formulae (L-1) to (L-19), preferably groups represented by the formulae (L-1) to (L-16), more preferably groups represented by the formulae (L-1) to (L-10), further preferably groups represented by the formulae (L-1) to (L-5), particularly preferably a group represented by the formula (L-1).

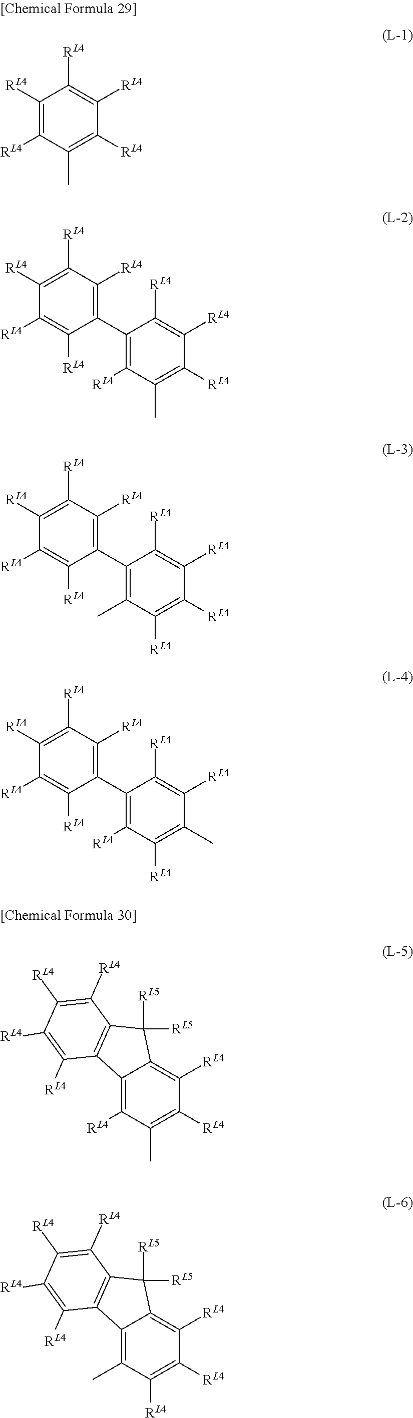

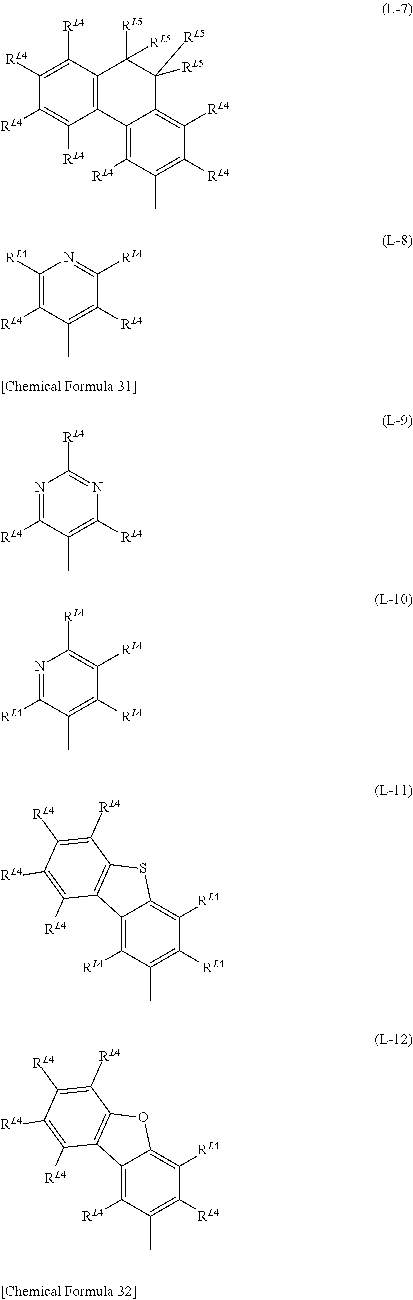

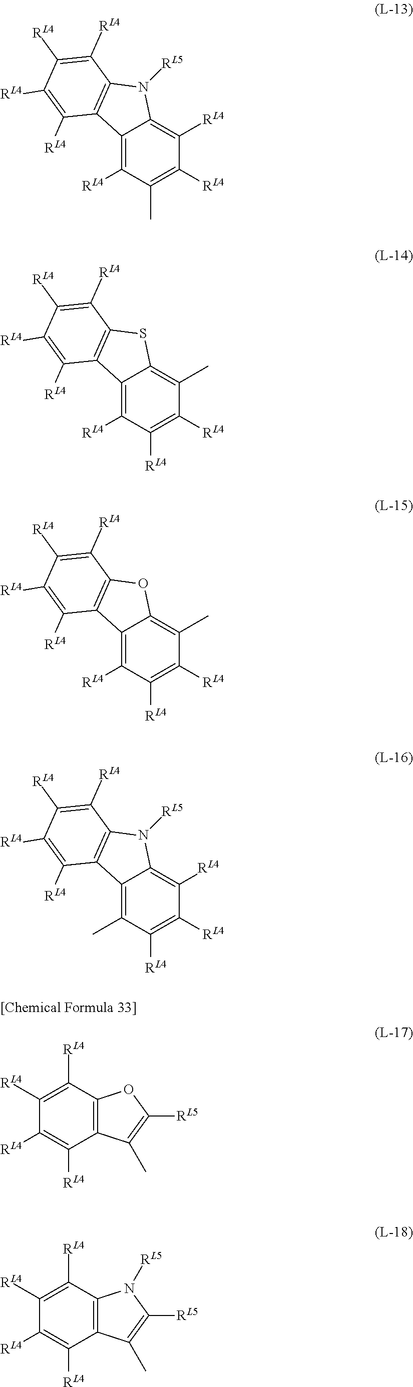

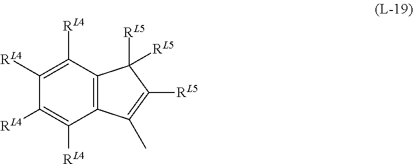

[wherein,

R^{L4} represents a hydrogen atom, an alkyl group, a cycloalkyl group, an aryl group or a monovalent heterocyclic group, and these groups each optionally have a substituent. The plurality of R^{L4} may be the same or different, and adjacent groups R^{L4} may be combined together to form a ring together with the carbon atoms to which they are attached.

R^{L5} represents an alkyl group, a cycloalkyl group, an aryl group or a monovalent heterocyclic group, and these groups each optionally have a substituent. The plurality of R^{L5} may be the same or different and may be combined together to form a ring together with the carbon atoms to which they are attached.]

In the formulae (L-1) to (L-19), R^{L4} is preferably a hydrogen atom, an alkyl group or a cycloalkyl group. The alkyl group or cycloalkyl group represented by R^{L4} is preferably a group selected from groups represented by the formulae (II-01) to (II-010).

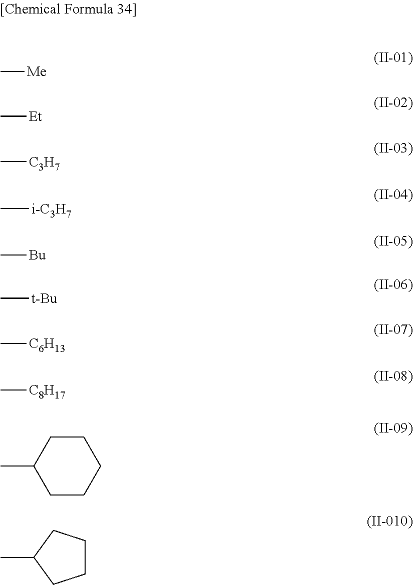

In the formulae (L-1) to (L-19), at least two of the plurality of R^{L4} represent preferably an alkyl group, a cycloalkyl group, an aryl group or a monovalent heterocyclic group, more preferably an alkyl group, a cycloalkyl group or an aryl group, further preferably an alkyl group or a cycloalkyl group, particularly preferably a group selected from groups represented by the formulae (II-01) to (II-010).

In the formulae (L-1) to (L-19), R^{L5} is preferably an alkyl group or a cycloalkyl group, more preferably a group selected from groups represented by the formula (II-01) to the formula (II-010).

In the formula (1), when E² is a nitrogen atom and R is present, R² is preferably an alkyl group, a cycloalkyl group, an aryl group or a monovalent heterocyclic group, more preferably an aryl group.

In the formula (1), when E³ is a nitrogen atom and R³ is present, R³ is preferably an alkyl group, a cycloalkyl group, an aryl group or a monovalent heterocyclic group, more preferably an aryl group.

In the formula (1), the ring A is preferably a 5-membered or 6-membered aromatic hydrocarbon ring or a 5-membered or 6-membered aromatic heterocyclic ring, more preferably a 5-membered or 6-membered aromatic hydrocarbon ring, further preferably a 6-membered aromatic hydrocarbon ring.

In the formula (1), the ring A includes, for example, a benzene ring, a naphthalene ring, a fluorene ring, an indene ring, a phenanthrene ring, a dibenzofuran ring, a dibenzothiophene ring, a carbazole ring, a pyridine ring, a diazabenzene ring, a triazine ring, a pyrrole ring, a furan ring or a thiophene ring, and is preferably a benzene ring, an indene ring, a fluorene ring, a phenanthrene ring, a dibenzofuran ring, a dibenzothiophene ring, a carbazole ring, a pyridine ring, a diazabenzene ring or a triazine ring, more preferably a benzene ring, a fluorene ring, aphenanthrene ring, a dibenzofuran ring, a dibenzothiophene ring, a carbazole ring, a pyridine ring, a diazabenzene ring or a triazine ring, further preferably a benzene ring, a fluorene ring, a dibenzofuran ring, a dibenzothiophene ring, a carbazole ring, a pyridine ring or a pyrimidine ring, particularly preferably a benzene ring, a pyridine ring or a pyrimidine ring, especially preferably a benzene ring.

In the formula (1), it is preferable that the aromatic hydrocarbon ring or aromatic heterocyclic ring represented by the ring A has at least one substituent, because the metal complex of the present invention is more excellent in light emission stability. The substituent which the ring A optionally has is preferably an alkyl group, a cycloalkyl group, an aryl group, a monovalent heterocyclic group or a halogen atom, more preferably an alkyl group, a cycloalkyl group or an aryl group, further preferably an aryl group.

In the formula (1), the anionic bidentate ligand represented by A¹-G¹-A² includes, for example, ligands shown below.

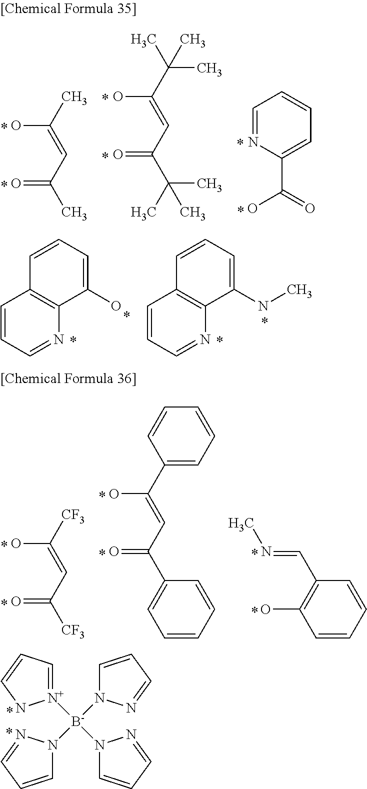

[wherein, * represents a site binding to an iridium atom or a platinum atom.]

In the formula (1), the anionic bidentate ligand represented by A¹-G¹-A² may also be a ligand shown below.

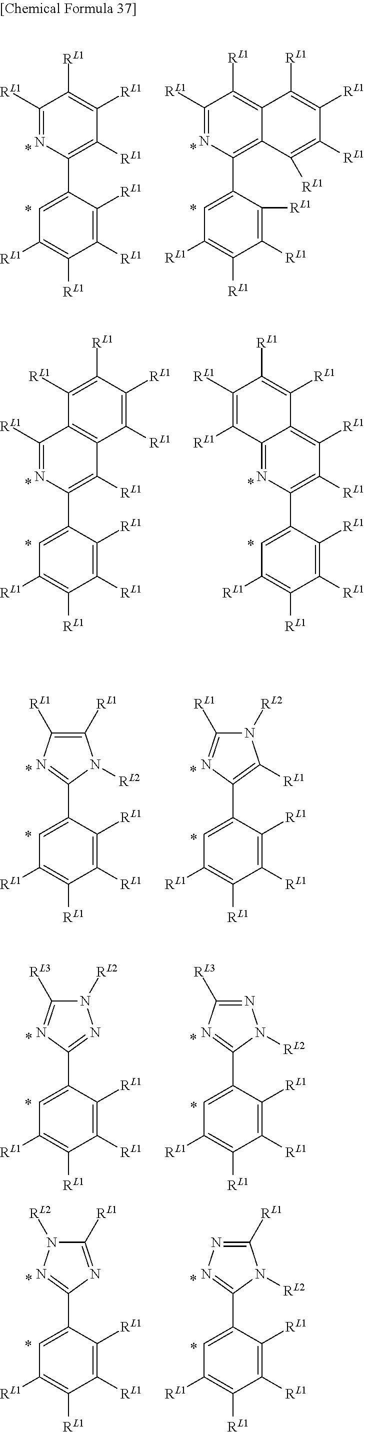

[wherein,

* represents a site binding to an iridium atom or a platinum atom.

R^{L1} represents a hydrogen atom, an alkyl group, a cycloalkyl group, an aryl group, a monovalent heterocyclic group or a halogen atom, and these groups each optionally have a substituent. The plurality of R^{L1} may be the same or different.

R^{L2} represents an alkyl group, a cycloalkyl group, an aryl group, a monovalent heterocyclic group or a halogen atom, and these groups each optionally have a substituent.

R^{L3} represents an alkyl group, a cycloalkyl group or a halogen atom, and these groups each optionally have a substituent.]

The metal complex represented by the formula (1) has a plurality of optical isomers and structural isomers in some cases, from the standpoint of its steric structure. Therefore, the metal complex represented by the formula (1) is produced in the form of a mixture of a plurality of optical isomers and structural isomers in some cases. When the metal complex represented by the formula (1) is produced in the form of a mixture of a plurality of optical isomers and structural isomers, the area percentage of a single component of the metal complex represented by the formula (1) is preferably 90% or more, more preferably 95% or more, further preferably 98% or more, especially preferably 99.5% or more, in high performance liquid chromatography analysis using a column (ODS) filled with achiral silica gel as a stationary phase.

The metal complex represented by the formula (1) is preferably a metal complex represented by the formula (1-a), because light emission stability is more excellent.

In the formula (1-a), R⁴ and R⁷ are preferably a hydrogen atom, an alkyl group, a cycloalkyl group, an aryl group, a monovalent heterocyclic group or a halogen atom, more preferably a hydrogen atom, an alkyl group or an aryl group, further preferably a hydrogen atom, because synthesis of the metal complex of the present invention is easy.

In the formula (1-a), R⁵ and R⁶ are preferably a hydrogen atom, an alkyl group, a cycloalkyl group, an aryl group, a monovalent heterocyclic group or a halogen atom, more preferably a hydrogen atom, an alkyl group, a cycloalkyl group or an aryl group, further preferably a hydrogen atom or an aryl group, and it is particularly preferable that at least one of R⁵ and R⁶ is an aryl group, because synthesis of the metal complex of the present invention is easy.

The metal complex represented by the formula (1-a) is preferably a metal complex represented by the formula (1-b), because light emission stability is more excellent.

In the formula (1-b), R⁸ and R¹² are preferably a hydrogen atom, an alkyl group, a cycloalkyl group, an aryl group or a monovalent heterocyclic group, more preferably a hydrogen atom, an alkyl group or an aryl group, further preferably a hydrogen atom or an alkyl group, particularly preferably a hydrogen atom, because synthesis of the metal complex of the present invention is easy.

In the formula (1-b), R⁹ and R¹¹ are preferably a hydrogen atom, an alkyl group, a cycloalkyl group, an aryl group or a monovalent heterocyclic group, more preferably a hydrogen atom, an alkyl group or an aryl group, further preferably an alkyl group or an aryl group, particularly preferably an alkyl group, because the metal complex of the present invention is excellent in solubility in a solvent and film formability.

Regarding R⁸, R⁹, R¹¹ and R¹² in the formula (1-b), it is more preferable that R⁹ and R¹¹ are the same atom or group, it is more preferable that R⁸ and R¹² are the same atom or group and R⁹ and R¹¹ are the same atom or group, because the metal complex of the present invention is more excellent in light emission stability.

In the formula (1-b), R¹⁰ is preferably a hydrogen atom, an alkyl group, a cycloalkyl group, an aryl group or a monovalent heterocyclic group, more preferably a hydrogen atom, an alkyl group or an aryl group, further preferably a hydrogen atom or an alkyl group, particularly preferably a hydrogen atom, because the metal complex of the present invention is excellent in solubility in a solvent and film formability.

The metal complex represented by the formula (1-b) is preferably a metal complex represented by the formula (1-c) or a metal complex represented by the formula (1-d), more preferably a metal complex represented by the formula (1-c), because light emission stability is more excellent. The metal complex represented by the formula (1-c) is preferably a metal complex represented by the formula (1-e), because light emission stability is further excellent.

In the formula (1-e), R¹⁴, R¹⁵ and R¹⁶ represent preferably an alkyl group, a cycloalkyl group, an aryl group or a monovalent heterocyclic group, more preferably an alkyl group or an aryl group, further preferably an alkyl group.

In the formula (1-e), R¹⁴, R¹⁵ and R¹⁶ represent preferably a hydrogen atom, an alkyl group, a cycloalkyl group, an aryl group or a monovalent heterocyclic group, more preferably a hydrogen atom, an alkyl group or an aryl group.

In the formula (1), the formula (1-a), the formula (1-b), the formula (1-c), the formula (1-d) and the formula (1-e), at least one selected from the group consisting of R¹, R², R³, R⁵, R⁶, R¹⁰ and R¹⁵ is preferably an aryl group or a monovalent heterocyclic group, more preferably an aryl group, because the metal complex of the present invention is more excellent in light emission stability. As the aryl group and the monovalent heterocyclic group, a dendron is preferable, a group represented by the formula (D-A) or (D-B) is more preferable, a group represented by the formula (D-A) is further preferable, a group represented by the formula (D-A1), (D-A2) or (D-A3) is particularly preferable, a group represented by the formula (D-A1) is especially preferable.

The metal complex represented by the formula (1) includes, for example, metal complexes represented by the formulae (Ir-1) to (Ir-18) and the formulae (Pt-1) to (Pt-3), preferably metal complexes represented by the formulae (Ir-1) to (Ir-12) or the formula (Pt-1), more preferably metal complexes represented by the formulae (Ir-1) to (Ir-8), further preferably metal complexes represented by the formulae (Ir-1) to (Ir-4).

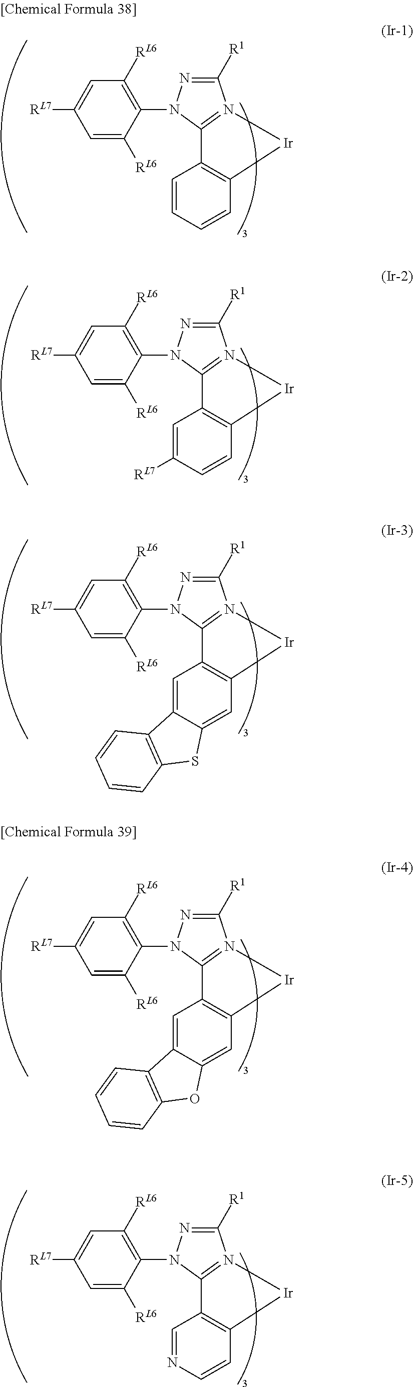

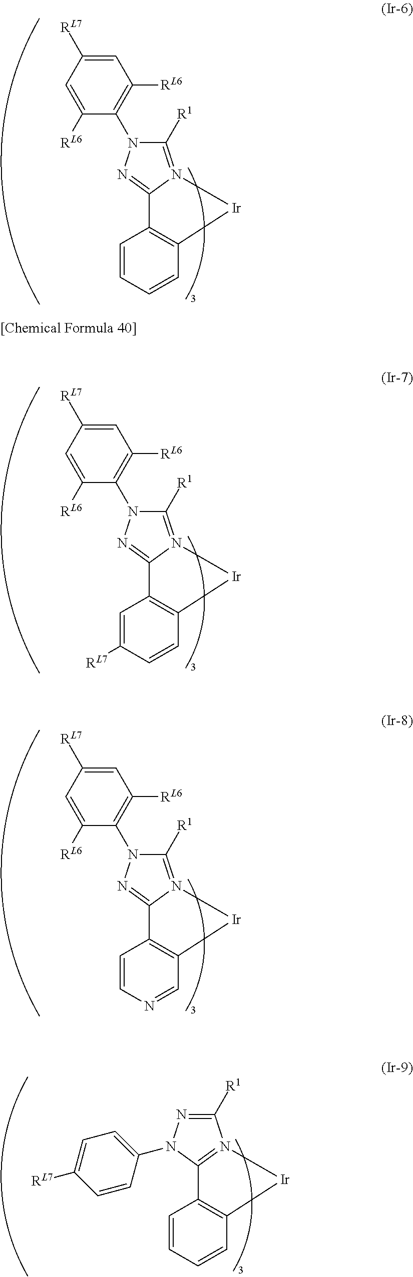

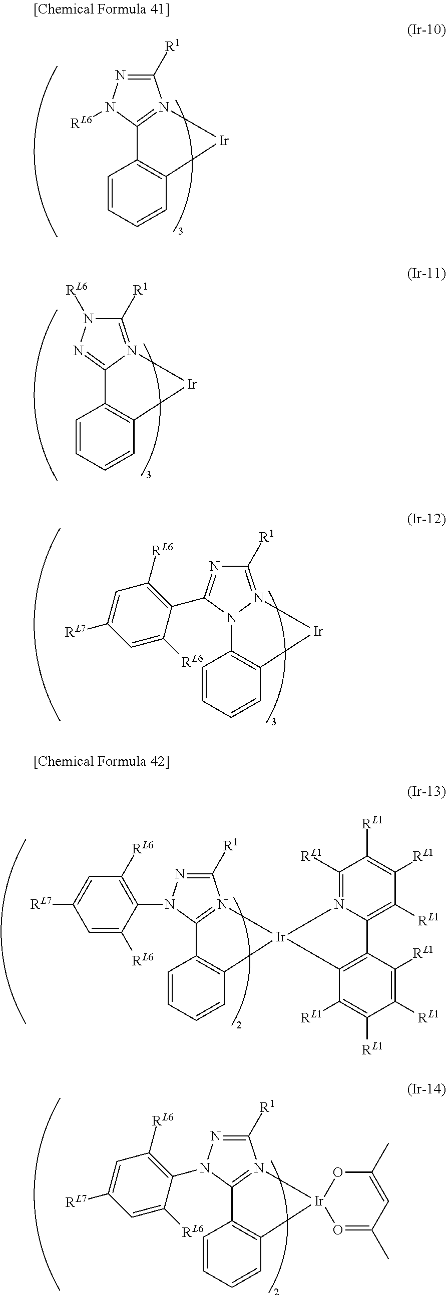

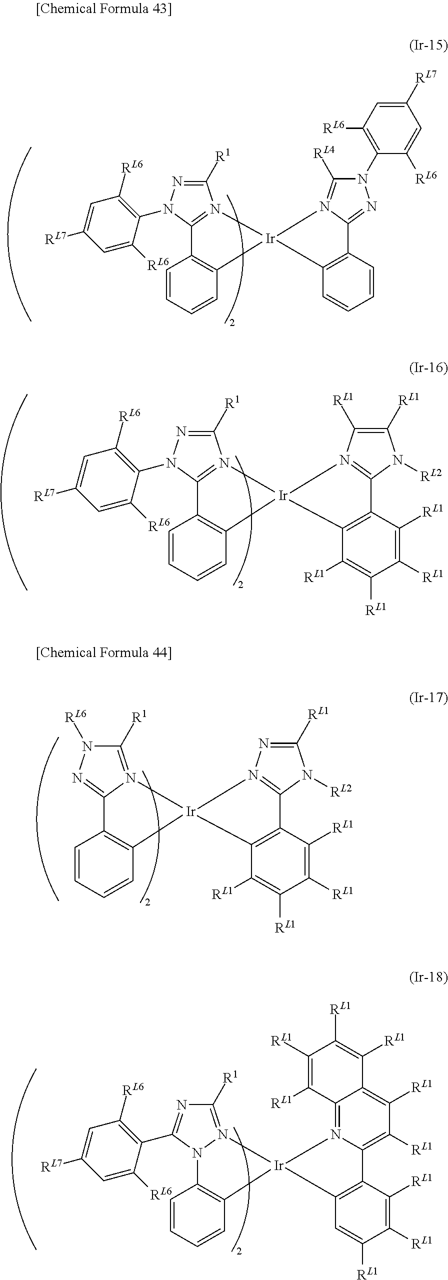

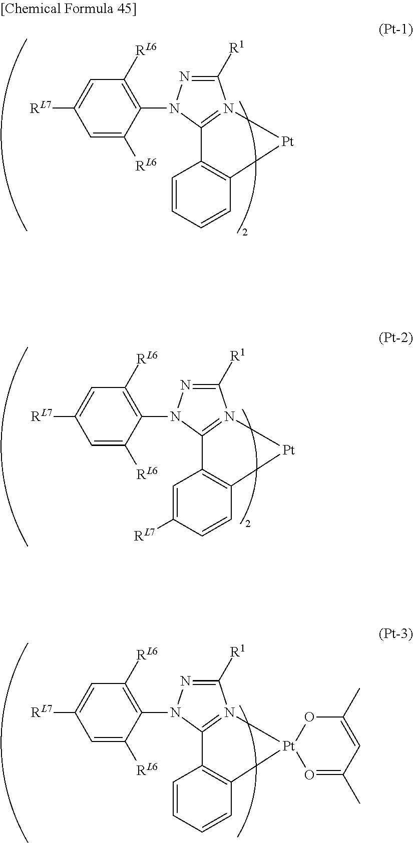

[wherein,

R¹, R^{L1} and R^{L2} represent the same meaning as described above.

R^{L6} represents an alkyl group or a cycloalkyl group, and these groups each optionally have a substituent. The plurality of R^{L6} may be the same or different.

R^{L7} represents an alkyl group, a cycloalkyl group, an aryl group, a monovalent heterocyclic group or a halogen atom, and these groups each optionally have a substituent. When a plurality of R^{L7} are present, they may be the same or different.]

In the formulae (Ir-1) to (Ir-18) and the formulae (Pt-1) to (Pt-3), R^{L6} is preferably an alkyl group or a cycloalkyl group, more preferably a group selected from groups represented by the formula (II-01) to the formula (II-010), further preferably a group selected from groups represented by the formula (II-01) to the formula (11-04), the formula (II-09) or the formula (11-010).

In the formulae (Ir-1) to (Ir-18) and the formulae (Pt-1) to (Pt-3), R^{L7} is preferably an alkyl group, an aryl group or a monovalent heterocyclic group, more preferably a group selected from groups represented by the formula (II-01) to the formula (II-010), a group selected from groups represented by the formula (11-01) to the formula (111-09) or a group represented by the formula (D-A).

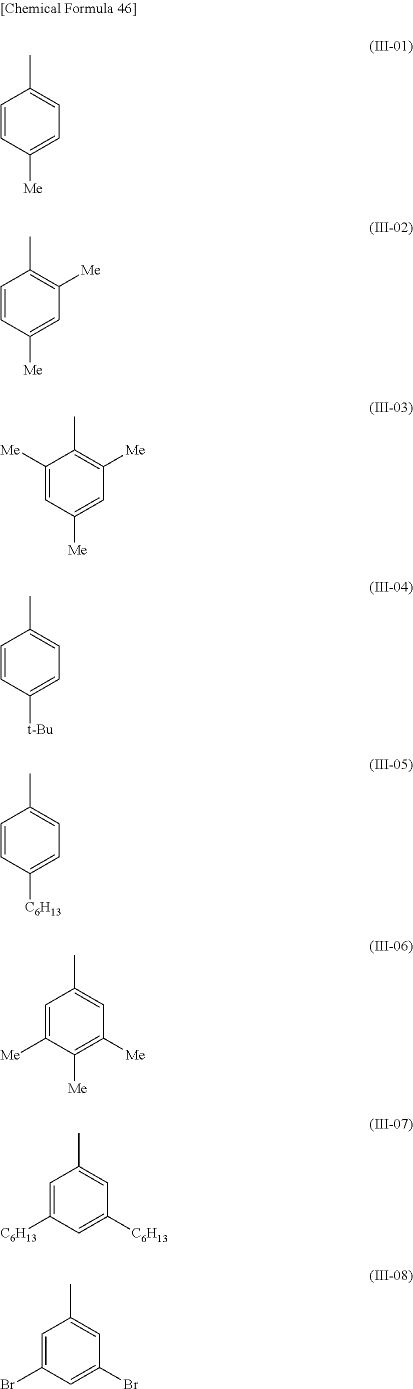

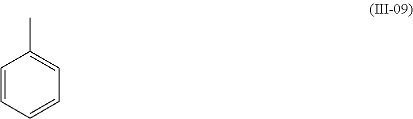

The metal complex represented by the formula (1) includes, for example, metal complexes represented by the formula (Ir-100) to the formula (Ir-124) and the formulae (Pt-100) to (Pt-103).

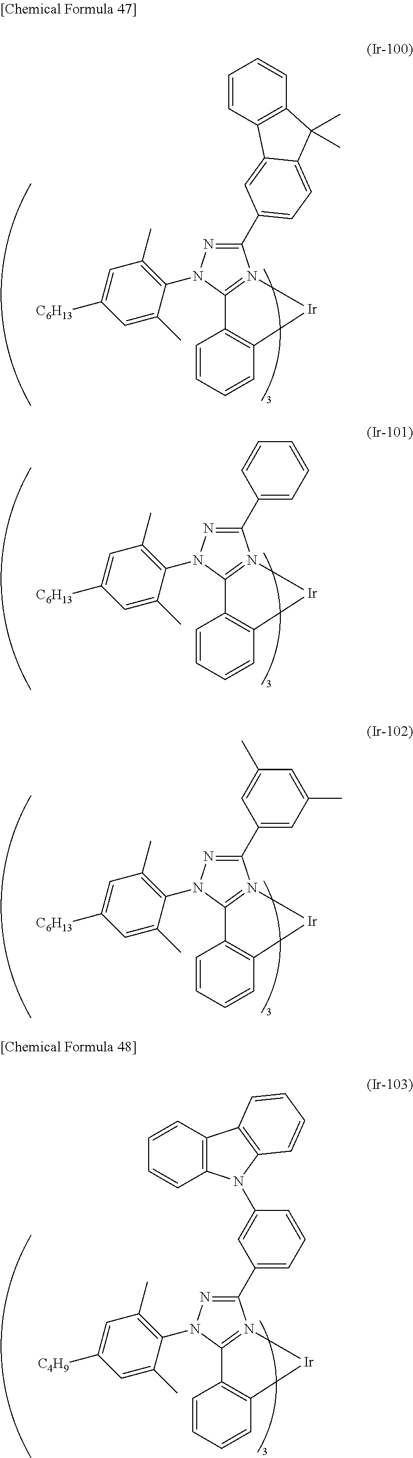

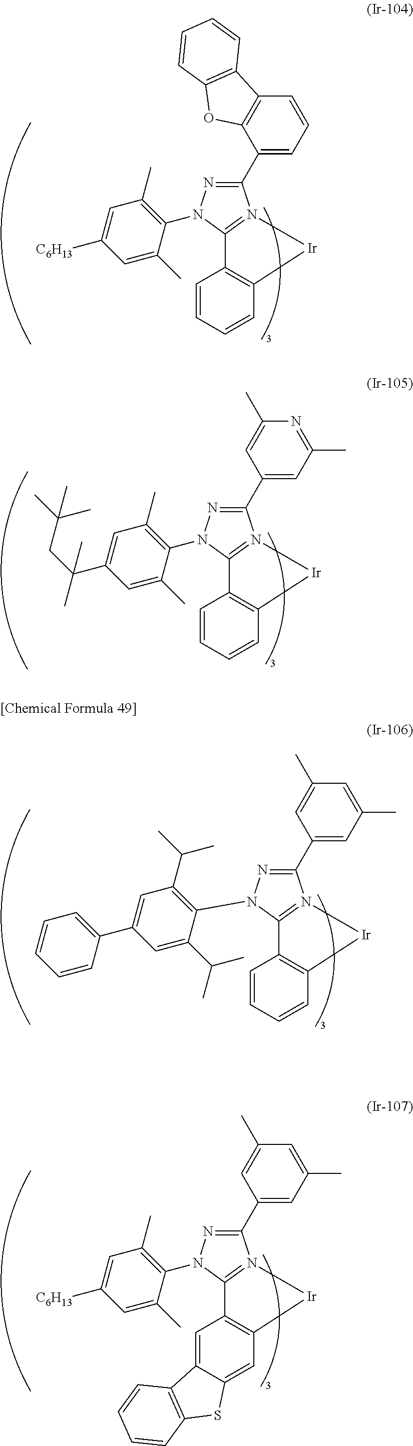

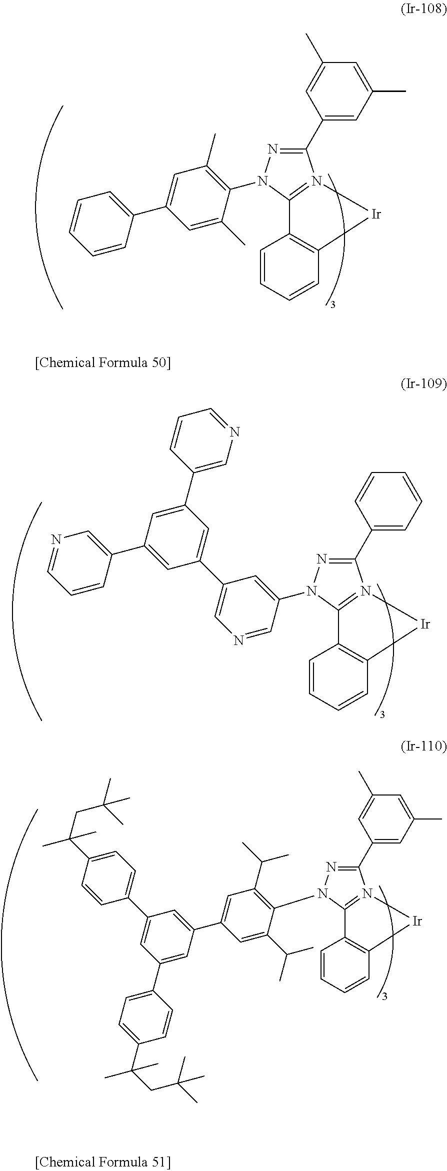

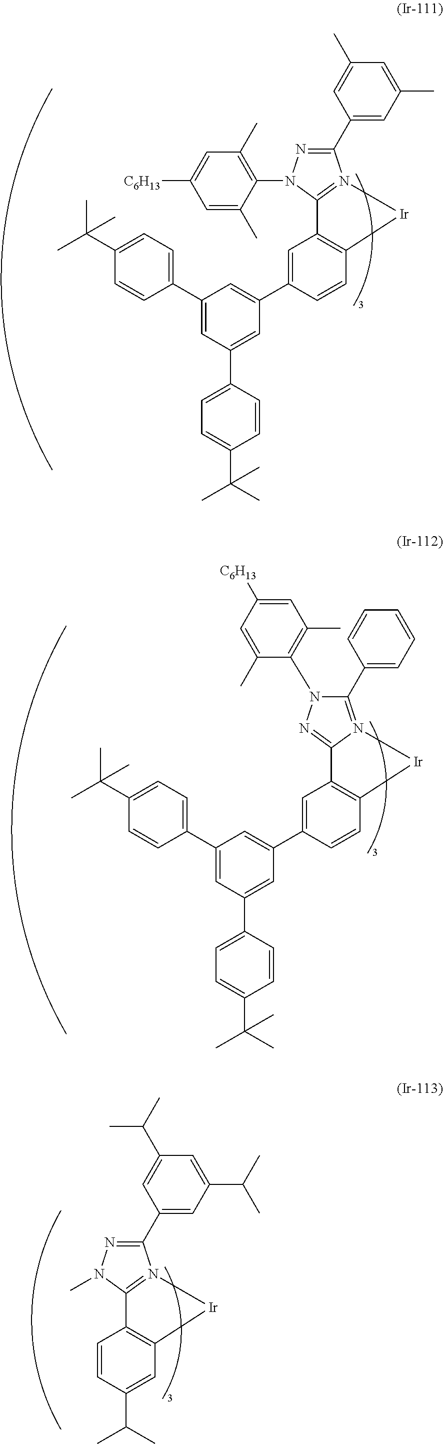

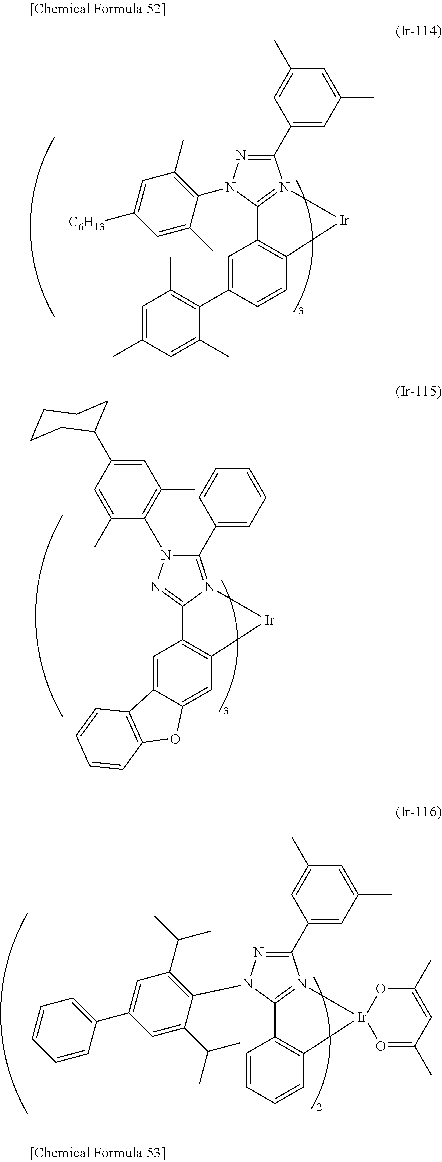

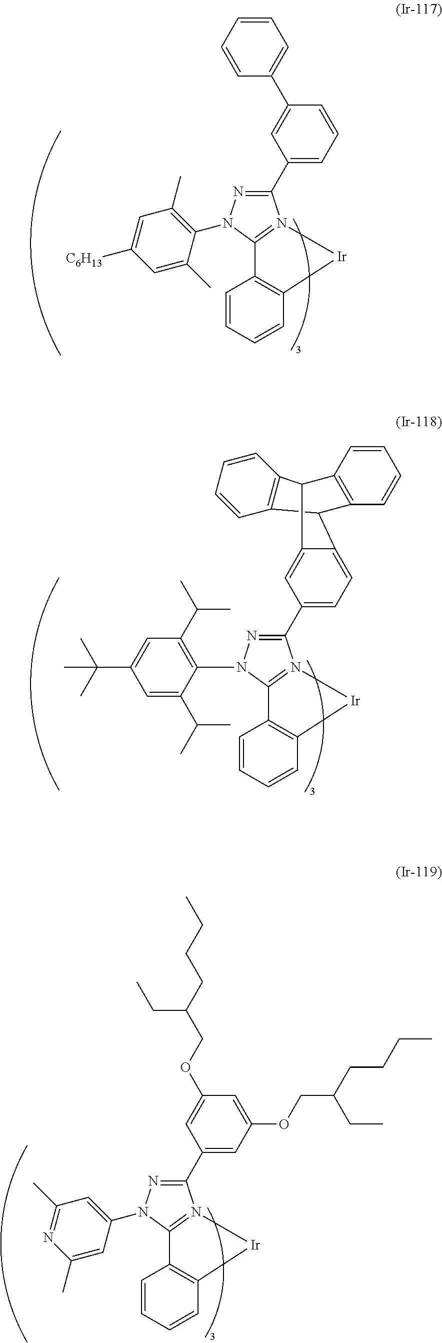

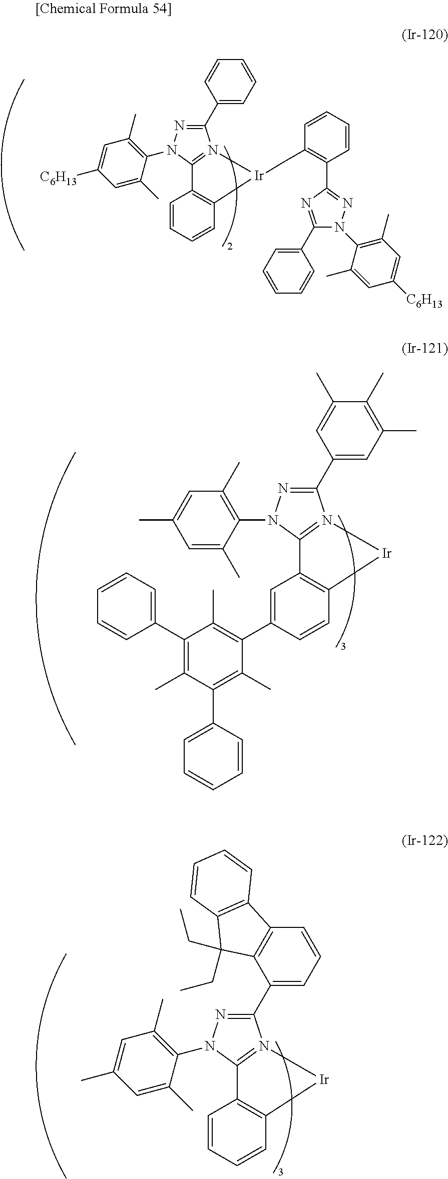

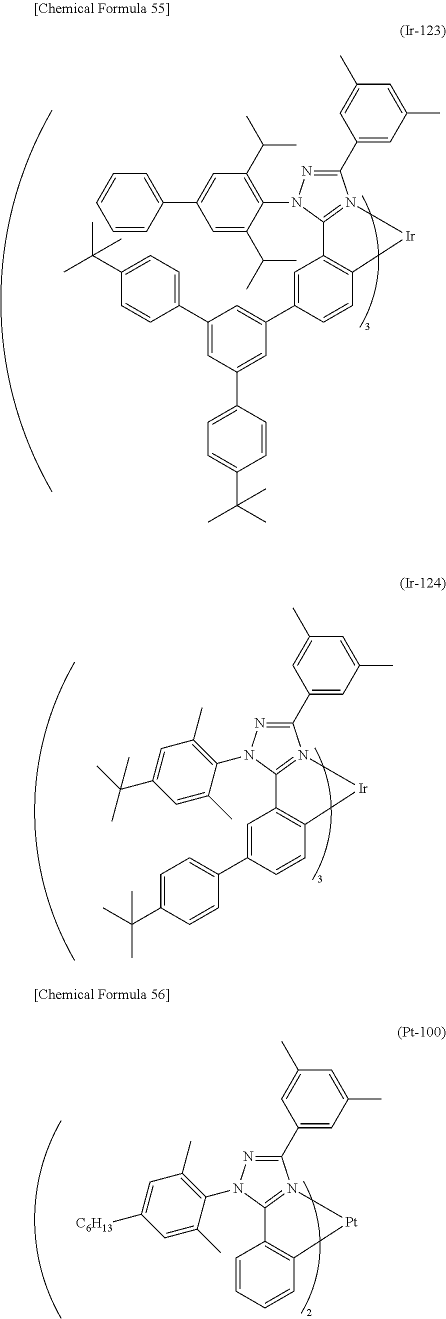

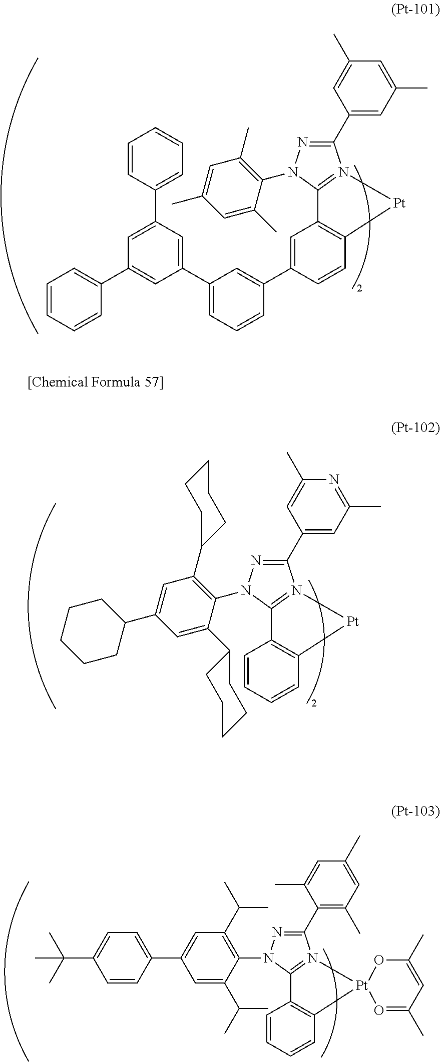

The metal, complex represented by the formula (1) includes a plurality of presumable geometric isomers and may be any geometric isomer, and a facial form is contained in a proportion of preferably 80 mol % or more, more preferably 90 mol % or more, further preferably 99 mol % or more, particularly preferably 100 mol %, with respect to the whole metal complex of the present invention, because a light emitting device produced by using the metal complex of the present invention is excellent in luminance life.

In the light emitting device of the present invention, the metal complexes of the present invention may be used each singly, or two or more of them may be used in combination.

### <Production Method of Metal Complex>

The metal complex of the present invention can be produced, for example, by a method of reacting a compound acting as a ligand with a metal compound. If necessary, a ligand of a metal complex may be subjected to a functional group conversion reaction.

The metal complex represented by the formula (1) can be produced, for example, by a method comprising a step A of reacting a compound represented by the formula (M-1) with an iridium compound or its hydrate or a platinum compound or its hydrate, and a step B of reacting a metal complex represented by the formula (M-2) with a compound represented by the formula (M-1) or a precursor of a ligand represented by A¹-G¹-A².

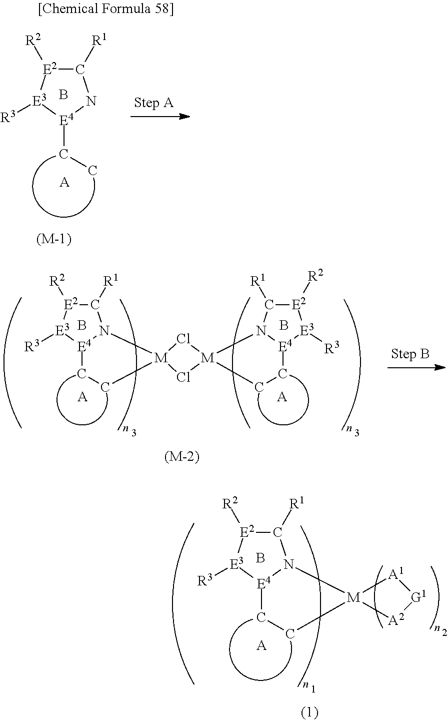

[wherein,

M, n₁, n₂, E², E³, E⁴, R¹, R², R³, a ring A, a ring B and A¹-G¹-A² represent the same meaning as described above.

n₃ represents 1 or 2. n; is 2 when M is an iridium atom, while n₃ is 1 when M is a platinum atom.]

In the step A, the iridium compound includes, for example, iridium chloride and chloro(cyclooctadiene)iridium(I) dimer. The hydrate of the iridium compound includes, for example, iridium chloride.trihydrate.

In the step A, the platinum compound includes, for example, potassium chloroplatinate.

The step A and the step B are conducted usually in a solvent. The solvent includes alcohol solvents such as methanol, ethanol, propanol, ethylene glycol, glycerin, 2-methoxyethanol and 2-ethoxyethanol; ether solvents such as diethyl ether, tetrahydrofuran (THF), dioxane, cyclopentyl methyl ether and diglyme; halogen-based solvents such as methylene chloride and chloroform; nitrile solvents such as acetonitrile and benzonitrile; hydrocarbon solvents such as hexane, decalin, toluene, xylene and mesitylene; amide solvents such as N,N-dimethylformamide and N,N-dimethylacetamide; acetone, dimethyl sulfoxide, water, and the like.

In the step A and the step B, the reaction time is usually between 30 minutes to 200 hours and the reaction temperature is usually between the melting point and the boiling point of a solvent present in the reaction system.

In the step A, the amount of a compound represented by the formula (M-1) is usually 2 to 20 mol with respect to 1 mol of an iridium compound or its hydrate or 1 mol of a platinum compound or its hydrate.

In the step B, the amount of a compound represented by the formula (M-1) or a precursor of a ligand represented by A¹-G¹-A² is usually 1 to 100 mol with respect to 1 mol of a metal complex represented by the formula (M-2).

In the step B, the reaction is preferably carried out in the presence of a silver compound such as silver trifluoromethanesulfonate. When a silver compound is used, the amount thereof is usually 2 to 20 mol with respect to 1 mol of a metal complex represented by the formula (M-2).

The compound represented by the formula (M-3) as one embodiment of a compound represented by the formula (M-1) can be synthesized, for example, by a step of subjecting a compound represented by the formula (M-4) and a compound represented by the formula (2) to a coupling reaction such as the Suzuki reaction, the Kumada reaction and the Stille reaction.

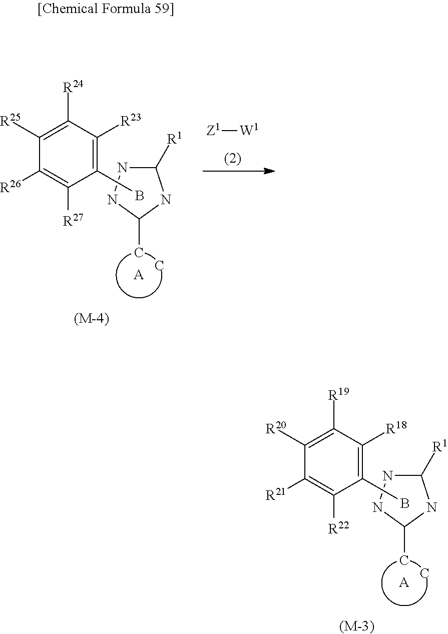

[wherein,

R¹, a ring B and a ring A represent the same meaning as described above.

R¹, R¹⁹, R²⁰, R²¹ and R²² each independently represent a hydrogen atom, an alkyl group, a cycloalkyl group, an alkoxy group, a cycloalkoxy group, an aryl group, an aryloxy group, a monovalent heterocyclic group or a halogen atom, and these groups each optionally have a substituent. At least one of R¹⁹, R²⁰ and R²¹ is a group represented by Z¹.

R²³, R²⁴, R²⁵, R²⁶ and R²⁷ each independently represent a hydrogen atom, an alkyl group, a cycloalkyl group, an alkoxy group, a cycloalkoxy group, an aryl group, an aryloxy group, a monovalent heterocyclic group, a halogen atom, a group represented by —B(OR^{W1})₂, an alkylsulfonyloxy group, a cycloalkylsulfonyloxy group or an arylsulfonyloxy group, and these groups each optionally have a substituent. At least one of R²⁴, R²⁵ and R²⁶ is a group represented by —B(OR^{W1})₂, an alkylsulfonyloxy group, a cycloalkylsulfonyloxy group, an arylsulfonyloxy group, a chlorine atom, a bromine atom or an iodine atom.

Z¹ represents an alkyl group, a cycloalkyl group, an aryl group or a monovalent heterocyclic group, and these groups each optionally have a substituent.

W¹ represents a group represented by —B(OR^{W1})₂, a group represented by —MgX^{W1}, an alkylsulfonyloxy group, a cycloalkylsulfonyloxy group, an arylsulfonyloxy group, a chlorine atom, a bromine atom or an iodine atom, and these groups each optionally have a substituent.

X^{W1} represents a chlorine atom, a bromine atom or an iodine atom.

R^{W1} represents a hydrogen atom, an alkyl group, a cycloalkyl group, an aryl group or an amino group, and these groups each optionally have a substituent. The plurality of R^{W1} may be the same or different and may be combined together to form a cyclic structure together with the oxygen atoms to which they are attached.]

The group represented by —B(OR^{W1})₂ includes, for example, groups represented by the following formulae (W-1)-(W-10).

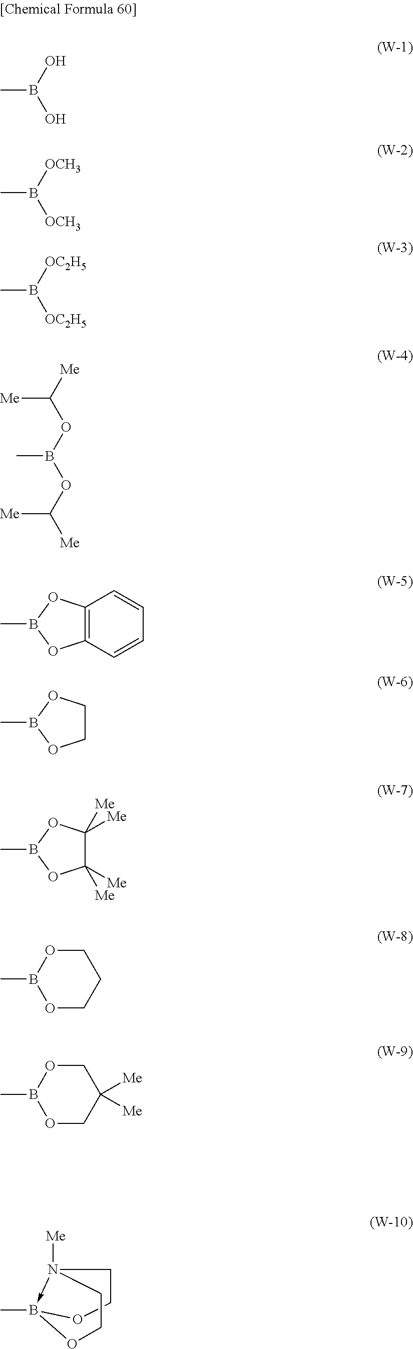

The alkylsulfonyloxy group represented by W¹ includes a methanesulfonyloxy group, an ethanesulfonyloxy group, a trifluoromethanesulfonyloxy group and the like.

The arylsulfonyloxy group represented by W¹ includes a p-toluenesulfonyloxy group and the like.

W¹ is preferably a group represented by —B(OR^{W1}))₂, a trifluoromethanesulfonyloxy group, a bromine atom or an iodine atom, more preferably a bromine atom or a group represented by the formula (W-7), because a coupling reaction of a compound represented by the formula (2) and a compound represented by the formula (M-4) progresses easily.

The examples of the alkylsulfonyloxy group, the cycloalkylsulfonyloxy group and the arylsulfonyloxy group represented by R²⁴, R²⁵ and R²⁶ are respectively the same as the examples of the alkylsulfonyloxy group, the cycloalkylsulfonyloxy group and the arylsulfonyloxy group represented by W¹.

R²⁴, R²⁵ and R²⁶ represent preferably a bromine atom, an iodine atom or a group represented by the formula (W-7).

Z¹ is preferably an alkyl group or an aryl group, more preferably a group selected from groups represented by the above-described formula (II-01) to formula (II-010), a group selected from groups represented by the above-described formula (III-01) to formula (III-08), or a group represented by the above-described formula (D-A).

This reaction is conducted usually in a solvent. The solvent, the reaction time and the reaction temperature are the same as those explained for the step A and the step B.

In this reaction, the amount of a compound represented by the formula (2) is usually 0.05 to 20 mol with respect to 1 mol of a compound represented by the formula (M-4).

The compound represented by the formula (2) can be synthesized, for example, according to methods described in documents such as International Publication WO2002/067343, JP-A No. 2003-231692, International Publication WO2003/079736 and International Publication WO2006/097717.

The compound represented by the formula (M-5) as one embodiment of a compound represented by the formula (M-4) can be synthesized, for example, by a method of condensing a benzoylimidic acid ester compound represented by the formula (M-7) and an arylhydrazine compound represented by the formula (M-6).

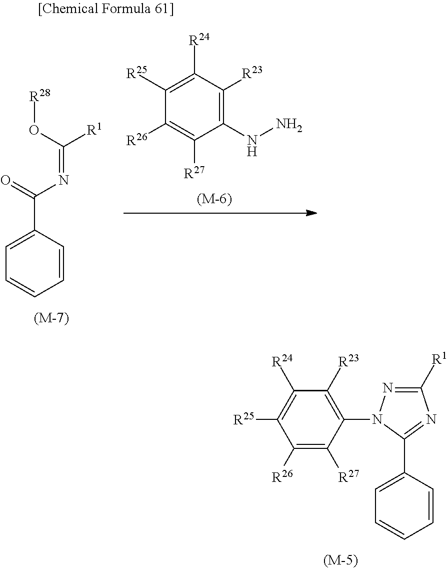

[wherein,

R¹, R², R²⁴, R²⁵, R²⁶ and R²⁷ represent the same meaning as described above.

R²⁸ represents an alkyl group, and this alkyl group optionally has a substituent.]

This reaction is conducted usually in a solvent. The solvent, the reaction time and the reaction temperature are the same as those explained for the step A and the step B. If necessary, a base may be used together.

In this reaction, the amount of a compound represented by the formula (M-6) is usually 0.05 to 20 mol with respect to 1 mol of a compound represented by the formula (M-7).

The compound represented by the formula (M-6) can be synthesized, for example, by methods described in documents such as JP-A No. 2013-147551 and “Journal of the American Chemical Society, Vol. 131, p. 16681 (2009)”. The compound represented by the formula (M-6) may be a salt such as a hydrochloride.

The compound represented by the formula (M-7) can be synthesized, for example, according to methods described in documents such as “Tetrahedron Letters, No. 3, p. 325 (1968)”, “Bioorganic & Medicinal Chemistry, 12, p. 2013 (2004)” and “European Journal of Organic Chemistry, p. 3197 (2011)”.

The metal complex represented by the formula (3) as one embodiment of a metal complex represented by the formula (1) can be produced, for example, by coupling-reacting a compound represented by the formula (2) and a metal complex represented by the formula (4) (as one embodiment of a metal complex represented by the formula (1)). This coupling reaction is the same as that explained for a compound represented by the formula (M-3).

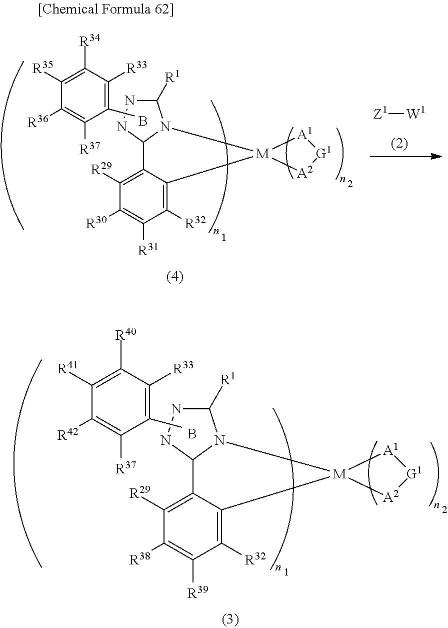

[wherein,

M, n₁, n₂, R¹, a ring B, Z¹, W¹ and A¹-G¹-A² represent the same meaning as described above.

R²⁹, R³⁰, R³¹, R³², R³³, R³⁴, R³⁵, R³⁶ and R³⁷ each independently represent a hydrogen atom, an alkyl group, a cycloalkyl group, an alkoxy group, a cycloalkoxy group, an aryl group, an aryloxy group, a monovalent heterocyclic group, a halogen atom, a group represented by —B(OR^{W1})₂, an alkylsulfonyloxy group, a cycloalkylsulfonyloxy group or an arylsulfonyloxy group, and these groups each optionally have a substituent. R^{W1} represents the same meaning as described above. At least one of R³⁰, R³¹, R³⁴, R³⁵ and R³⁶ is a group represented by —B(OR^{W1})₂, an alkylsulfonyloxy group, a cycloalkylsulfonyloxy group, an arylsulfonyloxy group, a chlorine atom, a bromine atom or an iodine atom.

R³⁸, R³⁹, R⁴⁰, R⁴¹ and R⁴² each independently represent a hydrogen atom, an alkyl group, a cycloalkyl group, an alkoxy group, a cycloalkoxy group, an aryl group, an aryloxy group, a monovalent heterocyclic group or a halogen atom, and these groups each optionally have a substituent. At least one of R³⁸, R³⁹, R⁴⁰, R⁴¹ and R⁴² is a group represented by Z¹.]

The metal complex represented by the formula (4-a) or the formula (4-b) can be synthesized, for example, from a metal complex represented by the formula (5) as one embodiment of a metal complex represented by the formula (4).

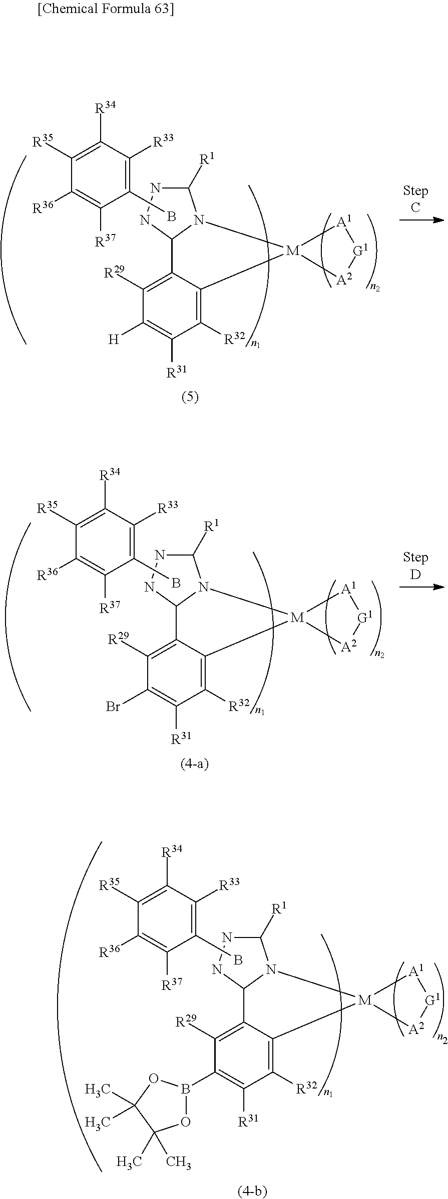

[wherein, M, n₁, n₂, R¹, a ring B, R²⁹, R³¹, R³², R³³, R³⁴, R³⁵, R³⁶ and R³⁷ and A¹-G¹-A² represent the same meaning as described above.]

More specifically, the metal complex represented by the formula (4a) can be synthesized, for example, by a step C of reacting a metal complex represented by the formula (5) and N-bromosuccinimide in an organic solvent.

In the step C, the amount of N-bromosuccinimide is usually 1 to 50 mol with respect to 1 mol of a compound represented by the formula (5).

More specifically, the metal complex represented by the formula (4b) can be synthesized, for example, by a step D of reacting a metal complex represented by the formula (4a) and bis(pinacolato)diboron in an organic solvent.

In the step D, the amount of bis(pinacolato)diboron is usually 1 to 50 mol with respect to 1 mol of a compound represented by the formula (4a).

The step C and the step D are conducted usually in a solvent. The solvent, the reaction time and the reaction temperature are the same as those explained for the step A and the step B.

In the above-described coupling reaction used in the production method of the metal complex of the present invention, catalysts such as a palladium catalyst may be used, for promoting the reaction. The palladium catalyst includes palladium acetate, bis(triphenylphosphine)palladium(II) dichloride, tetrakis(triphenylphosphine)palladium(0), [1,1′-bis(diphenylphosphino)ferrocene]dichloropalladium(II), tris(dibenzylideneacetone)dipalladium(0) and the like.

The palladium catalyst may be used together with a phosphorus compound such as triphenylphosphine, tri(o-tolyl)phosphine, tri(tert-butyl)phosphine, tricyclohexylphosphine and 1,1′-bis(diphenylphosphino)ferrocene.

When the palladium catalyst is used in a coupling reaction, its amount is, for example, usually effective amount, preferably 0.00001 to 10 mol in terms of a palladium element, with respect to 1 mol of a compound represented by the formula (M-4), the formula (4), the formula (4-a) or the formula (4-b).

In the coupling reaction, if necessary, a base is used together.

The compounds, the catalysts and the solvents used in each reaction explained in <Production method of metal complex> each may be used singly, or two or more of them may be used in combination.

### <Composition>

The composition of the present invention comprises at least one material selected from the group consisting of a hole transporting material, a hole injection material, an electron transporting material, an electron injection material, a light emitting material (the light emitting material is different from the metal complex of the present invention), an antioxidant and a solvent, and the metal complex of the present invention.

In the composition of the present invention, the metal complex of the present invention may be contained singly, or the two or more metal complexes of the present invention may be contained.

### [Host Material]

By a composition comprising the metal complex of the present invention and a host material having at least one function selected from hole injectability, hole transportability, electron injectability and electron transportability, the light emission efficiency of a light emitting device produced by using the metal complex of the present invention is excellent. In the composition of the present invention, a host material may be contained singly or two or more host materials may be contained.

In the composition comprising the metal complex of the present invention and the host material, the content of the metal complex of the present invention is usually 0.05 to 80 parts by weight, preferably 0.1 to 50 parts by weight, more preferably 0.5 to 40 parts by weight, when the total amount of the metal complex of the present invention and the host material is 100 parts by weight.

It is preferable that the lowest excited triplet state (T₁) of the host material has energy level equal to or higher than T₁ of the metal complex of the present invention because a light emitting device produced by using the composition of the present invention is excellent in light emission efficiency.

It is preferable that the host material shows solubility in a solvent which is capable of dissolving the metal complex of the present invention because the light emitting device produced by using the composition of the present invention can be produced by a solution coating process.

The host materials are classified into low molecular weight compounds and polymer compounds.

The low molecular weight compound which is preferable as a host compound (hereinafter, referred to as “low molecular weight host”.) will be explained.

### [Low Molecular Weight Host]

The low molecular weight host is preferably a compound represented by the formula (H-i).

Ar^{H1} and Ar^{H2} are preferably a phenyl group, a fluorenyl group, a spirobifluorenyl group, a pyridyl group, a pyrimidinyl group, a triazinyl group, a quinolinyl group, an isoquinolinyl group, a thienyl group, a benzothienyl group, a dibenzothienyl group, a furyl group, a benzofuryl group, a dibenzofuryl group, a pyrrolyl group, an indolyl group, an azaindolyl group, a carbazolyl group, an azacarbazolyl group, a diazacarbazolyl group, a phenoxazinyl group or a phenothiazinyl group, more preferably a phenyl group, a spirobifluorenyl group, a pyridyl group, a pyrimidinyl group, a triazinyl group, a dibenzothienyl group, a dibenzofuryl group, a carbazolyl group or an azacarbazolyl group, further preferably a phenyl group, a pyridyl group, a carbazolyl group or an azacarbazolyl group, particularly preferably a group represented by the formula (TDA-1) or (TDA-3) described above, especially preferably a group represented by the formula (TDA-3) described above, and these groups each optionally have a substituent.

The substituent which Ar^{H1} and Ar^{H2} optionally have is preferably a halogen atom, an alkyl group, a cycloalkyl group, an alkoxy group, a cycloalkoxy group, an aryl group or a monovalent heterocyclic group, more preferably an alkyl group, a cycloalkoxy group, an alkoxy group or cycloalkoxy group, further preferably an alkyl group or cycloalkoxy group, and these groups each optionally further have a substituent.

n^{H1} is preferably 1. n^{H2} is preferably 0.

n^{H3} is usually an integer of 0 to 10, preferably an integer of 0 to 5, further preferably an integer of 1 to 3, particularly preferably 1.

n^{H11} is preferably an integer of 1 to 5, more preferably an integer of 1 to 3, further preferably 1.

R^{H11} is preferably a hydrogen atom, an alkyl group, a cycloalkyl group, an aryl group or a monovalent heterocyclic group, more preferably a hydrogen atom, an alkyl group or a cycloalkyl group, further preferably a hydrogen atom or an alkyl group, and these groups each optionally have a substituent.

L^{H1} is preferably an arylene group or a divalent heterocyclic group.

L^{H1} is preferably a group represented by the formula (A-1) to (A-3), the formula (A-8) to (A-10), the formula (AA-1) to (AA-6), the formula (AA-10) to (AA-21) or the formula (AA-24) to (AA-34), more preferably a group represented by the formula (A-1), the formula (A-2), the formula (A-8), the formula (A-9), the formula (AA-1) to (AA-4), the formula (AA-10) to (AA-15) or the formula (AA-29) to (AA-34), further preferably a group represented by the formula (A-1), the formula (A-2), the formula (A-8), the formula (A-9), the formula (AA-2), the formula (AA-4) or the formula (AA-10) to (AA-15), particularly preferably a group represented by the formula (A-1), the formula (A-2), the formula (A-8), the formula (AA-2), the formula (AA-4), the formula (AA-10), the formula (AA-12) or the formula (AA-14), especially preferably a group represented by the formula (A-1), the formula (A-2), the formula (AA-2), the formula (AA-4) or the formula (AA-14).

The substituent which L^{H1} optionally has is preferably a halogen atom, an alkyl group, a cycloalkyl group, an alkoxy group, a cycloalkoxy group, an aryl group or a monovalent heterocyclic group, more preferably an alkyl group, an alkoxy group, an aryl group or a monovalent heterocyclic group, further preferably an alkyl group, an aryl group or a monovalent heterocyclic group, and these groups optionally further have a substituent.

L^{H21} is preferably a single bond or an arylene group, more preferably a single bond, and this arylene group optionally has a substituent.

The definition and examples of the arylene group or the divalent heterocyclic group represented by L^{H21} are the same as the definition and examples of the arylene group or the divalent heterocyclic group represented by L^{H1}.

R^{H21} is preferably an aryl group or a monovalent heterocyclic group, and these groups each optionally have a substituent.

The definition and examples of the aryl group and the monovalent heterocyclic group represented by R^{H21} are the same as the definition and examples of the aryl group and the monovalent heterocyclic group represented by Ar^{H1} and Ar^{H2}

The definition and examples of the substituent which R^{H21} may optionally has are the same as the definition and examples of the substituent which Ar^{H1} and Ar^{H2} optionally have.

The compound represented by the formula (H-1) is preferably a compound represented by the formula (H-2).

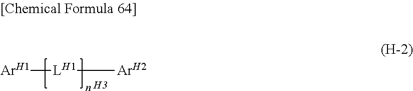

[wherein, Ar^{H1}, Ar^{H2}, n^{H3} and L^{H1} represent the same meaning as described above.]

As the compound represented by the formula (H-1), compounds represented by the following formulae (H-101) to (H-118) are exemplified.

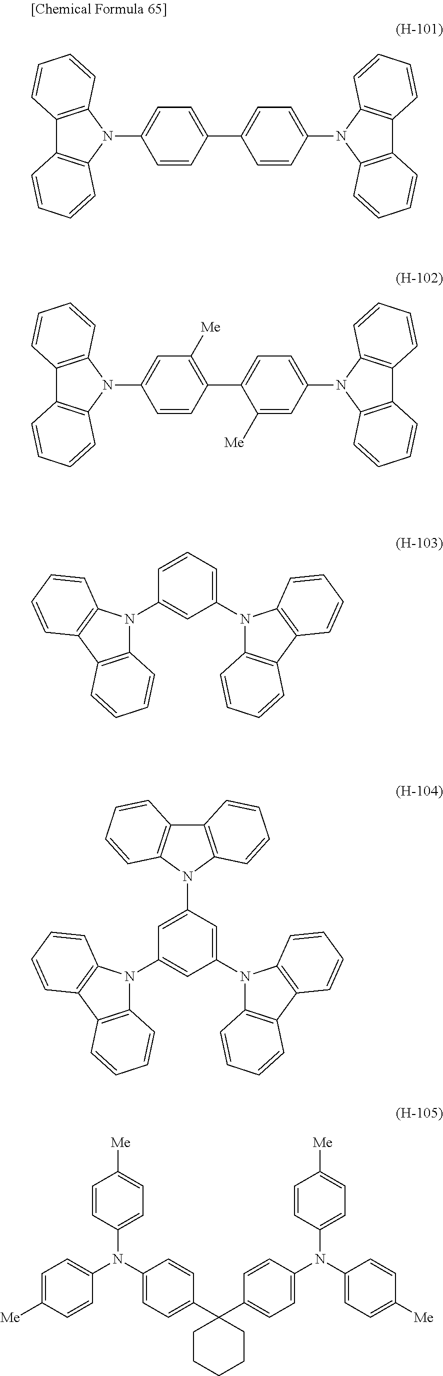 [SMILES: c1ccc2c(c1)c1ccccc1n2-c1ccc(-c2ccc(-n3c4ccccc4c4ccccc43)cc2)cc1 ; Cc1cc(-n2c3ccccc3c3ccccc32)ccc1-c1ccc(-n2c3ccccc3c3ccccc32)cc1C ; c1cc(-n2c3ccccc3c3ccccc32)cc(-n2c3ccccc3c3ccccc32)c1 ; c1ccc2c(c1)c1ccccc1n2-c1cc(-n2c3ccccc3c3ccccc32)cc(-n2c3ccccc3c3ccccc32)c1 ; Cc1ccc(N(c2ccc(C)cc2)c2ccc(C3(c4ccc(N(c5ccc(C)cc5)c5ccc(C)cc5)cc4)CCCCC3)cc2)cc1]

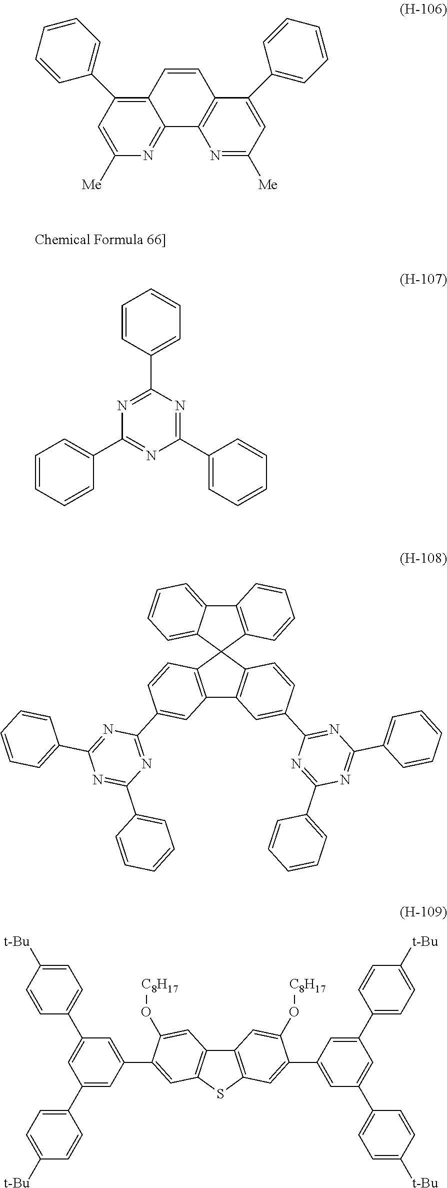

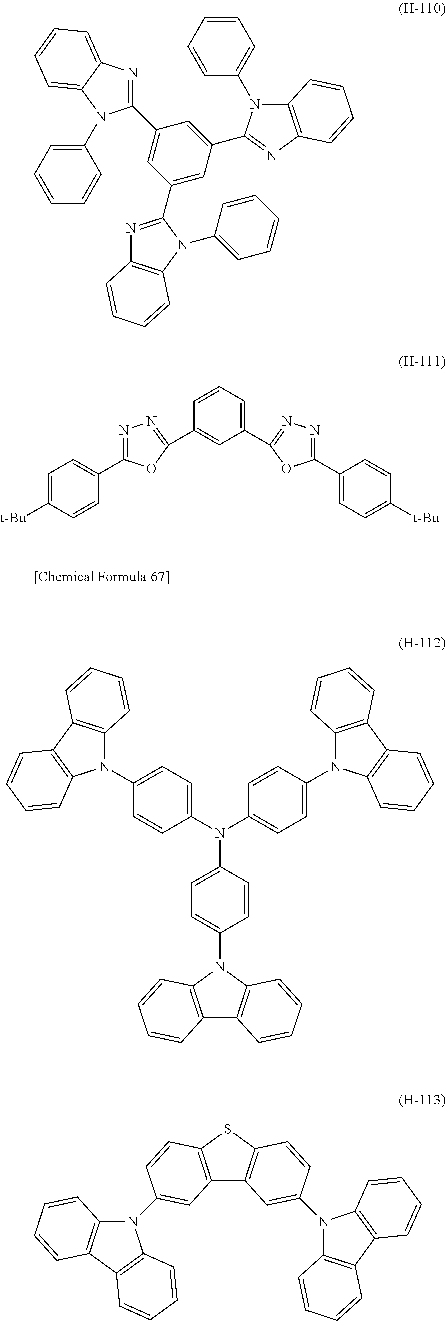 [SMILES: c1ccc(-n2c(-c3cc(-c4nc5ccccc5n4-c4ccccc4)cc(-c4nc5ccccc5n4-c4ccccc4)c3)nc3ccccc32)cc1 ; CC(C)(C)c1ccc(-c2nnc(-c3cccc(-c4nnc(-c5ccc(C(C)(C)C)cc5)o4)c3)o2)cc1 ; c1ccc2c(c1)c1ccccc1n2-c1ccc(N(c2ccc(-n3c4ccccc4c4ccccc43)cc2)c2ccc(-n3c4ccccc4c4ccccc43)cc2)cc1 ; c1ccc2c(c1)c1ccccc1n2-c1ccc2sc3ccc(-n4c5ccccc5c5ccccc54)cc3c2c1]

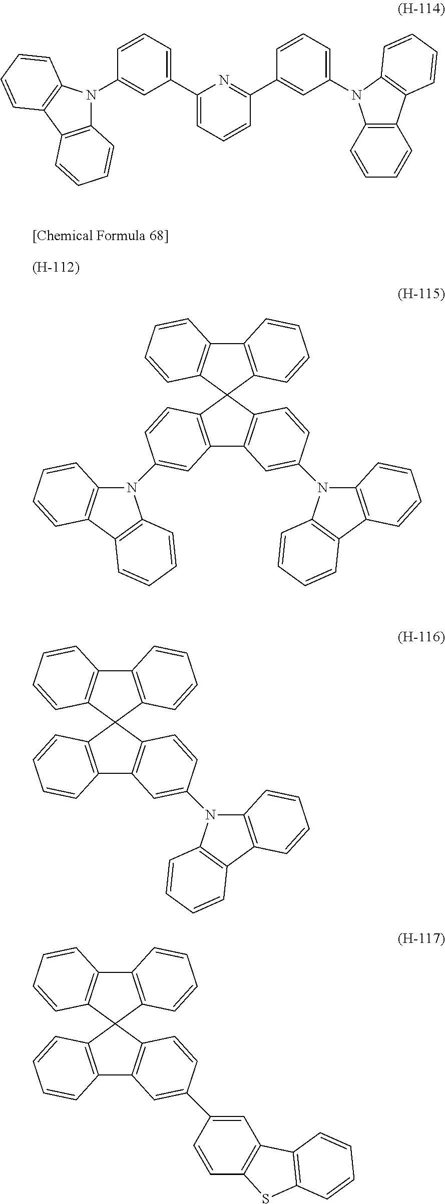

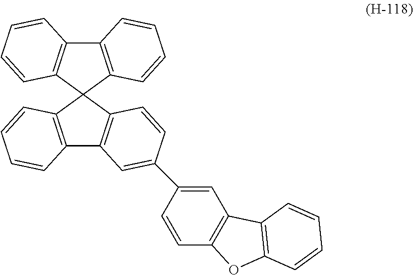 [SMILES: c1ccc2c(c1)-c1ccccc1C21c2ccccc2-c2cc(-c3ccc4oc5ccccc5c4c3)ccc21]

The polymer compound used as a host material includes, for example, polymer compounds as a hole transporting material described later and polymer compounds as an electron transporting material described later.

### [Polymer Host]

The polymer compound which is preferable as a host compound (hereinafter, referred to also as “polymer host”) will be explained.

The polymer host is preferably a polymer compound comprising a constitutional unit represented by the formula (Y).

The arylene group represented by Ar^{Y1} is more preferably a group represented by the formula (A-1), the formula (A-2), the formula (A-6) to (A-10), the formula (A-19) or the formula (A-20), further preferably a group represented by the formula (A-1), the formula (A-2), the formula (A-7), the formula (A-9) or the formula (A-19), and these groups each optionally have a substituent.

The divalent heterocyclic group represented by Ar^{Y1} is more preferably a group represented by the formula (AA-1) to (AA-4), the formula (AA-10) to (AA-15), the formula (AA-18) to (AA-21), the formula (AA-33) or the formula (AA-34), further preferably a group represented by the formula (AA-4), the formula (AA-10), the formula (AA-12), the formula (AA-14) or the formula (AA-33), and these groups each optionally have a substituent.

The more preferable range and the further preferable range of the arylene group and the divalent heterocyclic group in the divalent group in which at least one arylene group and at least one divalent heterocyclic group are bonded directly to each other represented by Ar^{Y1} are the same as the more preferable range and the further preferable range of the arylene group and the divalent heterocyclic group represented by Ar^{Y1} described above, respectively.

“The divalent group in which at least one arylene group and at least one divalent heterocyclic group are bonded directly to each other” includes, for example, groups represented by the following formulae, and each of them optionally has a substituent.

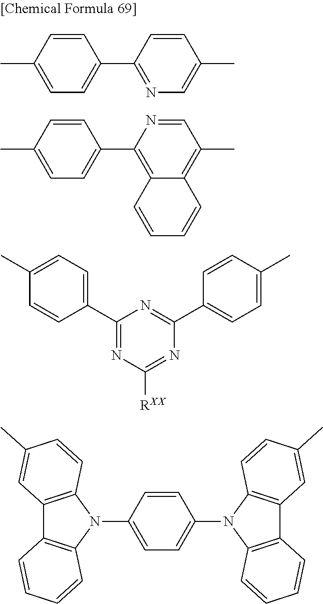

[wherein, R^{XX} represents a hydrogen atom, an alkyl group, a cycloalkyl group, an aryl group or a monovalent heterocyclic group and these groups each optionally have a substituent.]

R^{XX} is preferably an alkyl group, a cycloalkyl group or an aryl group, and these groups each optionally have a substituent.

The substituent which the group represented by Ar^{Y1} optionally has is preferably an alkyl group, a cycloalkyl group or an aryl group, and these groups each optionally further have a substituent.

The constitutional unit represented by the formula (Y) includes, for example, constitutional units represented by the formulae (Y-1) to (Y-10), and from the standpoint of the luminance life of the light emitting device produced by using the composition comprising the polymer host and the metal complex of the present invention preferable are constitutional units represented by the formulae (Y-1) to (Y-3), from the standpoint of electron transportability preferable are constitutional units represented by the formulae (Y-4) to (Y-7), and from the standpoint of hole transportability preferable are constitutional units represented by the formulae (Y-8) to (Y-10).

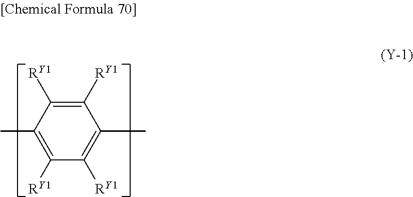

[wherein, R^{Y1} represents a hydrogen atom, an alkyl group, a cycloalkyl group, an alkoxy group, a cycloalkoxy group, an aryl group or a monovalent heterocyclic group, and these groups each optionally have a substituent. The plurality of R^{Y1} may be the same or different, and adjacent R^{Y1}s may be combined together to form a ring together with the carbon atoms to which they are attached.]

R^{Y1} is preferably a hydrogen atom, an alkyl group, a cycloalkyl group or an aryl group, and these groups each optionally have a substituent.

It is preferable that the constitional unit represented by the formula (Y-1) is a constitutional unit represented by the formula (Y-1′).

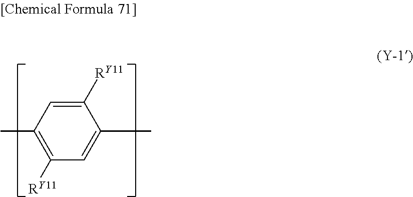

[wherein, B^{Y11} represents an alkyl group, a cycloalkyl group, an alkoxy group, a cycloalkoxy group, an aryl group or a monovalent heterocyclic group, and these groups each optionally have a substituent. The plurality of R^{Y11} may be the same or different.]

R^{Y11} is preferably an alkyl group, a cycloalkyl group or an aryl group, more preferably an alkyl group or a cycloalkyl group, and these groups each optionally have a substituent.

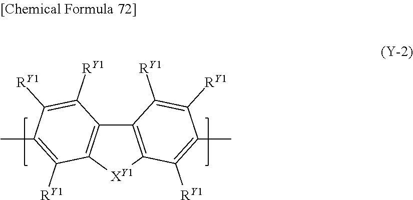

[wherein, R^{Y1} represents the same meaning as described above. X^{Y1} represents a group represented by —C(R^{Y2})₂—, —C(R^{Y2})═C(R^{Y2})— or —C(R^{Y2})₂—C(R^{Y2})₂—. R^{Y2} represents a hydrogen atom, an alkyl group, a cycloalkyl group, an alkoxy group, a cycloalkoxy group, an aryl group or a monovalent heterocyclic group and these groups each optionally have a substituent. The plurality of R^{Y2} may be the same or different, and these R^{Y2}s may be combined together to form a ring together with the carbon atoms to which they are attached.]

R^{Y2} is preferably an alkyl group, a cycloalkyl group, an aryl group or a monovalent heterocyclic group, more preferably an alkyl group a cycloalkyl group or an aryl group, and these groups each optionally have a substituent.

Regarding the combination of two R^{Y2}s in the group represented by —C(R^{Y2})₂— in X^{X1}, it is preferable that the both are an alkyl group or a cycloalkyl group, the both are an aryl group, the both are a monovalent heterocyclic group, or one is an alkyl group or a cycloalkyl group and the other is an aryl group or a monovalent heterocyclic group, it is more preferable that one is an alkyl group or cycloalkyl group and the other is an aryl group, and these groups each optionally have a substituent. The two groups R^{Y2} may be combined together to form a ring together with the atoms to which they are attached, and when the groups R^{Y2} form a ring, the group represented by —C(R^{Y2})₂— is preferably a group represented by the formula (Y-A1) to (Y-A5), more preferably a group represented by the formula (Y-A4), and these groups each optionally have a substituent.

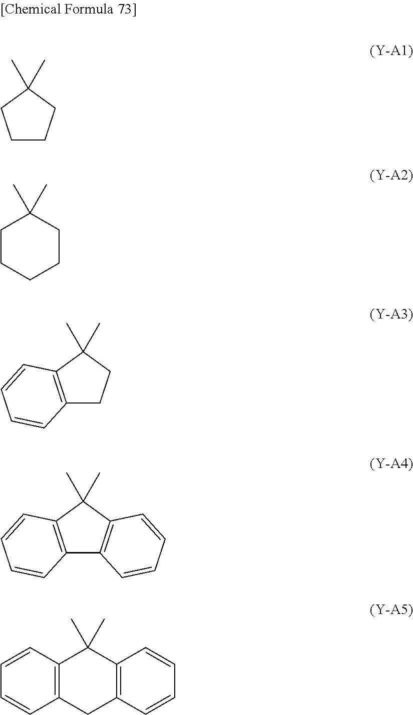

Regarding the combination of two R^{X2}s in the group represented by —C(R^{Y2})═C(R^{Y2})— in X^{Y1}, it is preferable that the both are an alkyl group or cycloalkyl group, or one is an alkyl group or a cycloalkyl group and the other is an aryl group, and these groups each optionally have a substituent.

Four R^{Y2}s in the group represented by —C(R^{Y2})₂—C(R^{Y2})₂— in X^{Y1} are preferably an alkyl group or a cycloalkyl group each optionally having a substituent. The plurality of R^{Y2} may be combined together to form a ring together with the atoms to which they are attached, and when the groups R^{Y2} form a ring, the group represented by —C(R^{Y2})₂—C(R^{Y2})₂— is preferably a group represented by the formula (Y-B1) to (Y-B5), more preferably a group represented by the formula (Y-B3), and these groups each optionally have a substituent.

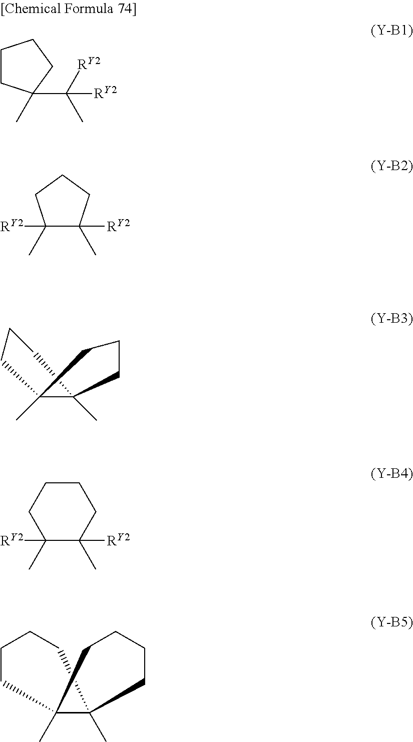

[wherein, R^{Y2} represents the same meaning as described above.]

It is preferable that the constitutional unit represented by the formula (Y-2) is a constitutional unit represented by the formula (Y-2′).

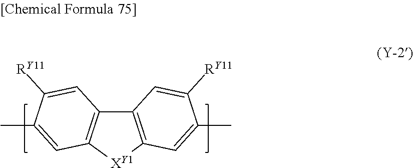

[wherein, R^{Y11} and X^{Y1} represent the same meaning as described above.]

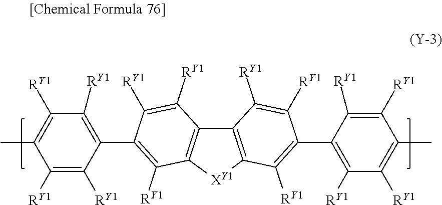

[wherein, R^{Y1} and X^{Y1} represent the same meaning as described above.]

It is preferable that the constitutional unit represented by the formula (Y-3) is a constitutional unit represented by the formula (Y-3′).

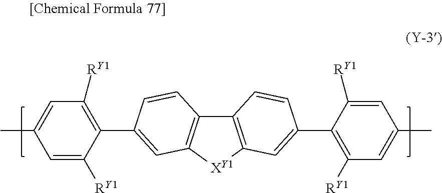

[wherein, R^{Y11} and X^{Y1} represent the same meaning as described above.]

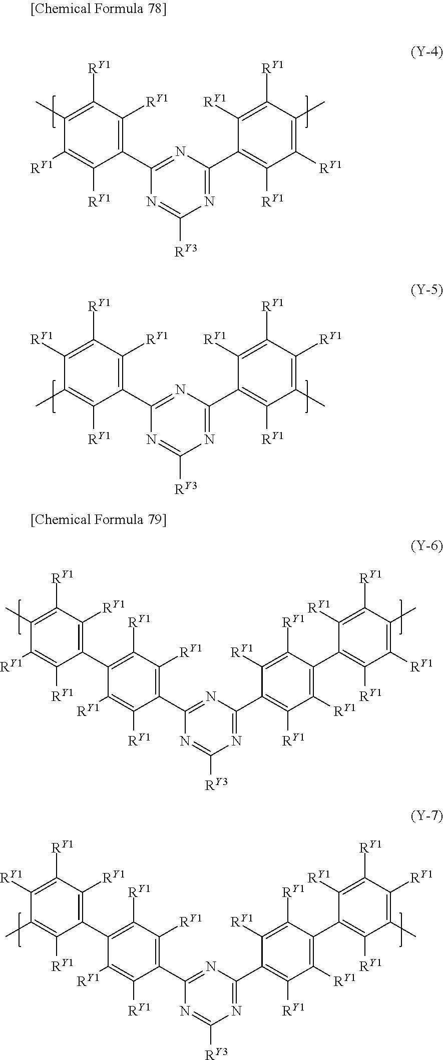

[wherein, R^{Y1} represents the same meaning as described above. R^{Y3} represents a hydrogen atom, an alkyl group, a cycloalkyl group, an alkoxy group, a cycloalkoxy group, an aryl group or a monovalent heterocyclic group and these groups each optionally have a substituent.]

R^{Y3} is preferably an alkyl group, a cycloalkyl group, an alkoxy group, a cycloalkoxy group, an aryl group or a monovalent heterocyclic group, more preferably an aryl group, and these groups each optionally have a substituent.

It is preferable that the constitutional unit represented by the formula (Y-4) is a constitutional unit represented by the formula (Y-4′), and it is preferable that the constitutional unit represented by the formula (Y-6) is a constitutional unit represented by the formula (Y-6′).

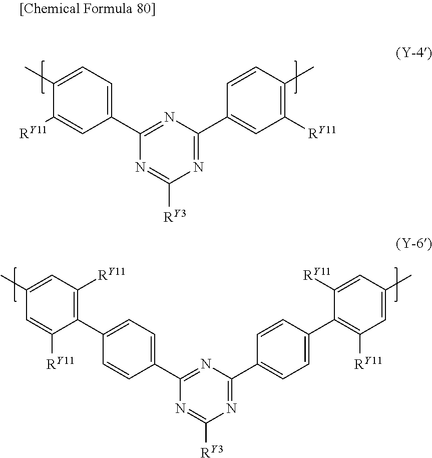

[wherein, R^{Y1} and R^{Y3} represent the same meaning as described above.]

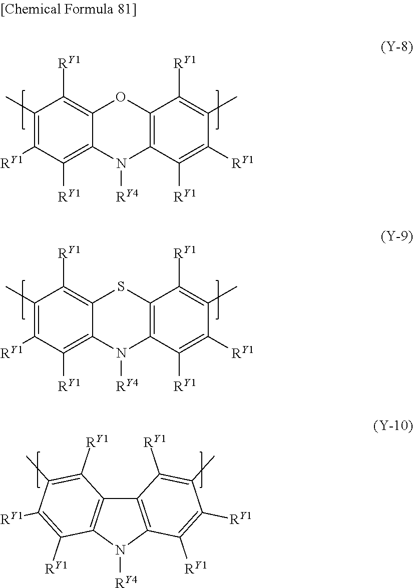

[wherein, R^{Y1} represents the same meaning as described above. R^{Y4} represents a hydrogen atom, an alkyl group, a cycloalkyl group, an alkoxy group, a cycloalkoxy group, an aryl group or a monovalent heterocyclic group, and these groups each optionally have a substituent.]

R^{Y4} is preferably an alkyl group, a cycloalkyl group, an alkoxy group, a cycloalkoxy group, an aryl group or a monovalent heterocyclic group, more preferably an aryl group, and these groups each optionally have a substituent.

The constitutional unit represented by the formula (Y) includes, for example, a constitutional unit composed of an arylene group represented by the formula (Y-101) to (Y-121), a constitutional unit composed of a divalent heterocyclic group represented by the formula (Y-201) to (Y-206), and a constitutional unit composed of a divalent group in which at least one arylene group and at least one divalent heterocyclic group are bonded directly to each other represented by the formula (Y-301) to (Y-304).

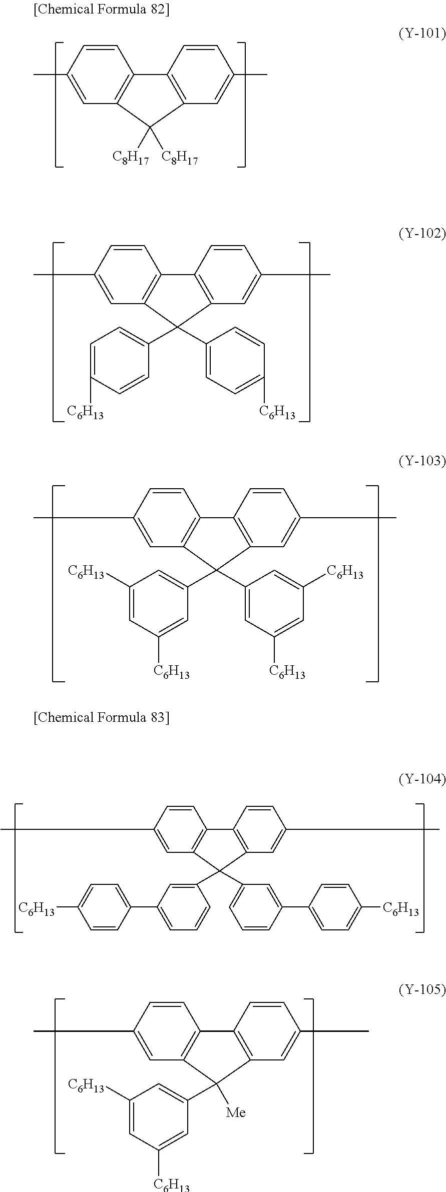

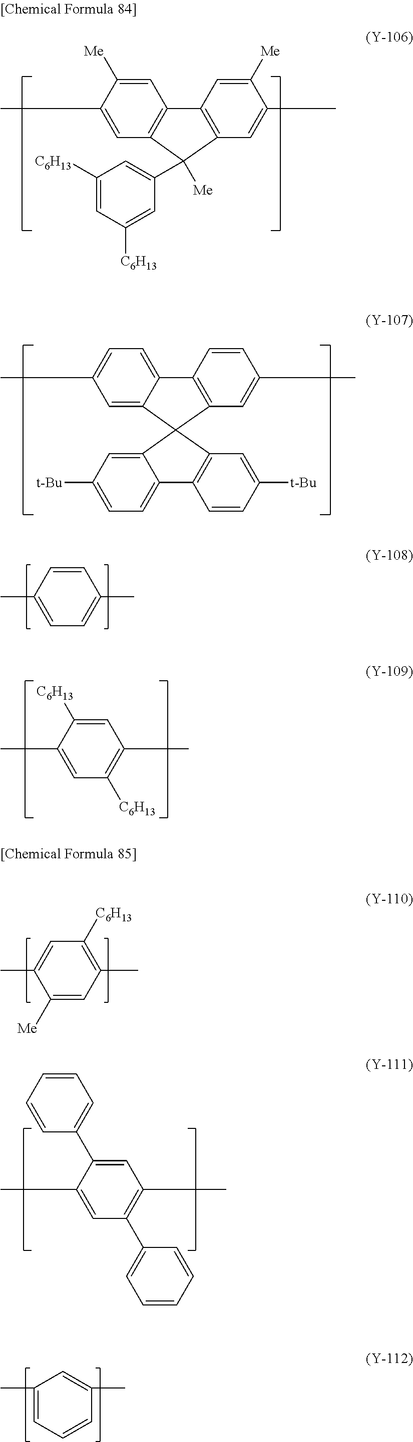

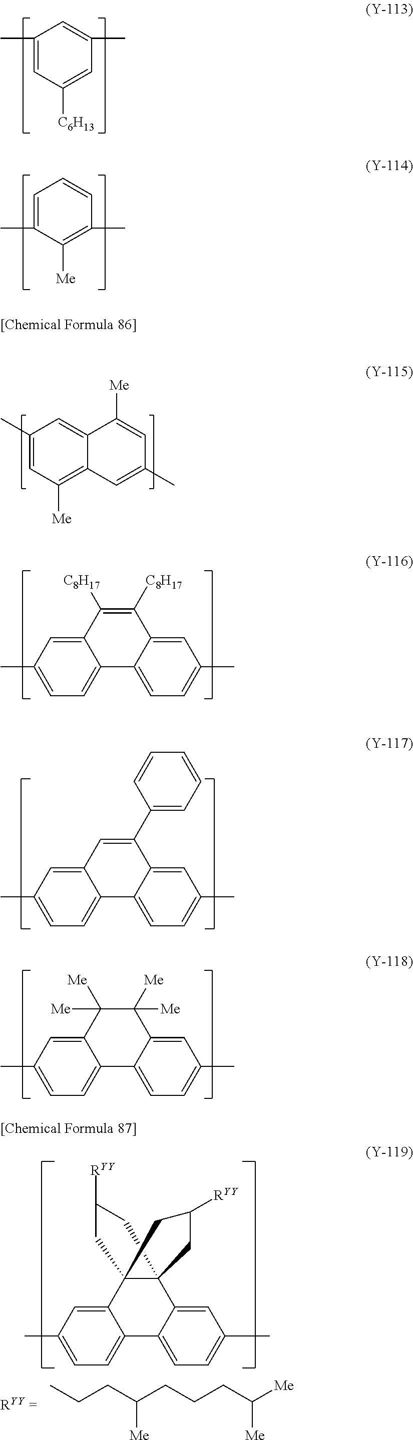

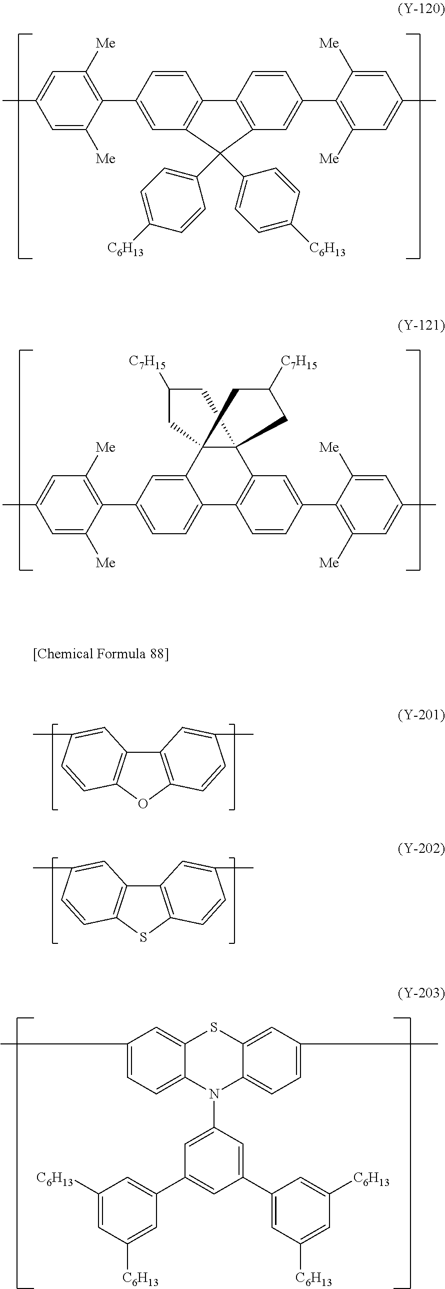

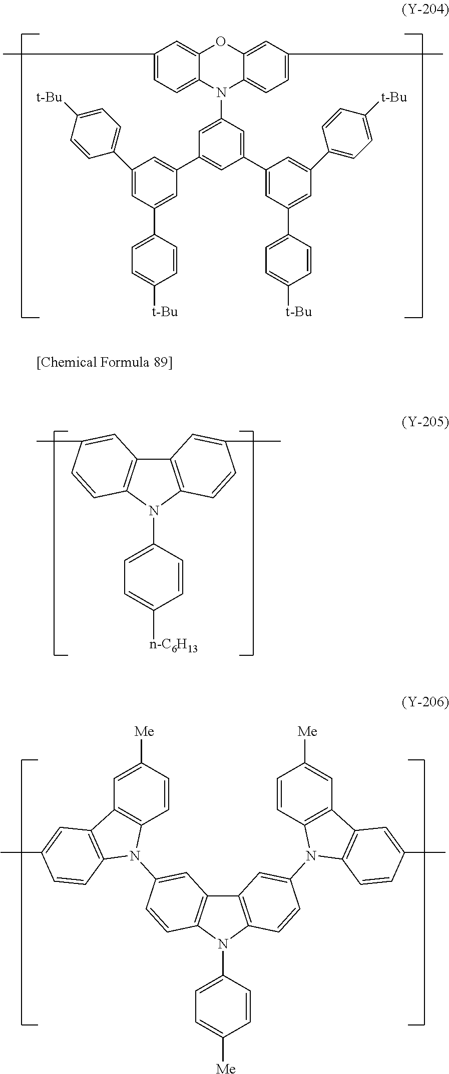

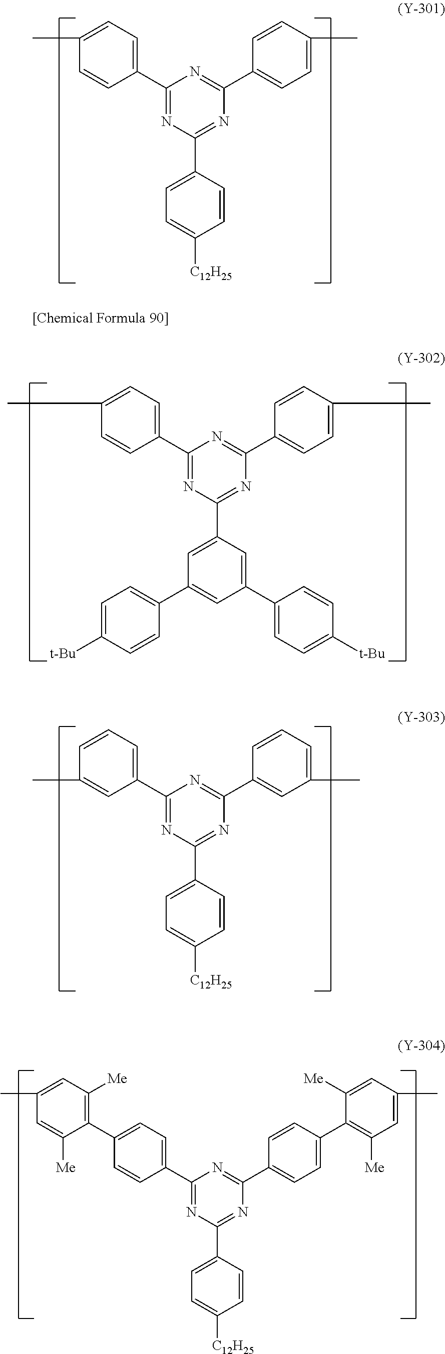

The amount of the constitutional unit represented by the formula (Y) in which Ar^{Y1} is an arylene group is preferably 0.5 to 80 mol %, more preferably 30 to 60 mol % with respect to the total amount of constitutional units contained in a polymer compound, because the luminance life of a light emitting device produced by using a composition comprising a polymer host and the metal complex of the present invention is excellent.

The amount of the constitutional unit represented by the formula (Y) in which Ar^{Y1} is a divalent heterocyclic group or a divalent group in which at least one arylene group and at least one divalent heterocyclic group are bonded directly to each other is preferably 0.5 to 30 mol %, more preferably 3 to 20 mol % with respect to the total amount of constitutional units contained in a polymer compound, because the charge transportability of a light emitting device produced by using a composition comprising a polymer host and the metal complex of the present invention is excellent.

The constitutional unit represented by the formula (Y) may be contained only singly or two or more units thereof may be contained in the polymer host.

It is preferable that the polymer host further comprises a constitutional unit represented by the following formula (X), because hole transportability is excellent.

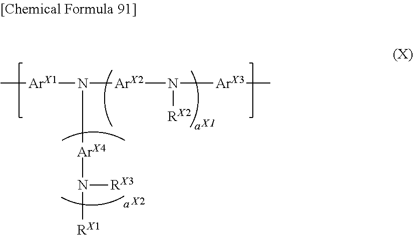

[wherein, a^{X1} and a^{X2} each independently represent an integer of 0 or more. Ar^{X1} and Ar^{X3} each independently represent an arylene group or a divalent heterocyclic group, and these groups each optionally have a substituent. Ar^{X2} and Ar^{X4} each independently represent an arylene group, a divalent heterocyclic group or a divalent group in which at least one arylene group and at least one divalent heterocyclic group are bonded directly to each other, and these groups each optionally have a substituent. R^{X1}, R^{X2} and R^{X3} each independently represent a hydrogen atom, an alkyl group, a cycloalkyl group, an aryl group or a monovalent heterocyclic group, and these groups each optionally have a substituent.]

a^{X1} is preferably 2 or less, more preferably 1, because the luminance life of a light emitting device produced by using a composition comprising a polymer host and the metal complex of the present invention is excellent.

a^{X2} is preferably 2 or less, more preferably 0, because the luminance life of a light emitting device produced by using a composition comprising a polymer host and the metal complex of the present invention is excellent.

R^{X1}, R^{X2} and R^{X3} are preferably an alkyl group, a cycloalkyl group, an aryl group or a monovalent heterocyclic group, more preferably an aryl group, and these groups each optionally have a substituent.

The arylene group represented by Ar^{X1} and Ar^{X3} is more preferably a group represented by the formula (A-1) or the formula (A-9), further preferably a group represented by the formula (A-1), and these groups each optionally have a substituent.

The divalent heterocyclic group represented by Ar^{X1} and Ar^{X3} is more preferably a group represented by the formula (AA-1), the formula (AA-2) or the formula (AA-7) to (AA-26), and these groups each optionally have a substituent.

Ar^{X1} and Ar^{X3} are preferably an arylene group optionally having a substituent.

The arylene group represented by Ar^{X2} and Ar^{X4} is more preferably a group represented by the formula (A-1), the formula (A-6), the formula (A-7), the formula (A-9) to (A-11) or the formula (A-19), and these groups each optionally have a substituent.

The more preferable range of the divalent heterocyclic group represented by Ar^{X2} and Ar^{X4} is the same as the more preferable range of the divalent heterocyclic group represented by Ar^{X1} and Ar^{X3}.

The more preferable range and the further preferable range of the arylene group and the divalent heterocyclic group in the divalent group in which at least one arylene group and at least one divalent heterocyclic group are bonded directly to each other represented by Ar^{X2} and Ar^{X4} are the same as the more preferable range and the further preferable range of the arylene group and the divalent heterocyclic group represented by Ar^{X1} and Ar^{X3}, respectively.

The divalent group in which at least one arylene group and at least one divalent heterocyclic group are bonded directly to each other represented by Ar^{X2} and Ar^{X4} includes the same groups as the divalent group in which at least one arylene group and at least one divalent heterocyclic group are bonded directly to each other represented by Ar^{Y1} in the formula (Y).

Ar^{X2} and Ar^{X4} are preferably an arylene group optionally having a substituent.

The substituent which the group represented by Ar^{X1} to Ar^{X4} and R^{X1} to R^{X3} optionally has is preferably an alkyl group, a cycloalkyl group or an aryl group, and these groups each optionally further have a substituent.

The constitutional unit represented by the formula (X) is preferably a constitutional unit represented by the formula (X-1) to (X-7), more preferably a constitutional unit represented by the formula (X-1) to (X-6), further preferably a constitutional unit represented by the formula (X-3) to (X-6).

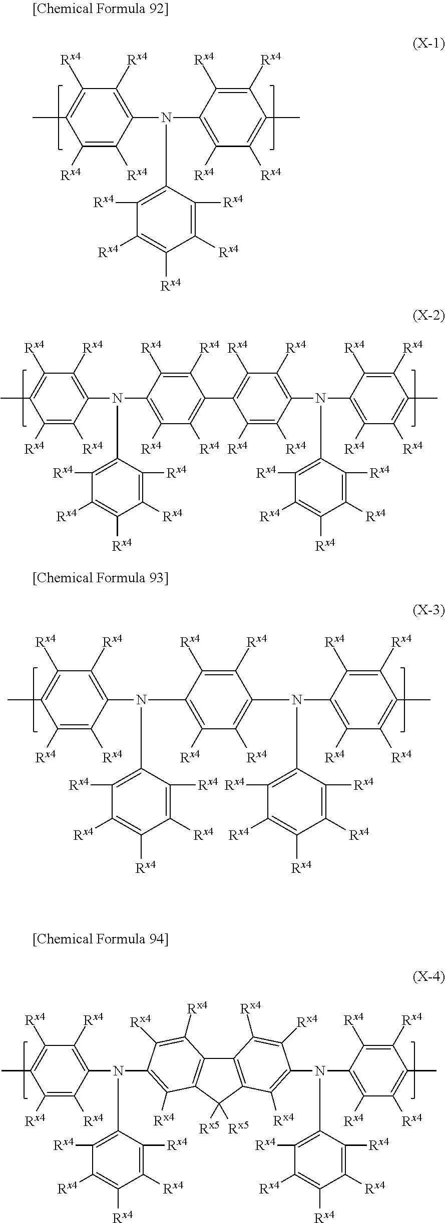

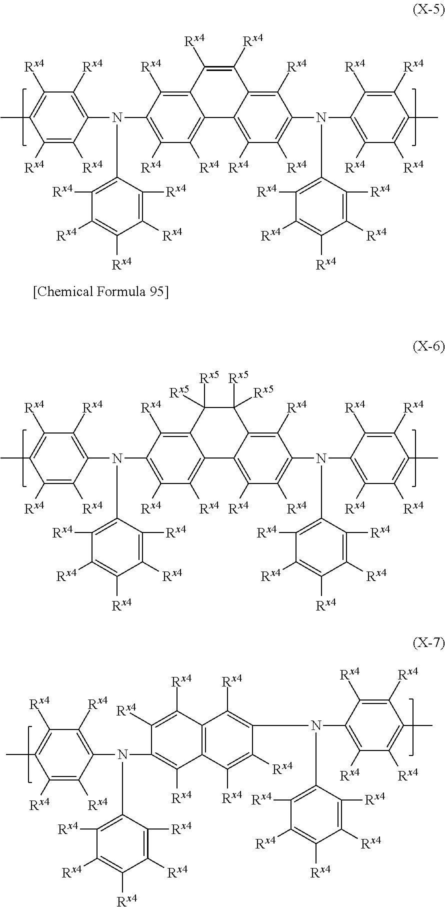

[wherein, R^{X4} and R^{X5} each independently represent a hydrogen atom, an alkyl group, a cycloalkyl group, an alkoxy group, a cycloalkoxy group, an aryl group, an aryloxy group, a halogen atom, a monovalent heterocyclic group or a cyano group, and these groups each optionally have a substituent. The plurality of R^{X4} may be the same or different. The plurality of R^{X5} may be the same or different, and adjacent groups R^{X5} may be combined together to form a ring together with the carbon atoms to which they are attached.]

The amount of the constitutional unit represented by the formula (X) is preferably 0.1 to 50 mol %, more preferably 1 to 40 mol %, further preferably 5 to 30 mol % with respect to the total amount of constitutional units contained in a polymer host, because hole transportability is excellent.

The constitutional unit represented by the formula (X) includes, for example, constitutional units represented by the formulae (X1-1) to (X1-11), preferably constitutional units represented by the formulae (X1-3) to (X1-10).

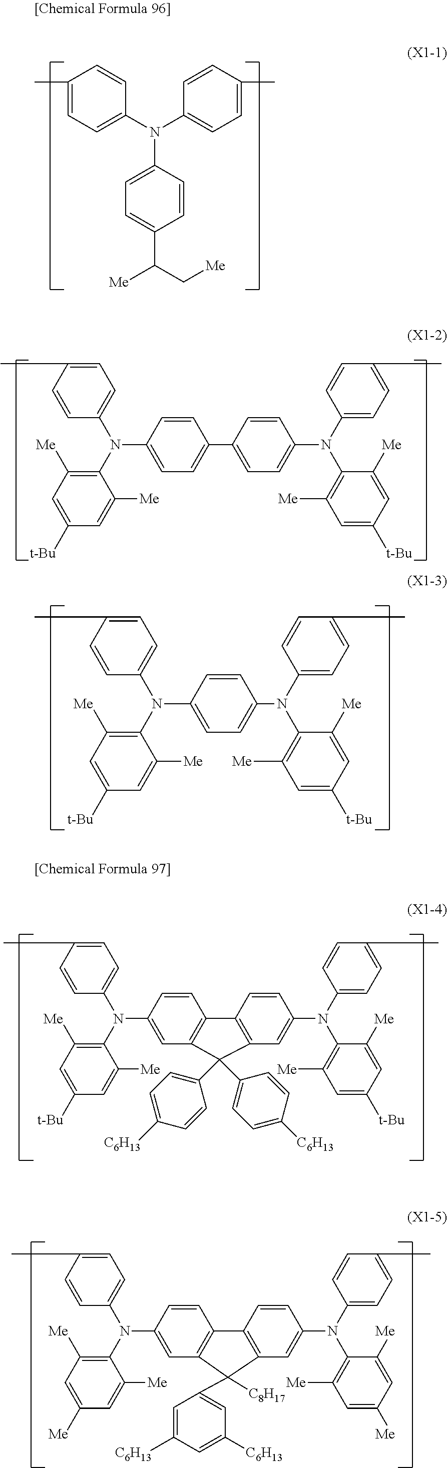

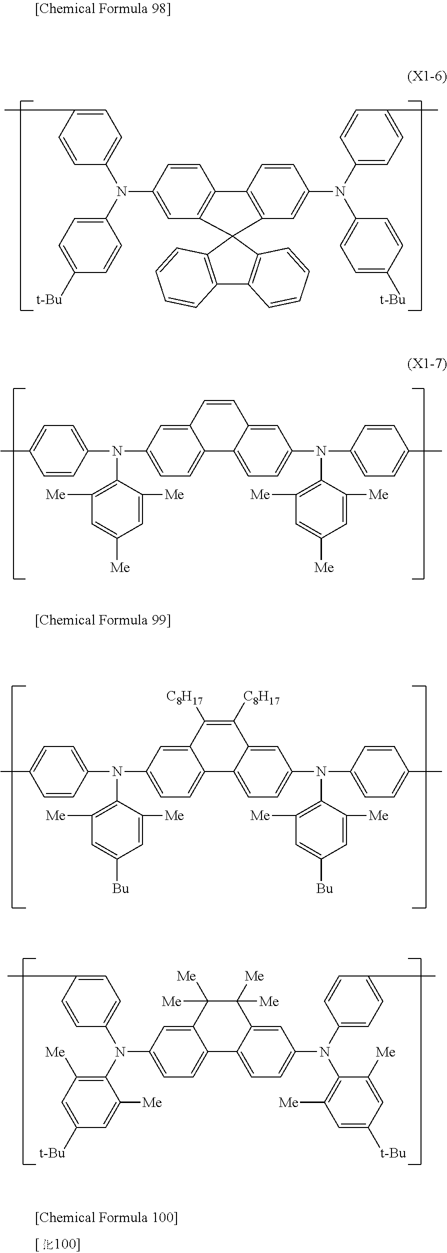

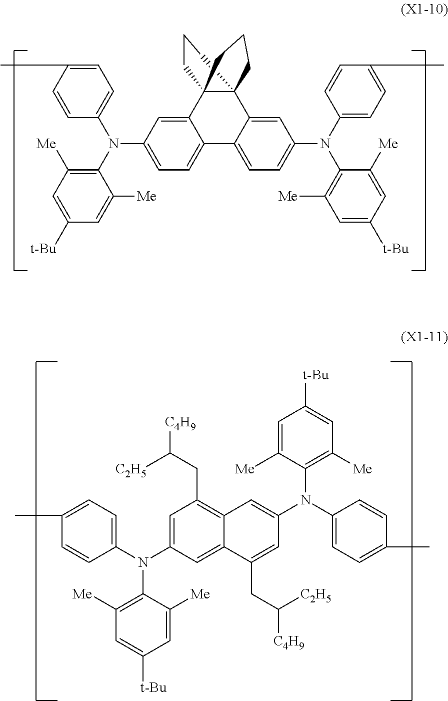

The constitutional unit represented by the formula (X) may be contained only singly or two or more units thereof may be contained in the polymer host.

Examples of the polymer host include polymer compounds (P-1) to (P-6) in Table 1. “Other” constitutional unit denotes a constitutional unit other than the constitutional unit represented by the formula (Y) and the constitutional unit represented by the formula (X).

TABLE 1

| | constitutional unit and mole fraction thereof | | | | |
|---|---|---|---|---|---|
| | formula (Y) | | | formula (X) | |
| | formulae | formulae | formulae | formulae | |
| | (Y-1) to | (Y-4) to | (Y-8) to | (X-1) to | |
| polymer | (Y-3) | (Y-7) | (Y-10) | (X-7) | other |
| compound | p | q | r | s | t |
| (P-1) | 0.1 to | 0.1 to | 0 | 0 | 0 to |
| | 99.9 | 99.9 | | | 30 |
| (P-2) | 0.1 to | 0 | 0.1 to | 0 | 0 to |
| | 99.9 | | 99.9 | | 30 |
| (P-3) | 0.1 to | 0.1 to | 0 | 0.1 to | 0 to |
| | 99.8 | 99.8 | | 99.8 | 30 |
| (P-4) | 0.1 to | 0.1 to | 0.1 to | 0 | 0 to |
| | 99.8 | 99.8 | 99.8 | | 30 |
| (P-5) | 0.1 to | 0 | 0.1 to | 0.1 to | 0 to |
| | 99.8 | | 99.8 | 99.8 | 30 |
| (P-6) | 0.1 to | 0.1 to | 0.1 to | 0.1 to | 0 to |
| | 99.7 | 99.7 | 99.7 | 99.7 | 30 |

[In the table, p, q, r, s and t represent the mole fraction of each constitutional unit. p+q+r+s+t=100, and 100≧p+q+r+s≧70. Other constitutional unit denotes a constitutional unit other than the constitutional unit represented by the formula (Y) and the constitutional unit represented by the formula (X).]

The polymer host may be any of a block copolymer, a random copolymer, an alternating copolymer or a graft copolymer, and may also be another embodiment, and is preferably a copolymer produced by copolymerizing a plurality of raw material monomers.

### <Production Method of Polymer Host>

The polymer host can be produced by using a known polymerization method described in Chem. Rev., vol. 109, pp. 897-1 091 (2009) and the like, and examples thereof include methods of causing polymerization by a coupling reaction using a transition metal catalyst such as the Suzuki reaction, the Yamamoto reaction, the Buchwald reaction, the Stille reaction, the Negishi reaction and the Kumada reaction.

In the above-described polymerization method, the method of charging monomers includes a method in which the total amount of monomers is charged in a lump into the reaction system, a method in which monomers are partially charged and reacted, then, the remaining monomers are charged in a lump, continuously or in divided doses, a method in which monomers are charged continuously or in divided doses, and the like.

The transition metal catalyst includes a palladium catalyst, a nicked catalyst and the like.

For the post treatment of the polymerization reaction, known methods, for example, a method of removing water-soluble impurities by liquid-separation, a method in which the reaction solution after the polymerization reaction is added to a lower alcohol such as methanol to cause deposition of a precipitate which is then filtered before drying, and other methods, are used each singly or combined. When the purity of the polymer host is low, the polymer host can be purified by usual methods such as, for example, recrystallization, reprecipitation, continuous extraction with a Soxhlet extractor and column chromatography.

The composition comprising the metal complex of the present invention and a solvent (hereinafter, referred to as “ink”) is suitable for fabrication of a light emitting device by using a printing method such as an inkjet printing method and a nozzle printing method.

The viscosity of the ink may be adjusted depending on the kind of the printing method, and when a solution goes through a discharge apparatus such as in an inkjet printing method, the viscosity is preferably in the range of 1 to 20 mPa·s at 25° C. because clogging in discharging and curved aviation are less likely to occur.

As the solvent contained in the ink, those capable of dissolving or uniformly dispersing solid components in the ink are preferable. The solvent includes, for example, chlorine-based solvents such as 1,2-dichloroethane, 1,1,2-trichloroethane, chlorobenzene and o-dichlorobenzene; ether solvents such as THF, dioxane, anisole and 4-methylanisole; aromatic hydrocarbon solvents such as toluene, xylene, mesitylene, ethylbenzene, n-hexylbenzene and cyclohexylbenzene; aliphatic hydrocarbon solvents such as cyclohexane, methylcyclohexane, n-pentane, n-hexane, n-heptane, n-octane, n-nonane, n-decane, n-dodecane and bicyclohexyl; ketone solvents such as acetone, methylethylketone, cyclohexanone and acetophenone; ester solvents such as ethyl acetate, butyl acetate, ethylcellosolve acetate, methyl benzoate and phenyl acetate; poly-hydric alcohols such as ethylene glycol, glycerin and 1,2-hexanediol and derivatives thereof; alcohol solvents such as isopropylalcohol and cyclohexanol; sulfoxide solvents such as dimethyl sulfoxide; and amide solvents such as N-methyl-2-pyrrolidone and N,N-dimethylformamide. These solvents may be used singly or two or more of them may be used in combination.

In the ink, the compounding amount of the solvent is usually 1000 to 100000 parts by weight, preferably 2000 to 20000 parts by weight with respect to 100 parts by weight of the metal complex of the present invention.

### [Hole Transporting Material]

The hole transporting material is classified into low molecular weight compounds and polymer compounds, and is preferably polymer compounds, more preferably polymer compounds having a crosslinkable group.

The polymer compound includes, for example, polyvinylcarbazole and derivatives thereof; polyarylene having an aromatic amine structure in the side chain or main chain and derivatives thereof. The polymer compound may also be a compound in which an electron accepting portion is linked. The electron accepting portion includes, for example, fullerene, tetrafluorotetracyanoquinodimethane, tetracyanoethylene, trinitrofluorenone, preferably fullerene.

In the composition of the present invention, the compounding amount of the hole transporting material is usually 1 to 400 parts by weight, preferably 5 to 150 parts by weight with respect to 100 parts by weight of the metal complex of the present invention.

The hole transporting material may be used singly or two or more hole transporting materials may be used in combination.

### [Electron Transporting Material]

The electron transporting material is classified into low molecular weight compounds and polymer compounds. The electron transporting material optionally has a crosslinkable group.

The low molecular weight compound includes, for example, a metal complex having 8-hydroxyquinoline as a ligand, oxadiazole, anthraquinodimethane, benzoquinone, naphthoquinone, anthraquinone, tetracyanoanthraquinodimethane, fluorenone, diphenyldicyanoethylene, diphenoquinone and derivatives thereof.

The polymer compound includes, for example, polyphenylene, polyfluorene and derivatives thereof. These polymer compounds may be doped with a metal.

In the composition of the present invention, the compounding amount of the electron transporting material is usually 1 to 400 parts by weight, preferably 5 to 150 parts by weight with respect to 100 parts by weight of the metal complex of the present invention.

The electron transporting material may be used singly or two or more electron transporting materials may be used in combination.

### [Hole Injection Material and Electron Injection Material]

The hole injection material and the electron injection material are each classified into low molecular weight compounds and polymer compounds. The hole injection material and the electron injection material optionally have a crosslinkable group.

The low molecular weight compound includes, for example, metal phthalocyanines such as copper phthalocyanine; carbon; oxides of metals such as molybdenum and tungsten; metal fluorides such as lithium fluoride, sodium fluoride, cesium fluoride and potassium fluoride.

The polymer compound includes, for example, polyaniline, polythiophene, polypyrrole, polyphenylenevinylene, polythienylenevinylene, polyquinoline and polyquinoxaline, and derivatives thereof; electrically conductive polymers such as a polymer comprising an aromatic amine structure in the side chain or main chain.

In the composition of the present invention, the compounding amounts of the hole injection material and the electron injection material are each usually 1 to 400 parts by weight, preferably 5 to 150 parts by weight with respect to 100 parts by weight of the metal complex of the present invention.

The hole injection material and the electron injection material may each be used singly or two or more of them may be used in combination.

### [Ion Dope]

When the hole injection material or the electron injection material comprises an electrically conductive polymer, the electric conductivity of the electrically conductive polymer is preferably 1×10⁻⁵ S/cm to 1×10³ S/cm. For adjusting the electric conductivity of the electrically conductive polymer within such a range, the electrically conductive polymer can be doped with a suitable amount of ions.

The kind of the ion to be doped is an anion for a hole injection material and a cation for an electron injection material. The anion includes, for example, a polystyrenesulfonate ion, an alkylbenzenesulfonate ion and a camphorsulfonate ion. The cation includes, for example, a lithium ion, a sodium ion, a potassium ion and a tetrabutylammonium ion.

The ion to be doped may be used singly or two or more ions to be doped may be used.

### [Light Emitting Material]

The light emitting material (the light emitting material is different form the metal complex of the present invention) is classified into low molecular weight compounds and polymer compounds. The light emitting material optionally has a crosslinkable group.

The low molecular weight compound includes, for example, naphthalene and derivatives thereof, anthracene and derivatives thereof, perylene and derivatives thereof, and, triplet light emitting complexes having iridium, platinum or europium as the central metal.

The polymer compound includes, for example, polymer compounds comprising a phenylene group, a naphthalenediyl group, a fluorenediyl group, a phenanthrenediyl group, dihydrophenanthrenediyl group, a group represented by the formula (X), a carbazolediyl group, a phenoxazinediyl group, a phenothiazinediyl group, an anthracenediyl group, a pyrenediyl group and the like.

The light emitting material preferably comprises a triplet light emitting complex and a polymer compound.

The triplet light emitting complex includes, for example, metal complexes listed below.

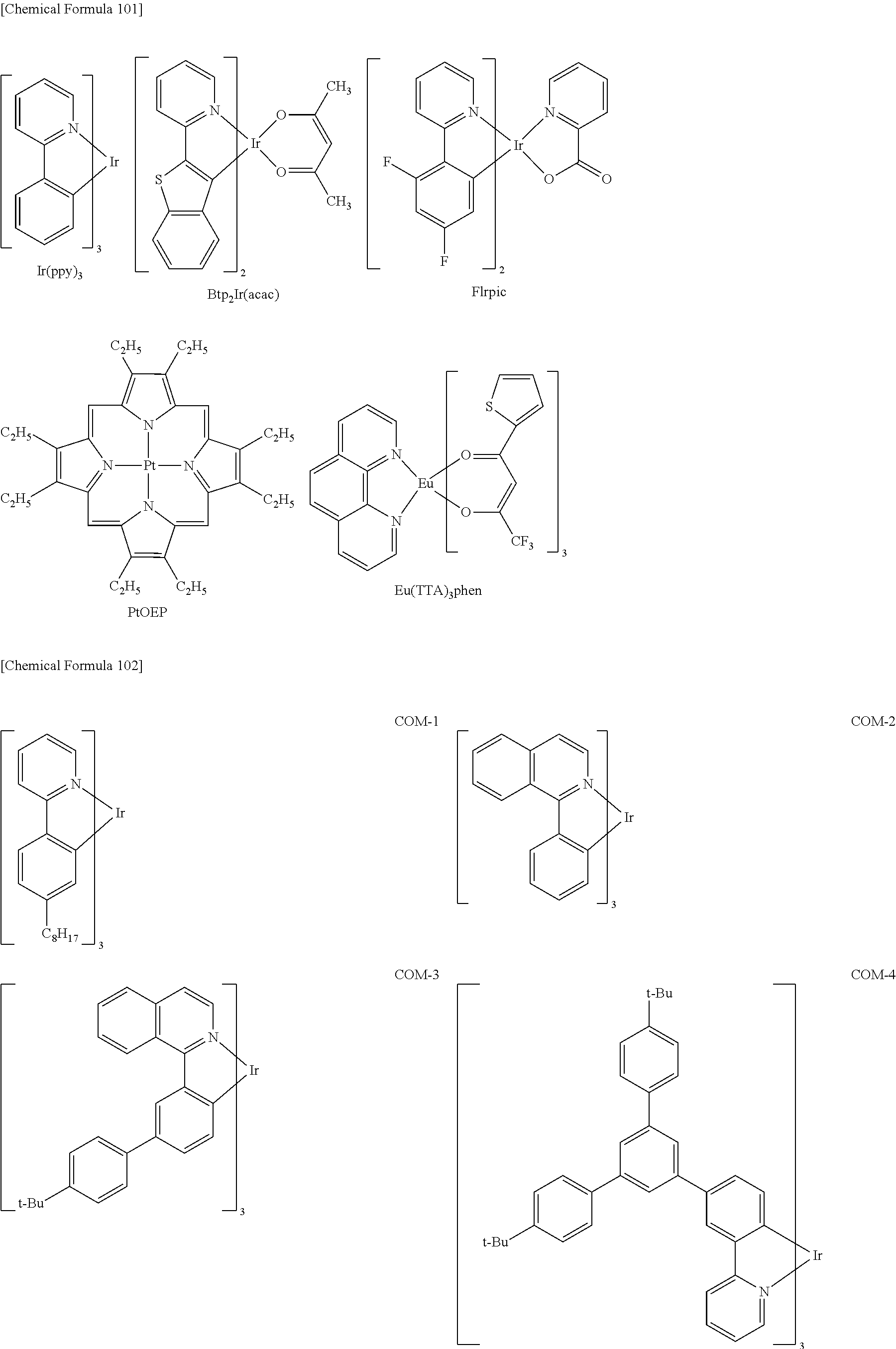

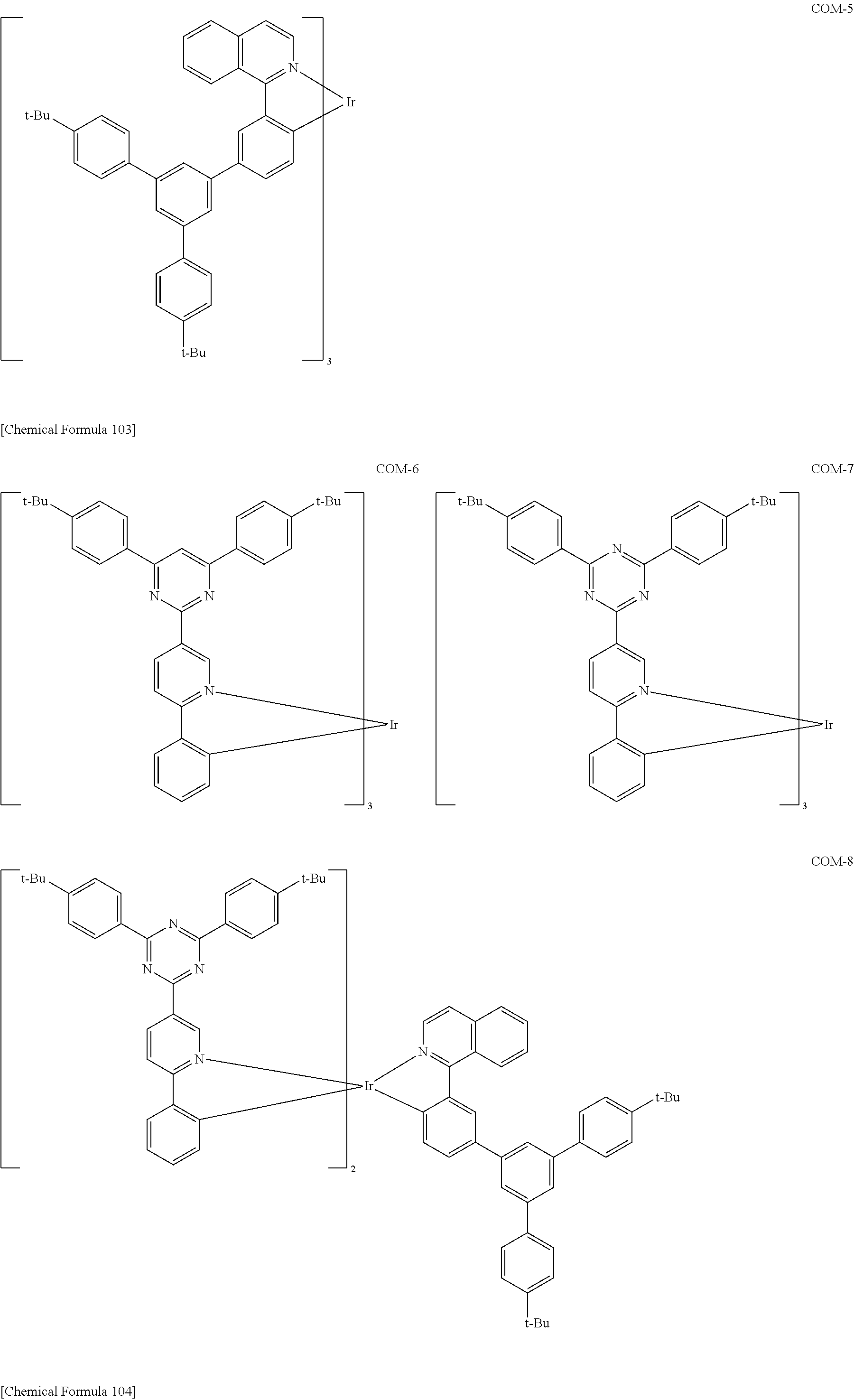

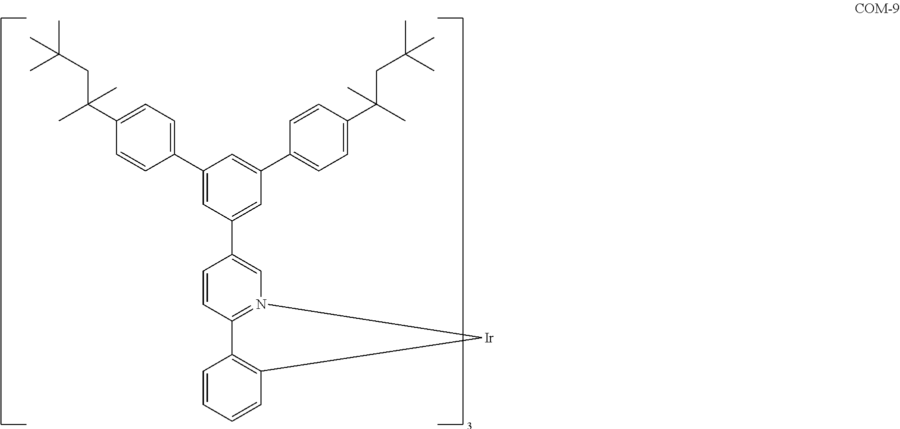

In the composition of the present invention, the compounding amount of the light emitting material is usually 0.1 to 400 parts by weight with respect to 100 parts by weight of the metal complex of the present invention.

### [Antioxidant]

The antioxidant may advantageously be one which is soluble in the same solvent as for the metal complex of the present invention and does not disturb light emission and charge transportation, and the examples thereof include phenol antioxidants and phosphorus-based antioxidants.

In the composition of the present invention, the compounding amount of the antioxidant is usually 0.001 to 10 parts by weight with respect to 100 parts by weight of the metal complex of the present invention.

The antioxidant may be used singly or two or more antioxidants may be used in combination.

### <Film>

The film comprises the metal complex of the present invention.

The film also includes an insolubilized film produced by insolubilizing the metal complex of the present invention in a solvent by crosslinking. The insolubilized film is a film produced by crosslinking the metal complex of the present invention by an external stimulus such as heating and light irradiation. The insolubilized film can be suitably used for lamination of a light emitting device because the insolubilized film is substantially insoluble in a solvent.

The heating temperature for crosslinking the film is usually 25 to 300° C., and because the external quantum efficiency is improved, preferably 50 to 250° C., more preferably 150 to 200° C.

The kind of light used in light irradiation for crosslinking the film includes, for example, ultraviolet light, near-ultraviolet light and visible light.

The film is suitable as a light emitting layer in a light emitting device.

The film can be fabricated, for example, by a spin coating method, a casting method, a micro gravure coating method, a gravure coating method, a bar coating method, a roll coating method, a wire bar coating method, a dip coating method, a spray coating method, a screen printing method, a flexo printing method, an offset printing method, an inkjet printing method, a capillary coating method or a nozzle coating method, using the ink.

The thickness of the film is usually 1 nm to 10 μm.

### <Light Emitting Device>

The light emitting device of the present invention is a light emitting device obtained by using the metal complex of the present invention. The light emitting device is, for example, a light emitting device containing the metal complex of the present invention or a light emitting device obtained by crosslinking the metal complex of the present invention intramolecularly, intermolecularly or in both modes when the metal complex of the present invention has a crosslinkable group, and, for example, a light emitting device containing the metal complex of the present invention when the metal complex of the present invention has no crosslinkable group.

The constitution of the light emitting device of the present invention has, for example, electrodes consisting of an anode and a cathode, and a layer obtained by using the metal complex of the present invention disposed between the electrodes.

### [Layer Constitution]

The layer produced by using the metal complex of the present invention is usually at least one selected from a light emitting layer, a hole transporting layer, a hole injection layer, an electron transporting layer and an electron injection layer, preferably a light emitting layer. These layers comprise a light emitting material, a hole transporting material, a hole injection material, an electron transporting material and an electron injection material, respectively. These layers can be formed by the same method as the above-described film fabrication using inks prepared by dissolving a light emitting material, a hole transporting material, a hole injection material, an electron transporting material and an electron injection material, respectively, in the solvent described above.

The light emitting device comprises a light emitting layer between an anode and a cathode. The light emitting device of the present invention preferably comprises at least one of a hole injection layer and a hole transporting layer between an anode and a light emitting layer from the standpoint of hole injectability and hole transportability, and preferably comprises at least one of an electron injection layer and an electron transporting layer between a cathode and a light emitting layer from the standpoint of electron injectability and electron transportability.

The material of a hole transporting layer, an electron transporting layer, a light emitting layer, a hole injection layer and an electron injection layer includes the above-described hole transporting materials, electron transporting materials, light emitting materials, hole injection materials and electron injection materials, respectively, in addition to the metal complex of the present invention.

When the material of a hole transporting layer, the material of an electron transporting layer and the material of a light emitting layer are soluble in a solvent which is used in forming a layer adjacent to the hole transporting layer, the electron transporting layer and the light emitting layer, respectively, in fabrication of a light emitting device, it is preferable that the materials have a crosslinkable group to avoid dissolution of the materials in the solvent. After forming the layers using the materials having a crosslinkable group, the layers can be insolubilized by crosslinking the crosslinkable group.

Methods of forming respective layers such as a light emitting layer, a hole transporting layer, an electron transporting layer, a hole injection layer and an electron injection layer in the light emitting device of the present invention include, for example, a method of vacuum vapor deposition from a powder and a method of film formation from solution or melted state when a low molecular weight compound is used, and, for example, a method of film formation from solution or melted state when a polymer compound is used.

The order and the number of layers to be laminated and the thickness of each layer may be controlled in view of external quantum efficiency and luminance life.

### [Substrate/Electrode]

The substrate in the light emitting device may advantageously be a substrate on which an electrode can be formed and which does not chemically change in forming an organic layer, and is a substrate made of a material such as, for example, glass, plastic and silicon. In the case of an opaque substrate, it is preferable that an electrode most remote from the substrate is transparent or semi-transparent.

The material of the anode includes, for example, electrically conductive metal oxides and semi-transparent metals, preferably, indium oxide, zinc oxide and tin oxide; electrically conductive compounds such as indium-tin-oxide (ITO) and indium.zinc.oxide; a composite of silver, palladium and copper (APC); NESA, gold, platinum, silver and copper.

The material of the cathode includes, for example, metals such as lithium, sodium, potassium, rubidium, cesium, beryllium, magnesium, calcium, strontium, barium, aluminum, zinc and indium; alloys composed of two or more of them; alloys composed of one or more of them and at least one of silver, copper, manganese, titanium, cobalt, nickel, tungsten and tin; and graphite and graphite intercalation compounds. The alloy includes, for example, a magnesium-silver alloy, a magnesium-indium alloy, a magnesium-aluminum alloy, an indium-silver alloy, a lithium-aluminum alloy, a lithium-magnesium alloy, a lithium-indium alloy and a calcium-aluminum alloy.

The anode and the cathode may each take a lamination structure composed of two or more layers.

### [Use]

For producing planar light emission by using a light emitting device, a planar anode and a planar cathode are disposed so as to overlap with each other. Patterned light emission can be produced by a method of placing a mask with a patterned window on the surface of a planer light emitting device, a method of forming extremely thick a layer intended to be a non-light emitting, thereby having the layer essentially no-light emitting or a method of forming an anode, a cathode or both electrodes in a patterned shape. By forming a pattern with any of these methods and disposing certain electrodes so as to switch ON/OFF independently, a segment type display capable of displaying numbers and letters and the like is provided. For producing a dot matrix display, both an anode and a cathode are formed in a stripe shape and disposed so as to cross with each other. Partial color display and multi-color display are made possible by a method of printing separately certain polymer compounds showing different emission or a method of using a color filter or a fluorescence conversion filter. The dot matrix display can be passively driven, or actively driven combined with TFT and the like. These displays can be used in computers, television sets, portable terminals and the like. The planar light emitting device can be suitably used as a planer light source for backlight of a liquid crystal display or as a planar light source for illumination. If a flexible substrate is used, it can be used also as a curved light source and a curved display.

### Examples

The present invention will be illustrated further in detail by examples below, but the present invention is not limited to these examples.

In the examples, the polystyrene-equivalent number average molecular weight (Mn) and the polystyrene-equivalent weight average molecular weight (Mw) of a polymer compound were measured by size exclusion chromatography (SEC) (manufactured by Shimadzu Corp., trade name: LC-10Avp). SEC measurement conditions are as described below.

### [Measurement Condition]

The polymer compound to be measured was dissolved in THF at a concentration of about 0.05 wt %, and 10 μL of the solution was injected into SEC. As the mobile phase of SEC, THF was used and allowed to flow at a flow rate of 2.0 mL/min. As the column, PLgel MIXED-B (manufactured by Polymer Laboratories) was used. As the detector, UV-VIS detector (manufactured by Shimadzu Corp., trade name: SPD-10Avp) was used.

Measurement of liquid chromatograph mass spectrometry (LC-MS) was carried out according to the following method.

A measurement sample was dissolved in chloroform or THF so as to give a concentration of about 2 mg/mL, and about 1 μL of the solution was injected into LC-MS (manufactured by Agilent Technologies, trade name: 1100LCMSD). As the mobile phase of LC-MS, acetonitrile and THF were used while changing the ratio thereof and allowed to flow at a flow rate of 0.2 mL/min. As the column, L-column 2 ODS (3 μm) (manufactured by Chemicals Evaluation and Research Institute, internal diameter: 2.1 mm, length: 100 mm, particle size: 3 μm) was used.

Measurement of NMR was carried out according to the following method.

5 to 10 mg of a measurement sample was dissolved in about 0.5 mL of deuterated chloroform (CDCl₃-d₁), deuterated dichloromethane (CD₂Cl-d₂), deuterated tetrahydrofuran (THF-d₈) or deuterated acetone ((CD₃)₂CO-d₆), and measurement was performed using an NMR apparatus (manufactured by Agilent, Inc., trade name: INOVA 300 or MERCURY 300).

As the index of the purity of a compound, a value of the high performance liquid chromatography (HPLC) area percentage was used. This value is a value in HPLC (manufactured by Shimadzu Corp., trade name: LC-20A) at 254 nm, unless otherwise stated. In this operation, the compound to be measured was dissolved in THF or chloroform so as to give a concentration of 0.01 to 0.2 wt %, and depending on the concentration, 1 to 10 μL of the solution was injected into HPLC. As the mobile phase of HPLC, acetonitrile and THF were used and allowed to flow at a flow rate of 1 mL/min as gradient analysis of acetonitrile/THF=100/0 to 0/100 (volume ratio). As the column, Kaseisorb LC ODS 2000 (manufactured by Tokyo Chemical Industry Co., Ltd.) or an ODS column having an equivalent performance was used. As the detector, a photo diode array detector (manufactured by Shimadzu Corp., trade name: SPD-M20A) was used.

TLC-MS measurement was performed by the following method.

A measurement sample was dissolved in toluene, tetrahydrofuran or chloroform, the solution was applied on a TLC plate for DART (manufactured by Techno Applications, YSK5-100), and measurement was performed using TLC-MS (manufactured by JEOL Ltd., trade name: JMS-T100TD (The AccuTOF TLC)). The temperature of a helium gas in measurement was controlled in a range of 200 to 400° C.

### <Evaluation of Light Emission Stability>

### [Apparatus for Evaluating Light Emission Stability]

In an apparatus for evaluating light emission stability, a measurement sample described later was irradiated with excitation light from the glass substrate side, thereby causing light emission of an organic layer contained in the measurement sample. As the excitation light source, Lightningcure LC-L1V3 (wavelength: 365 nm) manufactured by Hamamatsu Photonics K.K. was used. For measurement of light emission from the measurement sample, BM-9 manufactured by TOPCON Corporation as the light emission luminance measurement apparatus was used. At a photometric incident entrance of the light emission luminance measurement apparatus, a short wavelength-impermeable filter was installed, thereby blocking measurement of light having a wavelength of 400 nm or less.

### [Regulation of Excitation Light Intensity of Excitation Light Source]

In evaluation of light emission stability, the excitation light intensity of an excitation light source was regulated in such a manner that the numbers of photons of light emission from respective measurement samples described later were the same.

The formula (11), the formula (12), the formula (13-1), the formula (13-2), the formula (14), the formula (15), the formula (16) and the formula (17) were used, for calculating conditions under which the numbers of photons of light emission from respective measurement samples were the same.

Firstly, the number of photons of light emission from a measurement sample was calculated by the formula (11). Int_{PL} (A) indicating the light emission spectrum intensity was measured by FP-6500 manufactured by JASCO Corporation using a sample obtained by forming an organic layer contained in a measurement sample described later on a quartz substrate.

$${N}_{PL} = {\sum }_{λ} \frac{{Int}_{PL} ( λ ) \times λ}{1240 \times 1.6 \times {10}^{- 19}} \qquad Formula ( 11 )$$

[wherein,

N_{PL} represents the number of photons of light emission.

λ represents wavelength [nm].

Int^{PL}(λ) represents light emission spectrum intensity [W].]

Secondly, N_{PL} indicating the number of photons of light emission calculated by the formula (11) was rewritten to the formula (12).

N_{PL}=κᵢₙₜ×n_{nrm-PL} Formula (12)

[wherein,

N_{PL} represents the same meaning as described above.

Kᵢₙₜ represents proportionality factor.

n_{nrm-PL} represents standardized photon number.)]

n_{nrm-PL} indicating standardized photon number in the formula (12) was calculated by the formula (13-1).

$${n}_{nrm - PL} = {\sum }_{λ} \frac{{Int}_{nrm - PL} ( λ ) \times λ}{1240 \times 1.6 \times {10}^{- 19}} \qquad Formula ( 13 \text{-} 1 )$$

[wherein,

λ and n_{nrm-PL} represent the same meaning as described above.

Int_{nrm-PL} (λ) represents standardized emission spectrum.]

Int_{nrm-PL}(λ) indicating standardized emission spectrum in the formula (13-1) was calculated by the formula (13-2).

Int_{nrm-PL}(λ)=Int_{PL}(λ)/max(Int_{PL}(λ)) Formula (1.3-2)

[wherein, λ, Int_{nrm-PL}(λ) and Int_{PL}(λ) represent the same meaning as described above.)

Thirdly, standardized luminance was calculated from the formula (14) using Int_{nrm-PL}(λ) indicating standardized emission spectrum.

$${l}_{nrm} = {\sum }_{λ} ( {Int}_{nrm - PL} ( λ ) \cdot Lf ( λ ) ) \qquad Formula ( 14 )$$

[wherein,

λ and Int_{nrm-PL}(λ) represent the same meaning as described above.]

lₙᵣₘ represents standardized luminance.

Lf(λ) represents luminosity spectrum.]

Fourthly, light emission luminance was calculated from the formula (15) using lᵣₙₘ indicating standardized luminance.

$${L}_{PL} = {\sum }_{λ} ( {Int}_{PL} ( λ ) \times Lf ( λ ) ) = {κ}_{int} \times {\sum }_{λ} ( {Int}_{nrm - PL} ( λ ) \times Lf ( λ ) ) = {κ}_{int} \times {l}_{nrm} \qquad Formula ( 15 )$$

[wherein,

L_{PL} represents light emission luminance [cd/m²].

λ, Int_{PL}(λ), Lf(λ), Kᵢₙₜ, Int_{nrm-PL}(λ) and lₙᵣₘ represent the same meaning as described above.)

Fifthly, conditions under which the numbers of photons of light emission were the same were calculated from the formula (16) using the formula (12) and the formula (15). By using this formula (16), light emission luminances of measurement samples satisfying conditions under which the numbers of photons of light emission from measurement samples are the same can be calculated.

N_{PL}=κᵢₙₜ×n_{nrm-PL}=constant

Conditions for constant photon number of light emission [wherein, N_{PL}, Kᵢₙₜ and n_{nrm-PL} represent the same meaning as described above.]

$${L}_{eqv} [ cd / {m}^{2} ] = constant \times \frac{{l}_{nrm}}{{n}_{nrm - PL}} = {κ}_{int} \times {l}_{nrm} \qquad Formula ( 16 )$$

[wherein,

L_{eqv} represents light emission luminance [cd/m²].

lₙᵣₘ, n_{nrm-PL} and Kᵢₙₜ represent the same meaning as described above.]

For example, when a sample A is allowed to emit light at luminance L^{A}, the light emission luminance of a sample B at which the photon number of light emission is the same as that of a sample A can be calculated from the formula (17) using the standardized photon numbers and the standardized luminances of a sample A and a sample B

$${L}^{B} [ cd / {m}^{2} ] = {L}^{A} \times \frac{{n}_{nrm - PL}^{A}}{{l}_{nrm}^{A}} \times \frac{{l}_{nrm}^{B}}{{n}_{nrm - PL}^{B}} \qquad Formula ( 17 )$$

[wherein,

L^{A} represents the light emission luminance [cd/m²] of a sample A.

L^{B} represents the light emission luminance [cd/m²] of a sample B.

n_{nrm-PL}^{A} represents the standardized photon number of a sample A.

n_{nrm-PL}^{B} represents the standardized photon number of a sample B.

l^{A}ₙᵣₘ represents the standardized luminance of a sample A.

l^{B}ₙᵣₘ represents the standardized luminance of a sample B.]

### <Comparative Example 1> Synthesis of Metal Complex MM1

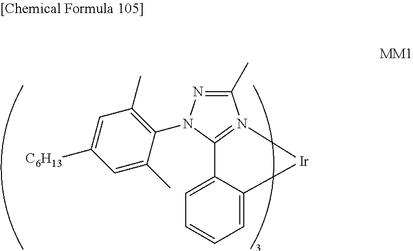

The metal complex MM1 was synthesized according to a method described in US Patent Application Publication No. 2014/0151659.

### <Comparative Example 2> Synthesis of Metal Complex MM2

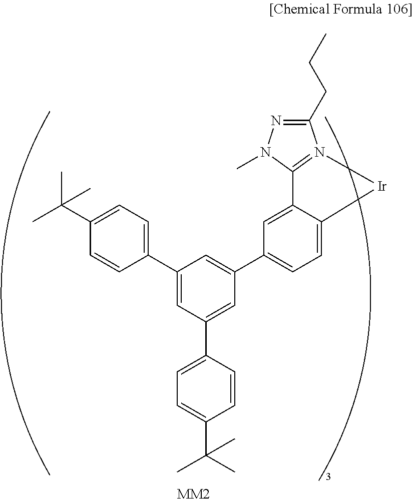

The metal complex MM2 was synthesized according to a method described in JP-A No. 2013-147551.

### <Comparative Example 3> Synthesis of Metal Complex MM3

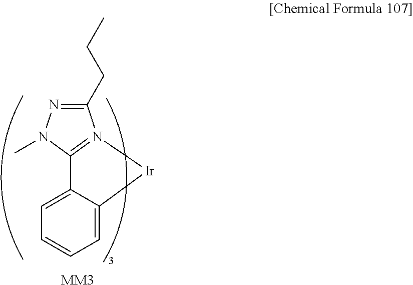

The metal complex MM3 was synthesized according to a method described in JP-A No. 2013-147551.

### <Example 1> Synthesis of Metal Complex MC1

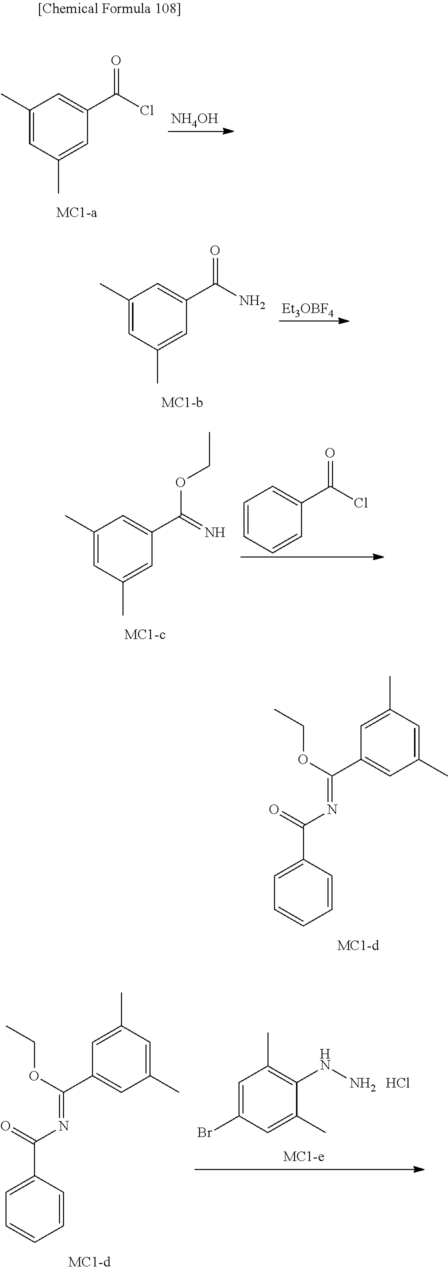

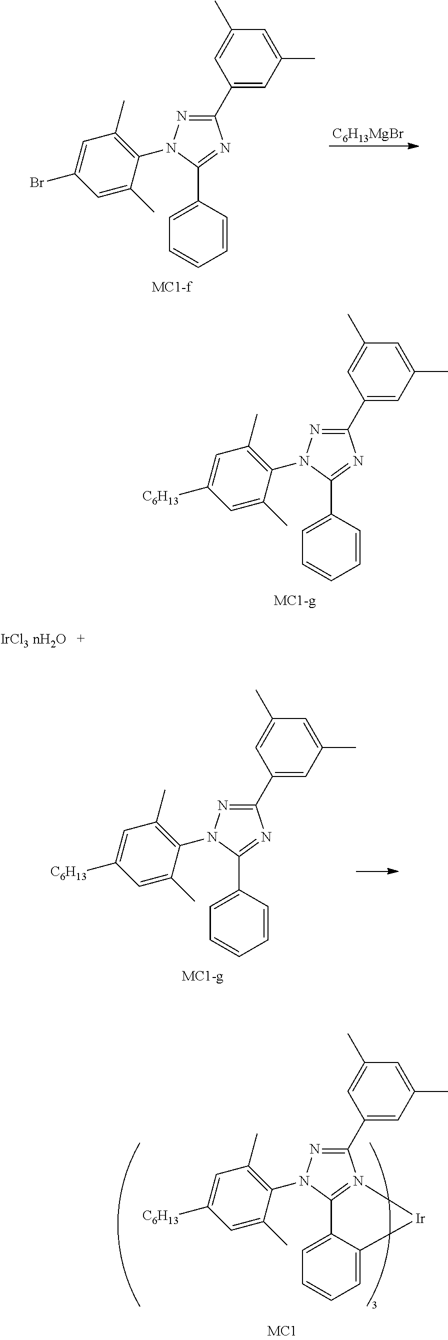

An argon gas atmosphere was prepared in a reaction vessel, then, a compund MC1-a (33.7 g) and dichloromethane (400 mL) were added, and the reaction vessel was placed in an ice bath and cooled. Thereafter, to this was added a 25 wt % ammonia aqueous solution (40.8 g), and the mixture was stirred for 1 hour while cooling the reaction vessel in an ice bath. Thereafter, to this were added ion exchanged water (200 mL) and dichloromethane (150 mL), and the organic layer was extracted. The resultant organic layer was dried over anhydrous magnesium sulfate, then, heptane (400 mL) was added, and dichloromethane was concentrated under reduced pressure, thereby obtaining a solution containing a white solid. The resultant solution containing a white solid was filtered, then, the resultant white solid was dried under reduced pressure, thereby obtaining compound MC1-b (27.8 g, yield: 93%) as a white solid. The compound MC1-b showed a HPLC area percentage value of 99.3%. This operation was conducted repeatedly, thereby obtaining a necessary amount of the compound MC1-b.

TLC/MS (DART, positive): m/z=150 [M+H]⁺

An argon gas atmosphere was prepared in a reaction vessel, then, the compound MC1-b (34.3 g) and dichloromethane (1.38 L) were added. Thereafter, to this was added a dichloromethane solution of triethyloxonium tetrafluoroborate (1 mol/L, 276 mL), and the mixture was stirred for 34 hours at room temperature. Thereafter, to this was added a sodium hydrogen carbonate aqueous solution (1 mol/L, 352 mL), and the mixture was stirred for 30 minutes at room temperature. The organic layer of the resultant reaction solution was extracted, then, the resultant organic layer was washed with saturated saline (300 mL), thereby obtaining an organic layer. To the resultant organic layer was added heptane (200 mL), then, dichloromethane was concentrated under reduced pressure, thereby obtaining a solution containing a white solid. The resultant solution containing a white solid was filtered, then, the resultant filtrate was concentrated, thereby obtaining a compound MC1-c (33.6 g, yield: 82%) as a yellow oil. The compound MC1-c showed a HPLC area percentage value of 98.0%.

TLC/MS (DART, positive): m/z=178 [M+H]⁺

An argon gas atmosphere was prepared in a reaction vessel, then, the compound MC1-c (33.5 g), benzoyl chloride (26.6 g) and chloroform (570 mL) were added, then, triethylamine (26.4 mL) was added, and the mixture was stirred for 66 hours at room temperature. The resultant reaction solution was concentrated under reduced pressure, to the resultant residue were added ion exchanged water (210 mL) and chloroform (210 mL), and the organic layer was extracted. The resultant organic layer was washed with saturated saline (150 mL), dried over anhydrous magnesium sulfate, then, concentrated under reduced pressure, thereby obtaining a compound MC1-d (54.2 g, yield: 88%) as an orange oil. The compound MC1-d showed a HPLC area percentage value of 86.0%.

TLC/MS (DART, positive): m/z=282 [M+H]⁺

¹H-NMR (300 MHz, CDCl₃-d₁): δ (ppm)=8.01-7.98 (m, 2H), 7.56-7.51 (m, 1H), 7.46-7.41 (m, 2H), 7.19 (s, 2H), 7.03 (s, 1H), 4.48-4.41 (m, 2H), 2.23 (s, 6H), 1.48 (t, 3H).

An argon gas atmosphere was prepared in a reaction vessel, then, a compound MC1-e (55.8 g) and toluene (925 mL) were added, and the reaction vessel was placed in an ice bath and cooled. Thereafter, to this was added a sodium hydroxide aqueous solution (1 mol/L, 222 mL), and the mixture was stirred for 30 minutes while cooling the reaction vessel in an ice bath. The organic layer of the resultant reaction solution was extracted, thereby obtaining a toluene solution as an organic layer.

An argon gas atmosphere was prepared in a reaction vessel separately prepared, then, the compound MC1-d (52.0 g) and chloroform (925 mL) were added, and the reaction vessel was placed in an ice bath and cooled. Thereafter, to this was added the toluene solution obtained above. Thereafter, the mixture was stirred for 7 hours while cooling the reaction vessel in an ice bath, then, stirred at room temperature for 100 hours. To the resultant reaction solution was added ion exchanged water (500 mL), the organic layer was extracted, and the resultant organic layer was concentrated under reduced pressure. The resultant residue was purified by silica gel column chromatography (a mixed solvent of chloroform and hexane), then, recrystallization was performed using a mixed solvent of chloroform and heptane. Thereafter, the crystal was dried under reduced pressure at 50° C., thereby obtaining a compound MC1-f (17.6 g, yield: 22%) as a white solid. The compound MC1-f showed a HPLC area percentage value of 99.5% or more. This operation was conducted repeatedly, thereby obtaining a necessary amount of the compound MC1-f.

TLC/MS (DART, positive): m/z=432 [M+H]⁺

¹H-NMR (300 MHz, CD₂Cl₂-d₂): δ (ppm)=7.84 (s, 2H), 7.56-7.54 (m, 2H), 7.43-7.32 (m, 5H), 7.09 (s, 1H), 2.40 (s, 6H), 1.99 (s, 6H).

An argon gas atmosphere was prepared in a reaction vessel, then, the compound MC1-f (17.3 g), cyclopentyl methyl ether (240 mL) and [1,1′-bis(diphenylphosphino)ferrocene]palladium(II) dichloride (98 mg) were added, and the mixture was heated up to 50° C. Thereafter, to this was added a diethyl ether solution of hexylmagnesium bromide (2 mol/L, 40 mL), then, the mixture was stirred at 50° C. for 2 hours. Thereafter, to this was added a hydrochloric acid aqueous solution (1 mol/L, 80 mL), and the organic layer was extracted. The resultant organic layer was washed with ion exchanged water (100 mL) twice, dried over anhydrous magnesium sulfate, then, filtered, and the resultant filtrate was concentrated under reduced pressure, thereby obtaining an oil. To the resultant oil were added toluene and activated carbon, and the mixture was stirred at 50° C. for 30 minutes. Thereafter, the mixture was filtered through a filter paved with silica gel and celite, and the resultant filtrate was concentrated under reduced pressure, thereby obtaining a solid. The resultant solid was purified by silica gel column chromatography (a mixed solvent of hexane and ethyl acetate), then, recrystallization was performed using methanol. Thereafter, the crystal was dried under reduced pressure at 50° C., thereby obtaining a compound MC1-g (12.1 g, yield: 69%) as a white solid. The compound MC1-g showed a HPLC area percentage value of 99.5% or more.

TLC/MS (DART, positive): m/z=438 [M+H]⁺

¹H-NMR (300 MHz, CD₂Cl₂-d₂) δ (ppm)=7.92 (s, 2H), 7.65-7.62 (m, 2H), 7.48-7.35 (m, 3H), 7.15 (s, 1H), 7.09 (s, 2H), 2.70 (t, 2H), 2.46 (s, 6H), 2.03 (s, 6H), 1.77-1.67 (m, 2H), 1.46-1.36 (m, 6H), 1.00-0.95 (m, 3H).

### <1-6> Synthesis of Metal Complex MC1

An argon gas atmosphere was prepared in a reaction vessel, then, iridium chloride n-hydrate (2.50 g), the compound MC1-g (6.43 g), ion exchanged water (28 mL) and 2-ethoxyethanol (112 mL) were added, and the mixture was stirred for 25 hours under reflux with heating. Thereafter, to this was added toluene, and the mixture was washed with ion exchanged water. The organic layer of the resultant washing liquid was extracted, and the resultant organic layer was concentrated under reduced pressure, thereby obtaining a solid. The resultant solid was purified by silica gel column chromatography (a mixed solvent of toluene and methanol), thereby obtaining a solid (4.82 g).

An argon gas atmosphere was prepared in a reaction vessel separately prepared, then, the solid obtained above (4.81 g), silver trifluoromethanesulfonate (1.43 g), the compound MC1-g (4.81 g) and tridecane (1.1 mL) were added, and the mixture was stirred with heating at 150° C. for 15 hours. Thereafter, to this was added toluene, the mixture was filtered through a filter paved with silica gel and celite, and the resultant filtrate was washed with ion exchanged water, thereby obtaining an organic layer. The resultant organic layer was concentrated under reduced pressure, thereby obtaining a solid. The resultant solid was purified by silica gel column chromatography (a mixed solvent of hexane and toluene), then, recrystallization was performed using a mixed solvent of ethyl acetate and ethanol. Thereafter, the crystal was dried under reduced pressure at 50° C., thereby obtaining a metal complex MC1 (2.32 g, yield: 35%) as a yellow solid. The metal complex MC1 showed a HPLC area percentage value of 99.5% or more.

LC-MS (APCI, positive): m/z=1502.8 [M+H]⁺

¹H-NMR (300 MHz, CD₂Cl₂-d₂) δ (ppm)=7.96 (s, 6H), 7.07 (s, 6H), 6.91 (s, 3H), 6.60 (t, 3H), 6.51 (t, 3H), 6.41 (d, 3H), 6.29 (d, 3H), 2.70 (t, 6H), 2.09 (s, 18H), 1.85 (s, 9H), 1.76-1.67 (m, 6H), 1.60 (s, 9H), 1.44-1.35 (m, 18H), 1.00-0.95 (m, 9H).

### <Example 2> Synthesis of Metal Complex MC2

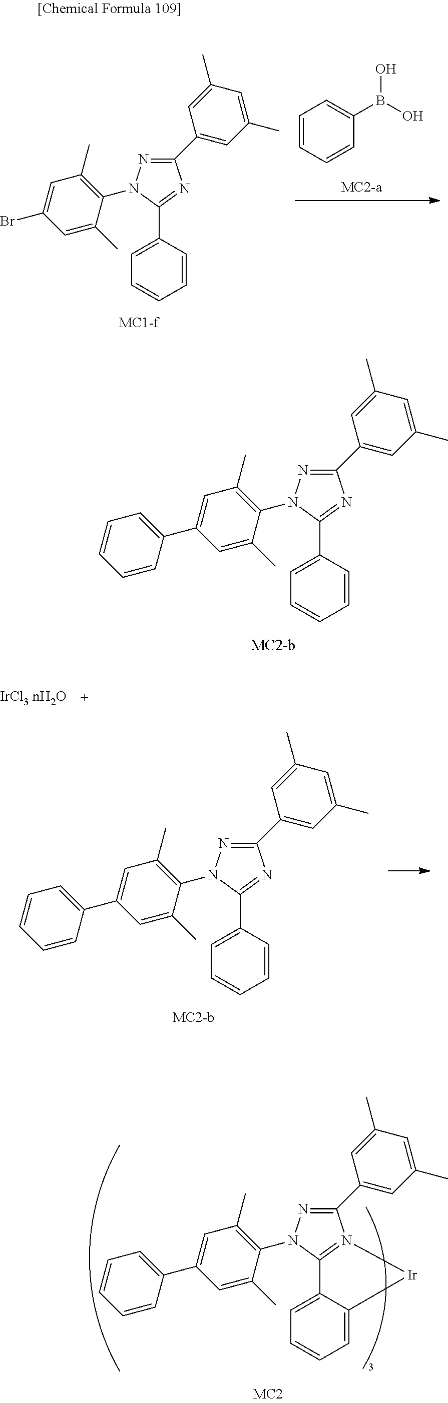

An argon gas atmosphere was prepared in a reaction vessel, then, a compound MC1-f (2.00 g), a compound MC2-a (0.62 g), bis[tri(2-methoxyphenyl)phosphine]palladium(II) dichloride (41.0 mg), toluene (20.0 g) and a 20 wt % tetraethylammonium hydroxide aqueous solution (8.17 g) were added, and the mixture was stirred for 4 hours under reflux with heating. Thereafter, to this was added toluene, and the organic layer was extracted. The resultant organic layer was washed with ion exchanged water, thereby obtaining an organic layer. The resultant organic layer was dried over anhydrous sodium sulfate, then, filtered, and the resultant filtrate was concentrated under reduced pressure, thereby obtaining a solid. The resultant solid was purified by silica gel column chromatography (a mixed solvent of hexane and chloroform), then, recrystallization was performed using heptane. Thereafter, the crystal was dried under reduced pressure at 50° C., thereby obtaining a compound MC2-b (1.29 g, yield: 66%) as a white solid. The compound MC2-b showed a HPLC area percentage value of 99.5% or more. This operation was conducted repeatedly, thereby obtaining a necessary amount of the compound MC2-b.

¹H-NMR (300 MHz, CD₂Cl₂-d₂) δ (ppm)=7.93 (s, 2H), 7.75-7.68 (m, 4H), 7.58-7.52 (m, 4H), 7.50-7.38 (m, 4H), 7.16 (s, 1H), 2.47 (s, 6H), 2.14 (s, 6H).

An argon gas atmosphere was prepared in a reaction vessel, then, iridium chloride n-hydrate (0.27 g), the compound MC2-b (0.68 g), ion exchanged water (5.35 g), 2-ethoxyethanol (16.0 g) and 1,4-dioxane (8.00 g) were added, and the mixture was stirred for 28 hours under reflux with heating. Thereafter, to this was added ethyl acetate, and the mixture was washed with ion exchanged water, thereby obtaining an organic layer. The resultant organic layer was concentrated under reduced pressure, thereby obtaining a solid (0.81 g).

An argon gas atmosphere was prepared in a reaction vessel separately prepared, then, the solid obtained above (0.81 g), silver trifluoromethanesulfonate (0.29 g), the compound MC2-b (0.645), diglyme (0.81 g) and 2,6-lutidine (0.20 g) were added, and the mixture was stirred for 22 hours with heating at 150° C. Thereafter, to this was added toluene, the mixture was filtered through a filter paved with silica gel and celite, and the resultant filtrate was washed with ion exchanged water, thereby obtaining an organic layer. The resultant organic layer was concentrated under reduced pressure, thereby obtaining a solid. The resultant solid was purified by silica gel column chromatography (a mixed solvent of hexane and toluene), then, recrystallization was performed using a mixed solvent of toluene and heptane. Thereafter, the crystal was dried under reduced pressure at 50° C., thereby obtaining a metal complex MC2 (0.17 g, yield: 16%) as a yellow solid. The metal complex MC2 showed a HPLC area percentage value of 99.5% or more.

LC-MS (APCI, positive): m/z=1478.6 [M+H]⁺

¹H-NMR (300 MHz, CD₂Cl₂-d₂) δ (ppm)=8.02 (s, 6H), 7.75 (d, 6H), 6.66-6.44 (m, 15H), 6.97 (s, 3H), 6.68-6.44 (m, 12H), 2.14 (s, 18H), 1.98 (s, 9H), 1.74 (s, 9H).

### <Example 3> Synthesis of Metal Complex MC3

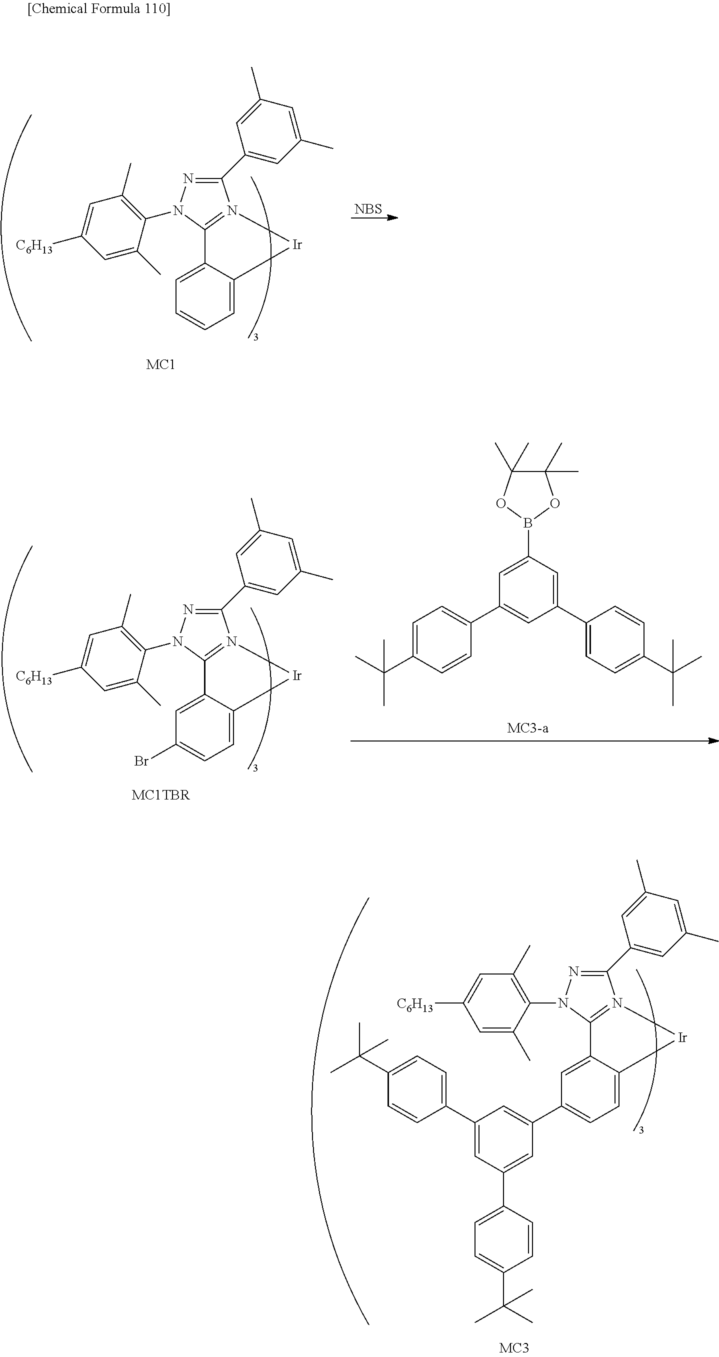

An argon gas atmosphere was prepared in a reaction vessel, then, the metal complex MC1 (0.50 g), dichloromethane (25 mL) and N-bromosuccinimide (203 mg) were added, and the mixture was stirred at room temperature for 27.5 hours. Thereafter, to this was added a 10 wt % sodium sulfite aqueous solution (4.20 g), then, ion exchanged water (8.40 mL) was added, and the mixture was stirred at room temperature for 30 minutes. The organic layer was extracted from the resultant reaction solution, and the resultant organic layer was filtered through a filter paved with silica gel. Methanol was added to the resultant filtrate, thereby causing deposition of a precipitate. The resultant precipitate was filtered, then, dried in vacuum at 50° C., thereby obtaining a metal complex MC1TBR (0.55 g, yield: 95%) as a yellow solid. The metal complex MC1TBR showed a HPLC area percentage value of 99.5% or more.

LC-MS (APCI, positive): m/z=1736.5 [M+H]⁺

¹H-NMR (300 MHz, CD₂Cl₂-d₂) δ (ppm)=7.94 (s, 6H), 7.71 (d, 6H), 6.94 (s, 3H), 6.73-6.70 (m, 3H), 6.29 (d, 3H), 6.25 (d, 3H), 2.72 (t, 6H), 2.10 (s, 18H), 1.84 (s, 91), 1.77-1.67 (m, 6H), 1.57 (s, 9H), 1.45-1.34 (m, 18H), 0.99-0.94 (m, 9H).

An argon gas atmosphere was prepared in a reaction vessel, then, the metal complex MC1TBR (0.50 g), a compound MC3-a (0.44 g), toluene (30 mL), tris(dibenzylideneacetone)dipalladium(0) (7.9 mg) and 2-dicyclohexylphosphino-2′,6′-dimethoxybiphenyl (8.5 mg) were added, and the mixture was heated up to 80° C. Thereafter, to this was added a 20 wt % tetraethylammonium hydroxide aqueous solution (4.2 mL), and the mixture was stirred for 6 hours under reflux with heating. Thereafter, to this was added toluene, and the organic layer was extracted. The resultant organic layer was washed with ion exchanged water, dried over anhydrous magnesium sulfate, then, the mixture was filtered through a filter paved with silica gel and celite, and the resultant filtrate was concentrated under reduced pressure, thereby obtaining a solid. The resultant solid was purified by silica gel column chromatography (a mixed solvent of hexane and toluene), thereby obtaining a metal complex MC3 (0.54 g, yield: 74%) as a yellow solid. The metal complex MC3 showed a HPLC area percentage value of 99.5% or more.

LC-MS (APCI, positive): m/z=2523.5 [M+H]⁺

¹H-NMR (300 MHz, CD₂Cl₂-d₂) δ (ppm)=8.05 (s(br), 6H), 7.70-7.50 (m, 27H), 7.38 (s(br), 6H), 7.13-7.01 (m, 9H), 6.95 (s, 3H), 6.82 (s(br), 3H), 6.65 (s(br), 3H), 2.25 (t, 6H), 2.11 (s, 18H), 2.02 (s, 9H), 1.71-1.64 (m, 9H), 1.48-1.20 (m, 78H), 0.96-0.86 (m, 9H).

### <Example 4> Synthesis of Metal Complex MC4

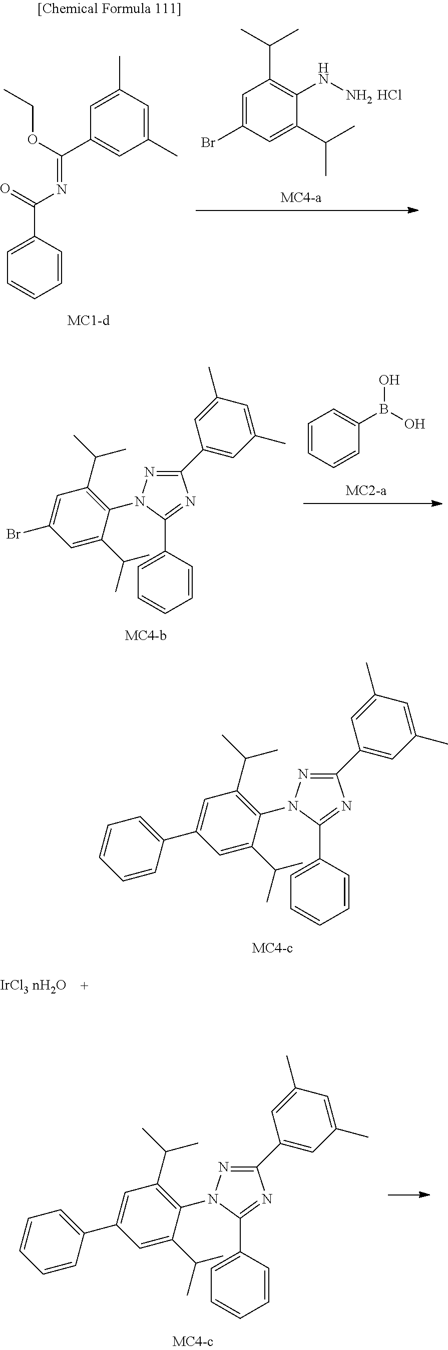

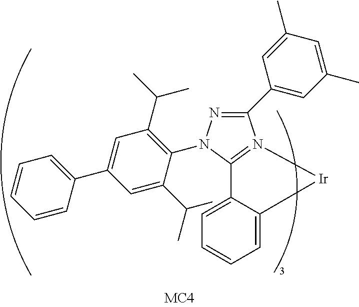

An argon gas atmosphere was prepared in a reaction vessel, then, a compound MC4-a (13.1 g) and tert-butyl methyl ether (110 mL) were added, and the reaction vessel was placed in an ice bath and cooled. Thereafter, to this was added a sodium hydroxide aqueous solution (1 mol/L, 125 mL), and the mixture was stirred for 30 minutes while cooling the reaction vessel in an ice bath. The organic layer of the resultant reaction solution was extracted, thereby obtaining a tert-butyl methyl ether solution as an organic layer.

An argon gas atmosphere was prepared in a reaction vessel separately prepared, then, the compound MC1-d (11.0 g) and chloroform (220 mL) were added, and the reaction vessel was placed in an ice bath and cooled. Thereafter, to this was added the tert-butyl methyl ether solution obtained above. Thereafter, the mixture was stirred for 7 hours while cooling the reaction vessel in an ice bath, then, stirred at room temperature for 110 hours. To the resultant reaction solution was added ion exchanged water (330 mL), the organic layer was extracted, and the resultant organic layer was concentrated under reduced pressure. The resultant residue was purified by silica gel column chromatography (a mixed solvent of chloroform and hexane), then, recrystallization was performed using a mixed solvent of chloroform and heptane. Thereafter, the crystal was dried under reduced pressure at 50° C., thereby obtaining a compound MC4-b (10.2 g, yield: 55%) as a white solid. The compound MC4-b showed a HPLC area percentage value of 99.5% or more.

LC-MS (ESI, positive): m/z=488.2 [M+H]⁺

¹H-NMR (CD₂Cl₂, 300 MHz): δ (ppm)=7.92 (s, 2H), 7.66-7.62 (m, 2H), 7.52 (s, 2H), 7.52-7.36 (m, 3H), 7.16 (s, 1H), 2.57-2.46 (m, 8H), 1.20 (d, 6H), 0.97 (d, 6H).

An argon gas atmosphere was prepared in a reaction vessel, then, the compound MC4-b (10.2 g), a compound MC2-a (2.8 g), bis[tri(2-methoxyphenyl)phosphine]palladium(II) dichloride (92.1 mg), toluene (102 mL) and a 20 wt % tetraethylammonium hydroxide aqueous solution (36.9 g) were added, and the mixture was stirred for 4 hours under reflux with heating. Thereafter, to this was added toluene, and the organic layer was extracted. The resultant organic layer was washed with ion exchanged water, thereby obtaining an organic layer. The resultant organic layer was dried over anhydrous sodium sulfate, then, silica gel (10 g) was added and filtration was performed, and the resultant filtrate was concentrated under reduced pressure, thereby obtaining a solid. The resultant solid was recrystallized using a mixed solvent of heptane and chloroform. Thereafter, the crystal was dried under reduced pressure at 50° C., thereby obtaining a compound MC4-c (8.55 g, yield: 84%) as a white solid. The compound MC4-c showed a HPLC area percentage value of 99.5% or more.

LC-MS (ESI, positive): m/z=486.3 [M+H]⁺

¹H-NMR (CD₂Cl₂, 300 MHz): δ (ppm)=7.96 (s, 2H), 7.75 (t, 48), 7.60-7.55 (m, 4H), 7.51-7.41 (m, 4H), 7.17 (s, 1H), 2.63-2.58 (m, 2H), 2.47 (d, 6H), 1.27 (d, 6H), 1.05 (d, 6H).

An argon gas atmosphere was prepared in a reaction vessel, then, iridium chloride n-hydrate (1.96 g), the compound MC4-c (5.61 g), ion exchanged water (20 mL) and diglyme (80 mL) were added, and the mixture was stirred for 18 hours with heating at 150° C. Thereafter, to this was added toluene, and the mixture was washed with ion exchanged water, thereby obtaining an organic layer. The resultant organic layer was concentrated under reduced pressure, thereby obtaining a solid. The resultant solid was purified by silica gel chromatography (a mixed solvent of toluene and methanol). Thereafter, the crystal was dried under reduced pressure at 50° C., thereby obtaining a solid (5.16 g).

An argon gas atmosphere was prepared in a reaction vessel separately prepared, then, the solid obtained above (4.5 g), silver trifluoromethanesulfonate (1.93 g), the compound MC4-c (2.78 g), diglyme (4.5 mL), decane (4.5 mL) and 2,6-lutidine (1.1 mL) were added, and the mixture was stirred for 31 hours with heating at 160° C. Thereafter, to this was added dichloromethane, and the mixture was filtered through a filter paved with celite, and the resultant filtrate was washed with ion exchanged water, thereby obtaining an organic layer. The resultant organic layer was dried over anhydrous magnesium sulfate, then, silica gel (18.6 g) was added and filtration was performed, and the resultant filtrate was concentrated under reduced pressure, thereby obtaining a solid. The resultant solid was purified by silica gel column chromatography (a mixed solvent of cyclohexane and dichloromethane), then, recrystallization was performed using a mixed solvent of toluene and acetonitrile. Thereafter, the crystal was dried under reduced pressure at 50° C., thereby obtaining a metal complex MC4 (1.9 g, yield: 24%) as a yellow solid. The metal complex MC4 showed a HPLC area percentage value of 98.9%.

LC-MS (APCI, positive): m/z=1646.8 [M+H]⁺

¹H-NMR (CD₂Cl₂, 300 MHz): δ (ppm)=9.12-7.10 (m, 27H), 7.00 (s, 3H), 6.72 (t, 3H), 6.62-6.33 (m, 9H), 2.74-1.67 (m, 24H), 1.25 (d, 9H), 1.15-1.00 (m, 18H), 0.84 (d, 9H).

### <Example 5> Synthesis of Metal Complex MC5

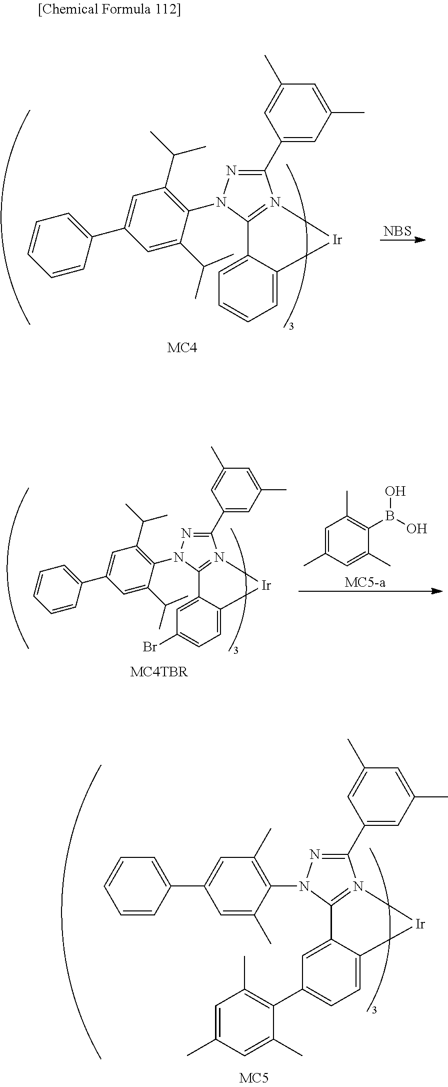

An argon gas atmosphere was prepared in a reaction vessel, then, the metal complex MC4 (0.70 g), dichloromethane (35 mL) and N-bromosuccinimide (825 mg) were added, and the mixture was stirred at room temperature for 40 hours. Thereafter, to this was added a 10 wt % sodium sulfite aqueous solution (7.7 g) then, ion exchanged water (15 mL) was added, and the mixture was stirred at room temperature for 30 minutes. The organic layer was extracted from the resultant reaction solution, and the resultant organic layer was filtered through a filter paved with silica gel. Ethanol was added to the resultant filtrate, thereby causing deposition of a precipitate. The resultant precipitate was filtered, then, dried in vacuum at 50° C., thereby obtaining a metal complex MC4TBR (0.73 g, yield: 91%) as a yellow solid. The metal complex MC4TBR showed a HPLC area percentage value of 96%. This operation was conducted repeatedly, thereby obtaining a necessary amount of the compound MC4TBR.

LC-MS (APCI, positive): m/z=1880.5 [M+H]⁺

¹H-NMR (CD₂Cl₂, 300 MHz): δ (ppm)=8.25-7.83 (m, 6H), 7.76 (d, 6H), 7.76-7.46 (m, 15H), 7.04 (s, 3H), 6.83 (d, 3H), 6.50 (s, 3H), 6.31 (d, 3H), 2.33-1.85 (m, 24H), 1.25 (d, 9H), 1.12-1.07 (m, 18H), 0.84 (d, 9H).

An argon gas atmosphere was prepared in a reaction vessel, then, the metal complex MC4TBR (0.60 g), a compound MC5-a (0.52 g), toluene (18 mL) and bis(di-tert-butyl(4-dimethylaminophenyl)phosphine)dichloropalladium (II) (6.8 mg) were added, and the mixture was heated up to 90° C. Thereafter, to this was added a 20 wt % tetraethylammonium hydroxide aqueous solution (9.1 mL), and the mixture was stirred for 19 hours under reflux with heating. Thereafter, to this was added toluene, and the organic layer was extracted. The resultant organic layer was washed with ion exchanged water, dried over anhydrous magnesium sulfate, then, filtered through a filter paved with silica gel, and the resultant filtrate was concentrated under reduced pressure, thereby obtaining a solid. The resultant solid was purified by silica gel column chromatography (a mixed solvent of cyclohexane and dichloromethane), then, recrystallization was performed using a mixed solvent of toluene and acetonitrile. Thereafter, the crystal was dried under reduced pressure at 50° C., thereby obtaining a metal complex MC5 (0.30 g, yield: 47%) as a yellow solid. The metal complex MC5 showed a HPLC area percentage value of 97.5%.

LC-MS (APCI, positive): m/z=2001.1 [M+H]⁺

¹H-NMR (CD₂Cl₂, 300 MHz): δ (ppm)=7.70-7.40 (m, 27H), 7.04 (s, 3H), 6.78 (s, 9H), 6.56-6.52 (m, 3H), 6.21 (s, 3H), 2.43-1.88 (m, 42H), 1.75 (s, 9H), 1.23 (d, 9H), 1.07-1.01 (m, 18H), 0.85 (d, 9H).

### <Example 6> Synthesis of Metal Complex MC6

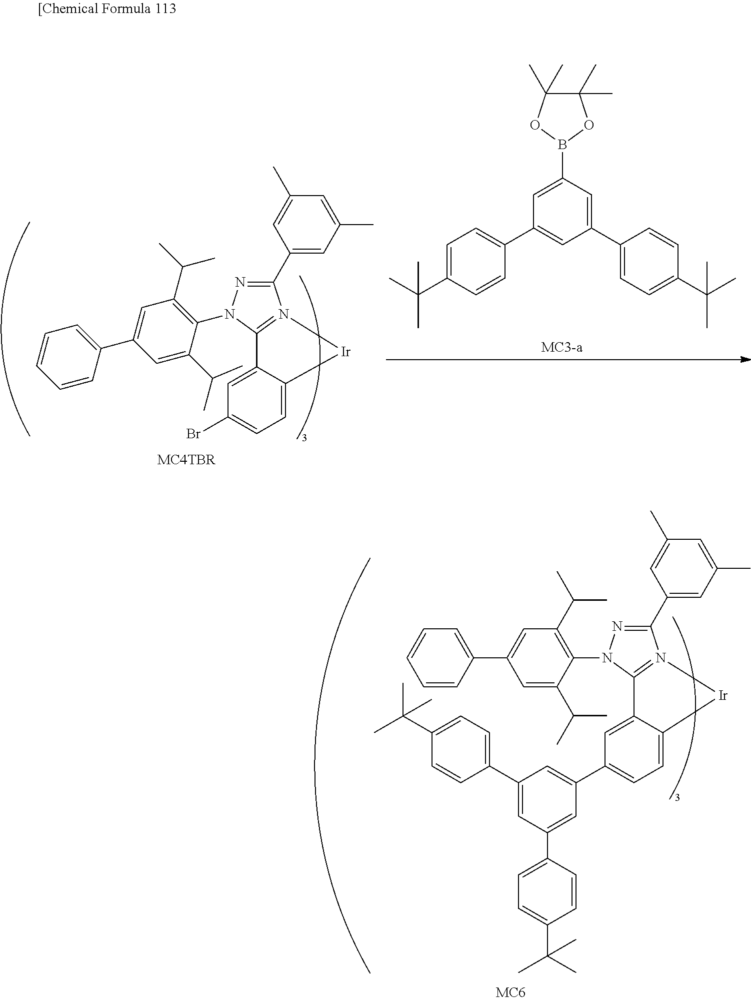

An argon gas atmosphere was prepared in a reaction vessel, then, the metal complex MC4TBR (0.31 g), a compound MC3-a (0.31 g), toluene (9.3 mL) and bis(di-tert-butyl(4-dimethylaminophenyl)phosphine)dichloropalladium (II) (3.5 mg) were added, and the mixture was heated up to 90° C. Thereafter, to this was added a 20 wt % tetraethylammonium hydroxide aqueous solution (2.7 mL), and the mixture was stirred for 5 hours under reflux with heating. Thereafter, to this was added toluene, and the organic layer was extracted. The resultant organic layer was washed with ion exchanged water, dried over anhydrous magnesium sulfate, then, filtered through a filter paved with silica gel, and the resultant filtrate was concentrated under reduced pressure, thereby obtaining a solid. The resultant solid was purified by silica gel column chromatography (a mixed solvent of cyclohexane and dichloromethane), then, recrystallization was performed using a mixed solvent of dichloromethane and hexane. Thereafter, the crystal was dried under reduced pressure at 50° C., thereby obtaining a metal complex MC6 (0.26 g, yield: 60%) as a yellow solid. The metal complex MC6 showed a HPLC area percentage value of 99.5% or more.

LC-MS (APCI, positive): m/z=2667.5 [M+H]⁺

¹H-NMR (CD Cl₂, 300 MHz): δ (ppm)=8.40-7.32 (m, 60H), 7.15 (d, 3H), 7.05-7.03 (m, 6H), 6.76 (s, 3H), 2.54-2.50 (m, 3H), 2.18-2.13 (m, 188H), 1.38 (s, 54H), 1.31-1.13 (m, 30H), 0.90 (d, 9H).

### <Example 7> Synthesis of Metal Complex MC7

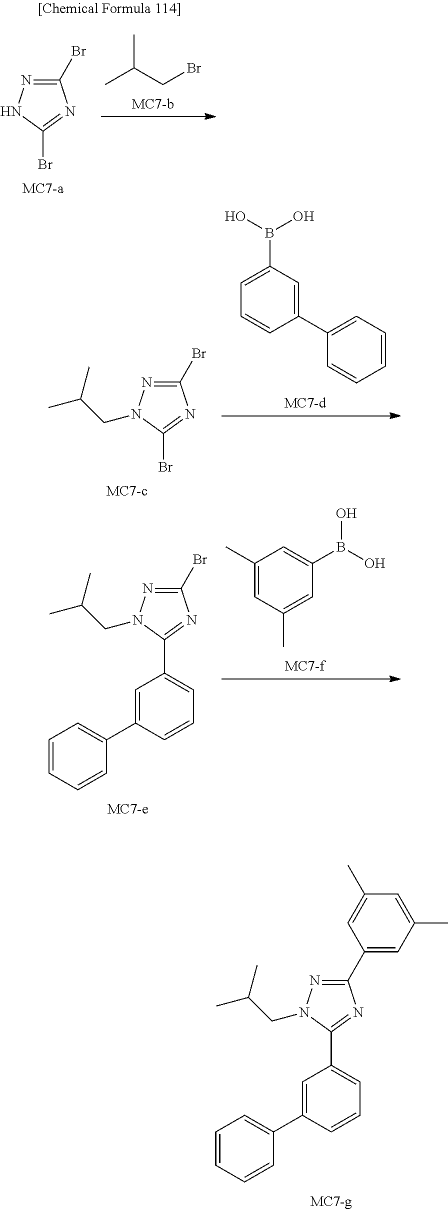

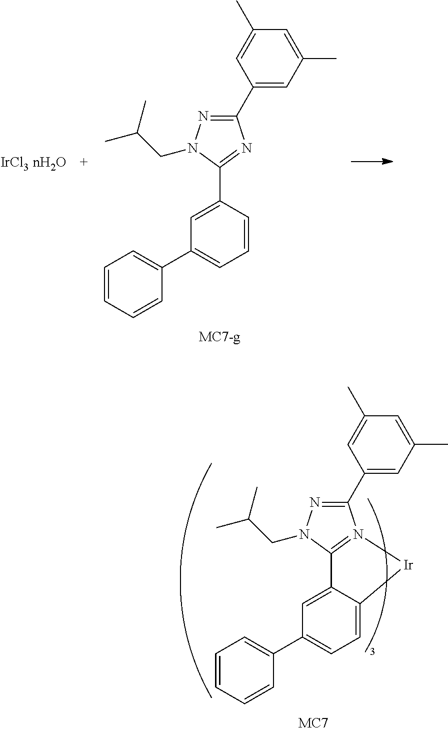

An argon gas atmosphere was prepared in a reaction vessel, then, a compound MC7-a (100 g), potassium carbonate (110 g) and N,N′-dimethylformamide (500 mL) were added, and the mixture was heated up to 90° C. Thereafter, to this was added an N,N′-dimethylformamide (100 mL) solution containing a compound MC7-b (109 g), and the mixture was stirred at 100° C. for 1 hour. Thereafter, the mixture was cooled down to room temperature, ion exchanged water and chloroform were added, and the organic layer was extracted. The resultant organic layer was washed with ion exchanged water, dried over anhydrous magnesium sulfate, then, filtered through a filter paved with silica gel, and the resultant filtrate was concentrated under reduced pressure, thereby obtaining an oil. The resultant oil was purified by silica gel column chromatography (a mixed solvent of heptane and ethyl acetate), then, dried under reduced pressure at 45° C., thereby obtaining a compound MC7-c (117 g, yield: 94%) as a colorless oil. The compound MC7-c showed a HPLC area percentage value of 99.5% or more. This operation was conducted repeatedly, thereby obtaining a necessary amount of the compound MC7-c.

TLC/MS (DART, positive): m/z=281.9 [M+H]⁺

¹H-NMR (CD₂Cl₂, 300 MHz): δ (ppm)=3.94 (d, 2H), 2.32-2.23 (m, 1H), 0.95 (d, 6H).

An argon gas atmosphere was prepared in a reaction vessel, then, the compound MC7-c (127 g), a compound MC7-d (88.9 g), ethanol (380 mL), toluene (1140 mL) and tetrakis(triphenylphosphine) palladium(0) (15.6 g) were added, and the mixture was heated up to 55° C. Thereafter, to this was added a sodium carbonate aqueous solution (2 mol/L, 450 mL), and the mixture was stirred for 29 hours at 70° C. Thereafter, to this was added toluene, and the organic layer was extracted. The resultant organic layer was washed with ion exchanged water, dried over anhydrous magnesium sulfate, then, the resultant solution was concentrated under reduced pressure, thereby obtaining an oil. The resultant oil was purified by silica gel column chromatography (a mixed solvent of toluene and ethyl acetate) several times, then, dried under reduced pressure at 45° C., thereby obtaining a compound MC7-e (63.2 g, yield: 39%) as a colorless oil. The compound MC7-e showed a HPLC area percentage value of 99.5% or more.

TLC/MS (DART, positive): m/z=356.1 [M+H]⁺

¹H-NMR (CD₂Cl₂, 300 MHz): δ (ppm)=7.83-7.82 (m, 1H), 7.76-7.74 (m, 1H), 7.63-7.53 (m, 4H), 7.56-7.46 (m, 2H), 7.42-7.39 (m, 1H), 4.03 (d, 2H), 2.38-2.28 (m, 1H), 0.88 (d, 6H).

An argon gas atmosphere was prepared in a reaction vessel, then, the compound MC7-e (25.0 g), a compound MC7-f (11.6 g), ethanol (75 mL), toluene (225 mL) and tetrakis(triphenylphosphine)palladium(0) (2.43 g) were added, and the mixture was heated up to 80° C. Thereafter, to this was added a sodium carbonate aqueous solution (2 mol/L, 70 mL), and the mixture was stirred at 80° C. for 16 hours. Thereafter, to this was added toluene, and the organic layer was extracted. The resultant organic layer was washed with ion exchanged water, dried over anhydrous magnesium sulfate, then, the resultant solution was concentrated under reduced pressure, thereby obtaining an oil. The resultant oil was purified by silica gel column chromatography (a mixed solvent of heptane and ethyl acetate), then, dried under reduced pressure at 45° C., thereby obtaining a compound MC7-g (26.5 g, yield: 99%) as a colorless oil. The compound MC7-g showed a HPLC area percentage value of 99.5% or more.

TLC/MS (DART, positive): m/z=382.2 [M+H]⁺

¹H-NMR (CD₂Cl₂, 300 MHz): δ (ppm)=7.88-7.87 (m, 1H), 7.82-7.80 (m, 2H), 7.75-7.72 (m, 1H), 7.67-7.56 (m, 4H), 7.49-7.45 (m, 2H), 7.41-7.37 (m, 1H), 7.05-7.04 (m, 1H), 4.06 (d, 2H), 2.42-2.38 (m, 7H), 0.88 (d, 6H).

An argon gas atmosphere was prepared in a reaction vessel, then, iridium chloride n-hydrate (1.43 g), the compound MC7-g (3.20 g), ion exchanged water (11 mL) and diglyme (35 mL) were added, and the mixture was stirred for 18 hours with heating at 140° C. Thereafter, to this was added toluene, and the mixture was washed with ion exchanged water, thereby obtaining an organic layer. The resultant organic layer was concentrated under reduced pressure, thereby obtaining a solid. The resultant solid was recrystallized using a mixed solvent of tert-butyl methyl ether and heptane, thereby obtaining a solid (2.5 g).

An argon gas atmosphere was prepared in a reaction vessel separately prepared, then, the solid obtained above (1.0 g), silver trifluoromethanesulfonate (0.58 g), the compound MC7-g (1.16 g) and 2,6-lutidine (0.9 mL) were added, and the mixture was stirred for 12 hours with heating at 160° C. Thereafter, to this was added dichloromethane, and the mixture was filtered through a filter paved with celite, and acetonitrile was added to the resultant filtrate, thereby observing generation of a precipitate. The resultant precipitate was filtered, thereby obtaining a solid. The resultant solid was dissolved in dichloromethane, silica gel was added, and the mixture was filtered. The resultant filtrate was concentrated under reduced pressure, purified by column chromatography (toluene), then, recrystallization was performed using a mixed solvent of toluene and methanol. Thereafter, the crystal was dried under reduced pressure at 50° C., thereby obtaining a metal complex MC7 (270 mg, yield: 20%) as a yellow solid. The metal complex MC7 showed a HPLC area percentage value of 88%.

LC-MS (APCI, positive): m/z=1334.6 [M+H]⁺

¹H-NMR (CD₂Cl₂, 300 MHz): δ (ppm)=7.75 (d, 3H), 7.67-7.64 (m, 6H), 7.49 (t, 6H), 7.39-7.34 (m, 3H), 7.12-7.08 (m, 3H), 6.96 (s, 38), 6.86-6.83 (m, 3H), 6.50 (s, 6H), 4.53-4.46 (m, 3H), 4.14-4.00 (m, 3H), 2.45-2.32 (m, 3H), 2.23-2.18 (m, 18H), 1.08 (d, 9H), 0.91 (d, 9H).

### <Example 8> Synthesis of Metal Complex MC8

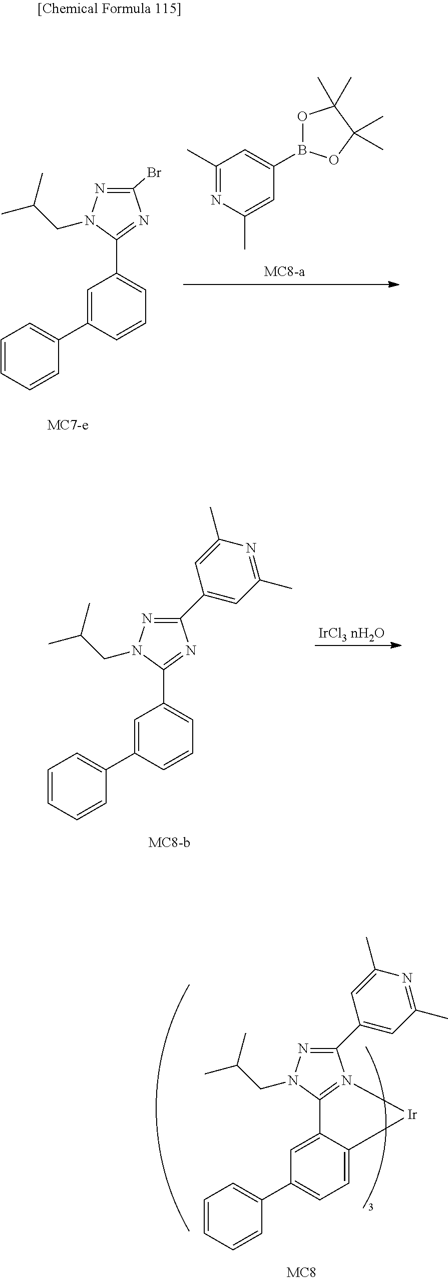

An argon gas atmosphere was prepared in a reaction vessel, then, the compound MC7-e (25.0 g), a compound MC8-a (18.0 g), ethanol (75 mL), toluene (225 mL) and tetrakis(triphenylphosphine)palladium(0) (2.43 g) were added, and the mixture was heated up to 80° C. Thereafter, to this was added a sodium carbonate aqueous solution (2 mol/L, 70 mL), and the mixture was stirred at 80° C. for 48 hours. Thereafter, the mixture was cooled down to room temperature, toluene was added, and the organic layer was extracted. The resultant organic layer was washed with ion exchanged water, dried over anhydrous magnesium sulfate, then, the resultant solution was concentrated under reduced pressure, thereby obtaining an oil. The resultant oil was purified by silica gel column chromatography (a mixed solvent of toluene and ethyl acetate) several times, then, dried under reduced pressure at 45° C., thereby obtaining a compound MC8-b (24.2 g, yield: 90%) as a yellow oil. The compound MC8-b showed a HPLC area percentage value of 99.5% or more.

TLC/MS (DART, positive): m/z=383.2 [M+H]⁺

¹H-NMR (CD₂Cl₂, 300 MHz): δ (ppm)=H-NMR (CDCl₃, 300 MHz): δ (ppm)=7.87 (s, 1H), 7.78-7.72 (m, 3H), 7.66-7.59 (m, 4H), 7.50-7.46 (m, 2H), 7.42-7.38 (m, 1H), 4.09 (d, 2H), 2.60 (m, 6H), 2.42-2.33 (m, 1H), 0.89 (d, 6H).

An argon gas atmosphere was prepared in a reaction vessel, then, iridium chloride n-hydrate (1.43 g), the compound MC8-b (3.21 g), ion exchanged water (11 mL) and diglyme (35 mL) were added, and the mixture was stirred for 18 hours under reflux with heating. Thereafter, to this was added dichloromethane, and the mixture was washed with saturated saline, thereby obtaining an organic layer. The resultant organic layer was dried over anhydrous magnesium sulfate, and the resultant filtrate was concentrated under reduced pressure, thereby obtaining an oil. Hexane was added to the resultant oil, thereby causing deposition of a precipitate. The resultant precipitate was filtered, washed with cyclopentyl methyl ether, then, dried under reduced pressure at 50° C., thereby obtaining a solid (3.0 g).

An argon gas atmosphere was prepared in a reaction vessel separately prepared, then, the solid obtained above (1.5 g), silver trifluoromethanesulfonate (0.58 g), the compound MC8-b (0.87 g) and 2,6-lutidine (0.9 mL) were added, and the mixture was stirred for 12 hours with heating at 160° C. Thereafter, to this was added dichloromethane containing 1 vol % of methanol, then, silica gel was added, and the mixture was filtered through a filter paved with celite, and the resultant filtrate was concentrated under reduced pressure, thereby obtaining a solid. The resultant solid was purified by column chromatography (a mixed solvent of toluene and methanol), then, recrystallization was performed using a mixed solvent of toluene and acetonitrile. Thereafter, the crystal was dried under reduced pressure at 50° C., thereby obtaining a metal complex MC8 (130 mg, yield: 13%) as a yellow solid. The metal complex MC8 showed a HPLC area percentage value of 98.6%.

LC-MS (APCI, positive): m/z=1337.6 [M+H]⁺

¹H-NMR (CD₂Cl₂, 300 MHz): δ (ppm)=7.77 (d, 3H), 7.66-7.63 (m, 6H), 7.50 (t, 6H), 7.40-7.35 (m, 3H), 7.14-7.10 (m, 3H), 6.80 (d, 3H), 6.72-6.48 (m, 6H), 4.57-4.50 (m, 3H), 4.21-4.13 (m, 3H), 2.45-2.31 (m, 21H), 1.09 (d, 9H), 0.92 (d, 9H).

### <Example 9> Synthesis of Metal Complex MC9

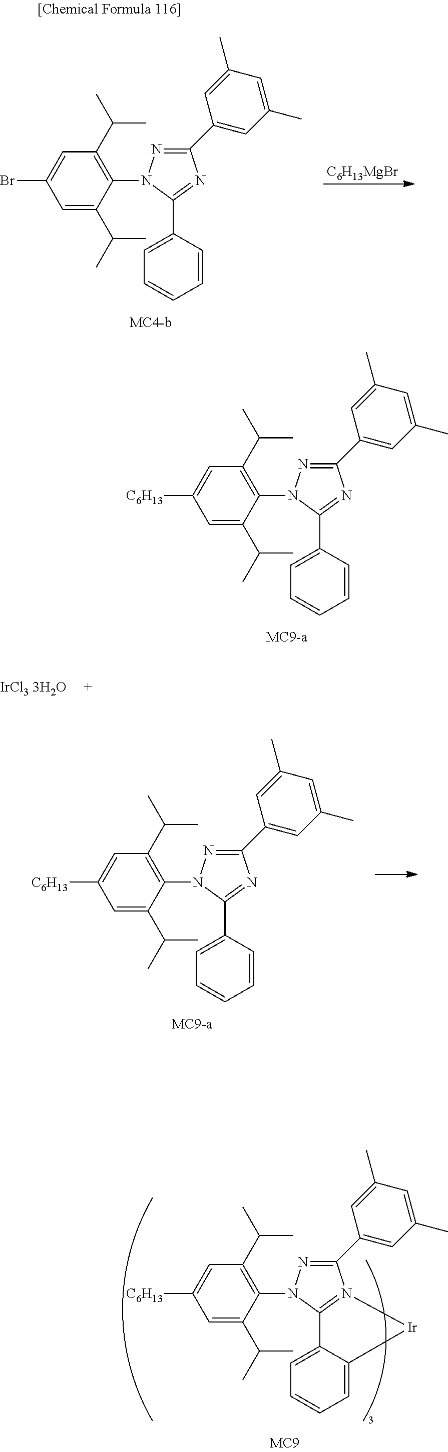

An argon gas atmosphere was prepared in a reaction vessel, then, the compound MC4-b (17.0 g), cyclopentyl methyl ether (150 mL) and [1, 1′-bis(diphenylphosphino) ferrocene]palladium (II) dichloride (172 mg) were added, and the mixture was heated up to 50° C. Thereafter, to this was added a diethyl ether solution of hexylmagnesium bromide (2 mol/L, 35 mL), then, the mixture was stirred at 50° C. for 5 hours. Thereafter, to this was added a hydrochloric acid aqueous solution (1 mol/L, 35 mL), and the organic layer was extracted. The resultant organic layer was washed with ion exchanged water (85 mL) twice, dried over anhydrous magnesium sulfate, then, filtered, and the resultant filtrate was concentrated under reduced pressure, thereby obtaining an oil. To the resultant oil were added toluene and silica gel, and the mixture was stirred at room temperature for 30 minutes. Thereafter, the mixture was filtered through a filter paved with celite, and the resultant filtrate was concentrated under reduced pressure, thereby obtaining a solid. The resultant solid was recrystallized using acetonitrile. Thereafter, the crystal was dried under reduced pressure at 50° C., thereby obtaining a compound MC9-a (13.7 g, yield: 80%) as a white solid. The compound MC9-a showed a HPLC area percentage value of 99.5% or more.

TLC/MS (DART, positive): m/z=494 [M+H]⁺

¹H-NMR (300 MHz, CD₂Cl₂-d₂) δ (ppm)=7.92 (s, 2H), 7.67-7.63 (m, 2H), 7.46-7.33 (m, 3H), 7.18 (s, 2H), 7.14 (s, 1H), 2.76 (t, 2H), 2.57-2.46 (m, 8H), 1.77-1.70 (m, 2H), 1.48-1.42 (m, 6H), 1.21-1.19 (m, 6H), 0.98-0.96 (m, 9H).

An argon gas atmosphere was prepared in a reaction vessel, then, iridium chloride n-hydrate (2.96 g), the compound MC9-a (8.65 g), ion exchanged water (30 mL) and diglyme (74 mL) were added, and the mixture was stirred for 18 hours under reflux with heating. Thereafter, the mixture was cooled down to room temperature, toluene was added, and the mixture was washed with ion exchanged water. The organic layer of the resultant washing liquid was extracted, and the resultant organic layer was concentrated under reduced pressure, thereby obtaining a solid. The resultant solid was purified by silica gel column chromatography (a mixed solvent of toluene and ethanol), thereby obtaining a solid (7.51 g).

An argon gas atmosphere was prepared in a reaction vessel separately prepared, then, the solid obtained above (7.40 g), silver trifluoromethanesulfonate (3.19 g), the compound MC9-a (4.59 g), 2,6-lutidine (1.66 g) and decane (15 mL) were added, and the mixture was stirred for 20 hours with heating at 150° C. Thereafter, the mixture was cooled down to room temperature, toluene was added, and the mixture was filtered through a filter paved with silica gel and celite, and the resultant filtrate was washed with ion exchanged water, thereby obtaining an organic layer. The resultant organic layer was concentrated under reduced pressure, thereby obtaining a solid. The resultant solid was purified by silica gel column chromatography (a mixed solvent of dichloromethane and cyclohexane), then, recrystallization was performed using a mixed solvent of toluene and methanol. Thereafter, the crystal was dried under reduced pressure at 50° C., thereby obtaining a metal complex MC9 (1.47 g, yield: 14%) as a yellow solid. The metal complex MC9 showed a HPLC area percentage value of 99.4%.

LC-MS (APCI, positive): m/z=1671.0 [M+H]⁺

¹H-NMR (300 MHz, CDCl₂-d₂) δ (ppm)=8.03 (br, 6H), 7.17 (s, 6H), 6.96 (s, 3H), 6.66 (t, 3H), 6.51-6.41 (m, 6H), 6.32 (d, 3H), 2.76 (t, 6H), 2.23-1.92 (m, 21H), 1.76-1.69 (m, 6H), 1.58 (s, 3H), 1.53-1.42 (m, 18H), 1.16 (d, 9H), 1.01-0.96 (m, 27H), 0.73 (d, 9H).

### <Example 10> Synthesis of Metal Complex MC10

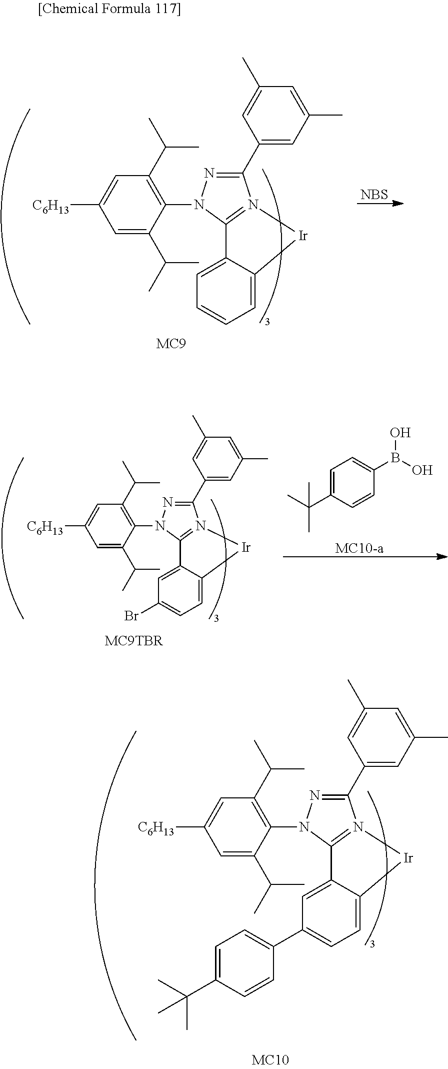

An argon gas atmosphere was prepared in a reaction vessel, then, the metal complex MC9 (1.36 g), dichloromethane (68 mL) and N-bromosuccinimide (1.23 g) were added, and the mixture was stirred at room temperature for 32 hours. Thereafter, to this was added a 10 wt % sodium sulfite aqueous solution (8.71 g), then, ion exchanged water (70 mL) was added, and the mixture was stirred at room temperature for 30 minutes. The organic layer was extracted from the resultant reaction solution, and the resultant organic layer was filtered through a filter paved with silica gel. The resultant filtrate was concentrated under reduced pressure, thereby obtaining a solid. The resultant solid was dissolved in toluene, then, methanol was added, thereby causing deposition of a precipitate. The resultant precipitate was filtered, then, dried in vacuum at 50° C., thereby obtaining a metal complex MC9TBR (1.47 g, yield: 95%) as a yellow solid. The metal complex MC9TBR showed a HPLC area percentage value of 99.5% or more.

LC-MS (APCI, positive): m/z=1903.7 [M+H]⁺

¹H-NMR (300 MHz, CD₂Cl₂-d₂) δ (ppm)=8.00 (br, 6H), 7.20 (s, 6H), 6.99 (s, 3H), 6.67 (d, 3H), 6.36 (d, 3H), 6.25 (d, 3H), 2.78 (t, 6H), 2.06-1.69 (m, 30H), 1.46-1.41 (m, 188H), 1.16 (d, 9H), 1.03-0.94 (m, 27H), 0.74 (d, 9H).

An argon gas atmosphere was prepared in a reaction vessel, then, the metal complex MC9TBR (1.30 g), a compound MC10-a (0.44 g), toluene (65 mL) and (di-tert-butyl(4-dimethylaminophenyl)phosphine)dichloropalladium(II) (16 mg) were added, and the mixture was heated up to 80° C. Thereafter, to this was added a 20 wt % tetrabutylammonium hydroxide aqueous solution (23 mL), and the mixture was stirred for 36 hours under reflux with heating. Thereafter, the mixture was cooled down to room temperature, toluene was added, and the organic layer was extracted. The resultant organic layer was washed with ion exchanged water, dried over anhydrous magnesium sulfate, then, filtered through a filter paved with silica gel and celite, and the resultant filtrate was concentrated under reduced pressure, thereby obtaining a solid. The resultant solid was purified by silica gel column chromatography (a mixed solvent of dichloromethane and cyclohexane), then, recrystallization was performed using a mixed solvent of ethyl acetate and acetonitrile. Thereafter, the crystal was dried under reduced pressure at 50° C., thereby obtaining a metal complex MC10 (0.93 g, yield: 72%) as a yellow solid. The metal complex MC10 showed a HPLC area percentage value of 99.5% or more.

LC-MS (APCI, positive): m/z=2067.3 [M+H]⁺

¹H-NMR (300 MHz, CD₂Cl₂-d₂) δ (ppm)=8.04 (br, 6H), 7.30-7.26 (m, 12H), 7.06-6.98 (m, 12H), 6.70 (s, 3H), 6.54 (d, 3H), 2.82 (t, 6H), 2.32-1.78 (m, 27H), 1.59-1.42 (m, 21H), 1.34 (s, 278), 1.20 (d, 9H), 1.10 (d, 9H), 1.04-0.98 (m, 18H), 0.73 (d, 9H).

### <Example 11> Synthesis of Metal Complex MC11

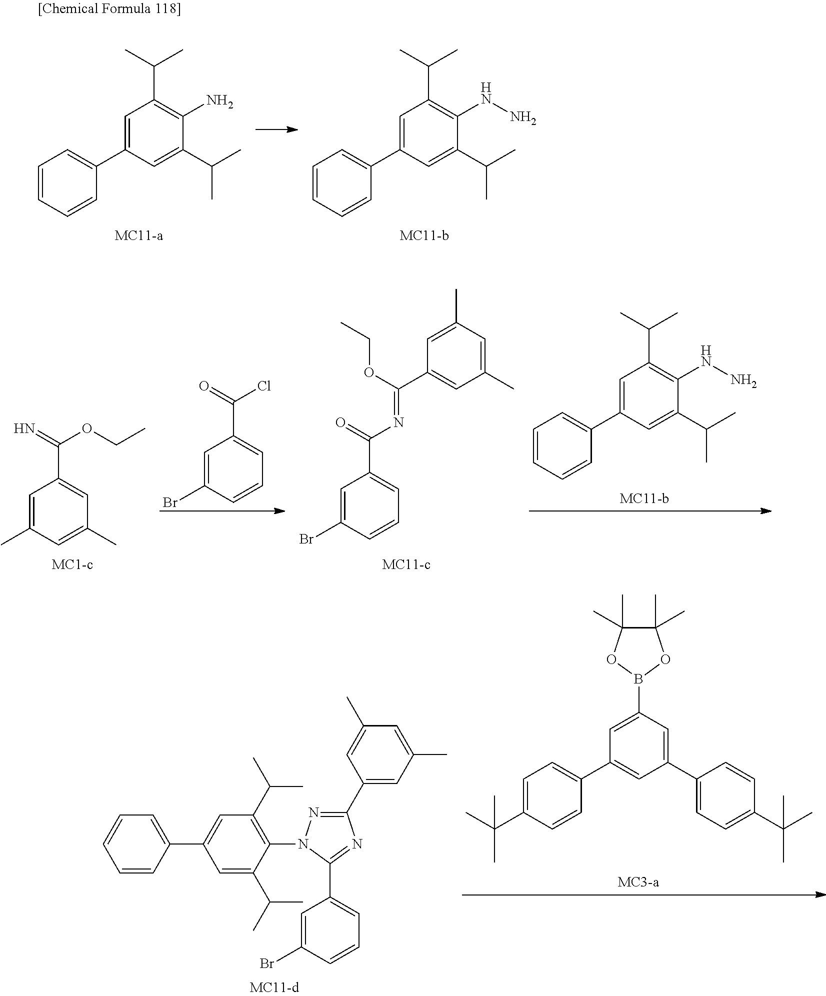

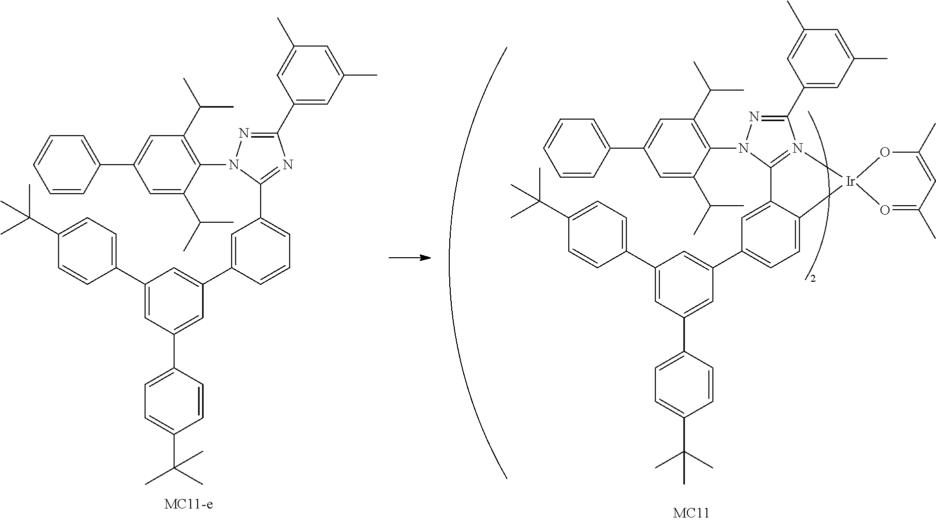

An argon gas atmosphere was prepared in a reaction vessel, then, a compound MC11-a (140 g) and concentrated hydrochloric acid (1.26 L) were added, and the reaction vessel was placed in an ice bath and cooled. Thereafter, to this was added sodium sulfite (50 g), and the mixture was stirred for 30 minutes while cooling the reaction vessel in an ice bath. Thereafter, to this was added tin(II) chloride (400 g), then, the mixture was stirred at room temperature for 18 hours. Thereafter, the resultant reaction liquid was concentrated under reduced pressure, and the resultant residue was washed with a mixed solvent of hexane and diethyl ether, thereby obtaining a solid. To the resultant solid were added tert-butyl methyl ether and a 10% sodium hydroxide aqueous solution, and the organic layer was extracted. The resultant organic layer was washed with ion exchanged water, dried over anhydrous sodium sulfate added, then, concentrated under reduced pressure, thereby obtaining a compound MC11-b (125 g, yield: 83%) as a white solid.

An argon gas atmosphere was prepared in a reaction vessel, then, the compound MC1-c (80 g), 3-bromobenzoyl chloride (100 g) and chloroform were added, then, triethylamine (94 mL) was added, and the mixture was stirred at room temperature for 16 hours. The resultant reaction solution was concentrated under reduced pressure, and to the resultant residue was added heptane, thereby obtaining a solution containing a white solid. The resultant solution containing a white solid was filtered, then, the resultant filtrate was concentrated, thereby obtaining a compound MC11-c (90 g, yield: 55%).

An argon gas atmosphere was prepared in a reaction vessel, then, the compound MC11-c (90 g), the compound MC11-b (56 g), triethylamine (100 mL) and carbon tetrachloride were added, and the mixture was stirred at 50° C. for 3 days. The resultant reaction mixture was purified by silica gel column chromatography (a mixed solvent of ethyl acetate and hexane), thereby obtaining a compound MC11-d (45 g, yield: 32%) as a white solid. The compound MC11-d showed a HPLC area percentage value of 94.8%. This operation was conducted repeatedly, thereby obtaining a necessary amount of the compound MC11-d.

An argon gas atmosphere was prepared in a reaction vessel, then, the compound MC11-d (60 g), a compound MC3-a (55 g), tris(dibenzylideneacetone)dipalladium(0) (980 mg), 2-dicyclohexylphosphino-2′,6′-dimethoxybiphenyl (440 mg), toluene and a 40 wt % tetraethylammonium hydroxide aqueous solution (156 g) were added, and the mixture was stirred for 18 hours under reflux with heating. Thereafter, the mixture was cooled down to room temperature, the organic layer was extracted, and the resultant organic layer was concentrated under reduced pressure, thereby obtaining a solid. The resultant solid was purified by silica gel column chromatography (a mixed solvent of hexane and ethyl acetate), then, recrystallization was performed using a mixed solvent of toluene and acetonitrile. Thereafter, the crystal was dried under reduced pressure at 50° C., thereby obtaining a compound MC11-e (85 g, yield: 97%) as a white solid. The compound MC11-e showed a HPLC area percentage value of 99.5% or more.

LC-MS (ESI, positive): m/z=826.5 [M+H]

¹H-NMR (CD₂C₁₂, 300 MHz): δ (ppm)=8.00 (t, 1H), 7.96 (s, 2H), 7.87-7.82 (m, 3H), 7.68-7.46 (m, 18H), 7.17 (s, 1H), 2.71-2.62 (m, 2H), 2.47 (s, 6H), 1.42 (s, 18H), 1.29 (d, 6H), 1.07 (s, 6H).

An argon gas atmosphere was prepared in a reaction vessel, then, iridium chloride n-hydrate (6.38 g), the compound MC11-e (31.1. g), ion exchanged water (51 mL) and diglyme (151 mL) were added, and the mixture was stirred for 36 hours under reflux with heating. Thereafter, to this was added toluene, and the mixture was washed with ion exchanged water. The organic layer of the resultant washing liquid was extracted, and the resultant organic layer was concentrated under reduced pressure, thereby obtaining a solid. The resultant solid was purified by silica gel column chromatography (a mixed solvent of toluene and ethanol), thereby obtaining a solid (28.5 g).

An argon gas atmosphere was prepared in a reaction vessel separately prepared, then, the solid obtained above (0.60 g), acetylacetone (0.96 g), sodium carbonate (0.34 g) and 2-ethoxyethanol (18 mL) were added, and the mixture was stirred at 120° C. for 2 hours, thereby causing deposition of a precipitate. The resultant precipitate was filtered, and washed with 2-ethoxyethanol (30 mL), ion exchanged water (30 mL) and methanol (30 mL) in this order, thereby obtaining a solid. The resultant solid was dissolved in dichloromethane (5 mL), then, the solution was filtered through a filter paved with silica gel (3 g), and the resultant filtrate was concentrated under reduced pressure, thereby obtaining a solid. The resultant solid was recrystallized using ethyl acetate, then, further, recrystallized using a mixed solvent of toluene and acetonitrile. Thereafter, the crystal was dried under reduced pressure at 50° C., thereby obtaining a metal complex MC11 (0.40 g, yield: 65%) as a yellow solid. The metal complex MC11 showed a HPLC area percentage value of 97.9%.

LC-MS (ESI, positive): m/z=1980.0 [M+K]⁺

¹H-NMR (300 MHz, CD₂Cl₂-d₂) δ (ppm)=7.78 (d, 4H), 7.69-7.65 (m, 10H), 7.53-7.50 (m, 18H), 7.36-7.30 (m, 12H), 7.07-7.04 (m, 4H), 4.71 (s, 1H), 3.15-3.06 (m, 2H), 2.86-2.77 (m, 2H), 2.25 (s, 12H), 1.46-1.26 (m, 66H).

### <Example 12> Synthesis of Metal Complexes MC12, MC13 and MC14

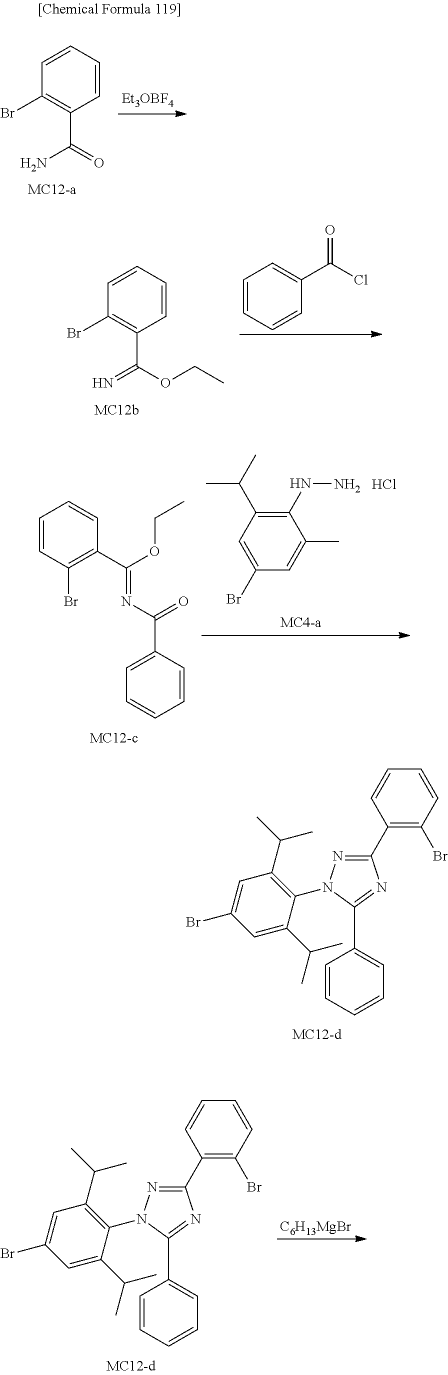

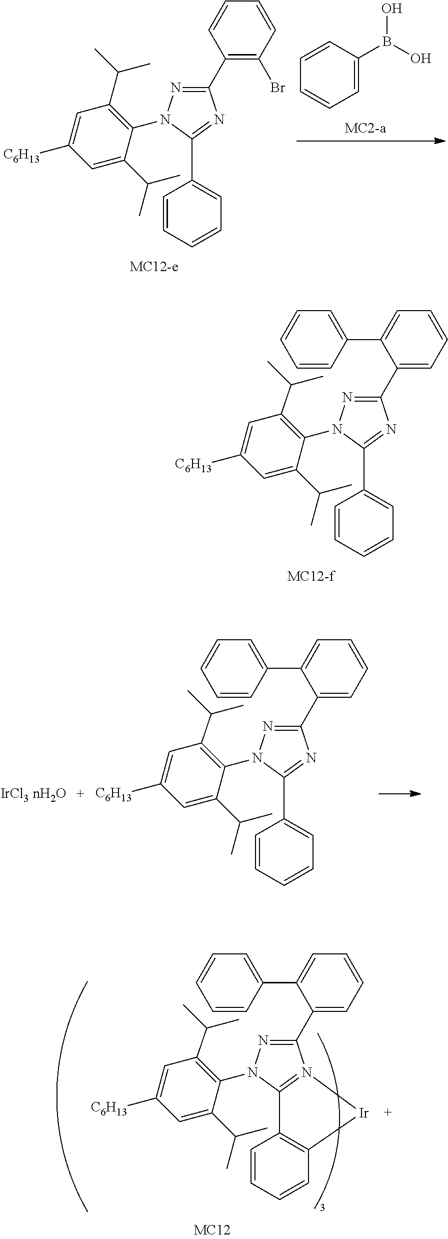

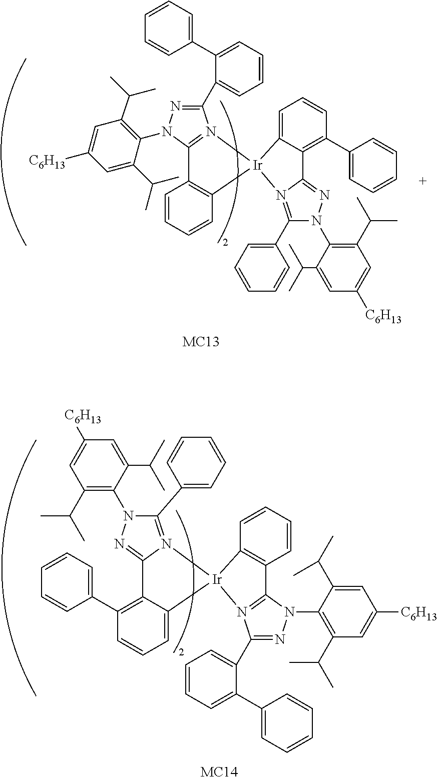

An argon gas atmosphere was prepared in a reaction vessel, then, a compound MC12-a (90.0 g) and dichloromethane (900 mL) were added. Thereafter, to this was added a dichloromethane solution of triethyloxonium tetrafluoroborate (1 mol/L, 525 mL), and the mixture was stirred at room temperature for 38 hours. Thereafter, to this was added a sodium hydrogen carbonate aqueous solution (1 mol/L, 525 mL), and the mixture was stirred for 30 minutes at room temperature. The organic layer of the resultant reaction solution was extracted, then, the resultant organic layer was washed with ion exchanged water, thereby obtaining an organic layer. To the resultant organic layer was added heptane (200 mL), then, dichloromethane was concentrated under reduced pressure, thereby obtaining a solution containing a white solid. The resultant solution containing a white solid was filtered, then, the resultant filtrate was concentrated, thereby obtaining a compound MC12-b (74.2 g, yield: 65%) as a yellow oil. The compound MC12-b showed a HPLC area percentage value of 98.6%.

TLC/MS (DART, positive): m/z=228 [M+H]⁺

An argon gas atmosphere was prepared in a reaction vessel, then, the compound MC12-b (33.5 g), benzoyl chloride (52.4 g) and chloroform (730 mL) were added, then, triethylamine (52.0 mL) was added, and the mixture was stirred for 66 hours at room temperature. The resultant reaction solution was concentrated under reduced pressure, to the resultant residue was added cyclopentyl methyl ether (600 mL), and the mixture was filtered, thereby obtaining a filtrate. The resultant filtrate was concentrated under reduced pressure, and the resultant residue was purified by silica gel column chromatography (chloroform), thereby obtaining a compound MC12-c (88.0 g, yield: 78%) as a yellow oil. The compound MC12-c showed a HPLC area percentage value of 91.3%.

TLC/MS (DART, positive): m/z=332 [M+H]⁺

An argon gas atmosphere was prepared in a reaction vessel, then, a compound MC4-a (56.8 g) and tert-butyl methyl ether (570 mL) were added, the reaction vessel was cooled down to temperatures in the range of 0° C. to 10° C. using an ice bath. Thereafter, to this was added a sodium hydroxide aqueous solution (1 mol/L, 550 mL), and the mixture was stirred for 30 minutes while cooling the reaction vessel to temperatures in the range of 0° C. to 10° C. using an ice bath. The organic layer of the resultant reaction solution was extracted, thereby obtaining a tert-butyl methyl ether as an organic layer.

An argon gas atmosphere was prepared in a reaction vessel separately prepared, then, the compound MCL2-c (60.0 g) and chloroform (1.20 L) were added, and the reaction vessel was placed in an ice bath and cooled. Thereafter, to this was added the tert-butyl methyl ether solution obtained above. Thereafter, the mixture was stirred for 6 hours while cooling the reaction vessel by an ice bath, then, stirred at room temperature for 100 hours, then, stirred for 200 hours under reflux with heating, then, the mixture was cooled down to room temperature. To the resultant reaction solution was added ion exchanged water (500 mL), the organic layer was extracted, and the resultant organic layer was concentrated under reduced pressure. The resultant residue was purified by silica gel column chromatography (toluene), then, recrystallization was performed using heptane. Thereafter, the crystal was dried under reduced pressure at 50° C., thereby obtaining a compound MC12-d (58.5 g, yield: 66%) as a white solid. The compound MC12-d showed a HPLC area percentage value of 99.5% or more.

LC-MS (ESI, positive): m/z=538.1 [M+H]⁺

¹H-NMR (300 MHz, CD₂Cl₂-d₂): δ (ppm)=8.06-8.04 (m, 1H), 7.82-7.79 (m, 1H), 7.68-7.62 (m, 2H), 7.53-7.36 (m, 7H), 2.63-2.49 (m, 2H), 1.22 (d, 6H), 1.00 (d, 6H).

An argon gas atmosphere was prepared in a reaction vessel, then, the compound MC12-d (30.0 g), cyclopentyl methyl ether (1.20 L) and [1,1′-bis(diphenylphosphino)ferrocene]palladium(II) dichloride (230 mg) were added, and the mixture was heated up to 40° C. Thereafter, to this was added a diethyl ether solution of hexylmagnesium bromide (2 mol/L, 33.4 mL), then, the mixture was stirred at 40° C. for 3 hours. Thereafter, to this was added a hydrochloric acid aqueous solution (1 mol/L, 80 mL), and the organic layer was extracted. The resultant organic layer was washed with ion exchanged water (300 mL) three times, dried over anhydrous magnesium sulfate, then, silica gel (30 g) was added and filtration was performed, and the resultant filtrate was concentrated under reduced pressure, thereby obtaining an oil. The resultant oil was purified by silica gel column chromatography (a mixed solvent of hexane and ethyl acetate), to obtain a compound MC12-e (28.5 g, yield: 79%) as a colorless oil. The compound MC12-e showed a HPLC area percentage value of 84%.

LC-MS (ESI, positive): m/z=544.2 [M+H]⁺

An argon gas atmosphere was prepared in a reaction vessel, then, the compound MC12-e (23.0 g), a compound MC2-a (5.20 g), toluene (460 mL) and (di-tert-butyl(4-dimethylaminophenyl)phosphine)dichloropalladium(II) (251 mg) were added, and the mixture was heated up to 80° C. Thereafter, to this was added a 10 wt % tetrabutylammonium hydroxide aqueous solution (276 mL), and the mixture was stirred for 32 hours under reflux with heating. Thereafter, the mixture was cooled down to room temperature, toluene was added, and the organic layer was extracted. The resultant organic layer was washed with ion exchanged water, dried over anhydrous magnesium sulfate, then, the mixture was filtered through a filter paved with silica gel and celite, and the resultant filtrate was concentrated under reduced pressure, thereby obtaining an oil. The resultant oil was purified by silica gel column chromatography (a mixed solvent of hexane and ethyl acetate), then, recrystallization was performed using acetonitrile. Thereafter, the crystal was dried under reduced pressure at 50° C., thereby obtaining a compound MC12-f (15.2 g, yield: 79%) as a white solid. The compound MC12-f showed a HPLC area percentage value of 99.5% or more.

LC-MS (APCI, positive): m/z=542.4 [M+H]⁺

¹H-NMR (300 MHz, CD₂Cl₂-d₂) δ (ppm)=7.96-7.93 (m, 1H), 7.63-7.53 (m, 3H), 7.45-7.27 (m, 10H), 7.14 (s, 2H), 2.75 (t, 2H), 2.46-2.33 (m, 2H), 1.78-1.68 (m, 2H), 1.48-1.38 (m, 6H), 1.12 (d, 6H), 1.01-0.94 (m, 9H).

An argon gas atmosphere was prepared in a reaction vessel, then, iridium chloride n-hydrate (3.14 g), the compound MC12-f (10.0 g), ion exchanged water (25 mL) and diglyme (78 mL) were added, and the mixture was stirred at 130° C. for 42 hours, then, the mixture was cooled down to room temperature. Thereafter, to this was added toluene, and the mixture was washed with ion exchanged water, thereby obtaining an organic layer. The resultant organic layer was concentrated under reduced pressure, thereby obtaining a solid. The resultant solid was purified by silica gel column chromatography (a mixed solvent of toluene and ethanol), thereby obtaining a solid (10.0 g).

An argon gas atmosphere was prepared in a reaction vessel separately prepared, then, the solid obtained above (10.0 g), silver trifluoromethanesulfonate (2.94 g) and acetonitrile (250 mL) were added, and the mixture was stirred for 2 hours under reflux with heating. Thereafter, the mixture was cooled down to room temperature, filtered through a filter paved with celite, and the resultant filtrate was concentrated under reduced pressure, thereby obtaining an oil. The resultant oil was purified by alumina column chromatography (acetonitrile), then, dried at room temperature using an argon gas, thereby obtaining a solid (9.94 g).

An argon gas atmosphere was prepared in a reaction vessel separately prepared, then, the solid obtained above (9.0 g), the compound MC12-f (4.54 g), 2,6-lutidine (3.5 mL) and pentadecane (4.5 mL) were added, and the mixture was stirred at 190° C. for 70 hours. Thereafter, the mixture was cooled down to room temperature, dichloromethane (130 mL) was added, and the reaction mixture was dissolved in dichloromethane. Thereafter, to this was added 2-propanol (30 mL), and dichloromethane was concentrated under reduced pressure, thereby observing generation of a precipitate. The resultant precipitate was filtered, thereby obtaining a filtrate. The resultant filtrate was concentrated under reduced pressure, thereby obtaining an oil. The resultant oil was purified by silica gel column chromatography (a mixed solvent of toluene and hexane), then, further, purified by reversed phase column chromatography (a mixed solvent of acetonitrile and ethyl acetate) several times, thereby obtaining a metal complex MC12, a metal complex MC13 and a metal complex MC14 under individually separated condition.

The resultant metal complex MC12 was further recrystallized using acetonitrile, and the crystal was dried under reduced pressure at 50° C., thereby obtaining a yellow solid (70 mg, yield: 0.6%). The metal complex MC12 showed a HPLC area percentage value of 99.5% or more. The resultant metal complex MC13 was further recrystallized using a mixed solvent of dichloromethane, acetonitrile and methanol, and the crystal was dried under reduced pressure at 50° C., thereby obtaining a yellow solid (120 mg, yield: 1.1%). The metal complex MC13 showed a HPLC area percentage value of 99.5% or more. The resultant metal complex MC14 was further recrystallized using a mixed solvent of dichloromethane and acetonitrile, and the crystal was dried under reduced pressure at 50° C., thereby obtaining a yellow solid (230 mg, yield: 2.1%). The metal complex MC14 showed a HPLC area percentage value of 98.7%.

Metal complex MC12

LC-MS (APCI, positive): m/z=1815.0 [M+H]⁺

¹H-NMR (300 MHz, CD₂Cl₂-d₂) δ (ppm)=9.19-9.16 (m, 3H), 7.39-7.26 (m, 9H), 6.97-6.88 (m, 15H), 6.72 (t, 3H), 6.61 (t, 3H), 6.52 (d, 3H), 6.44-6.35 (m, 6H), 6.22 (d, 3H), 2.54 (t, 6H), 1.89-1.83 (m, 3H), 1.60-1.50 (m, 6H), 1.43-1.34 (m, 3H), 1.30-1.24 (m, 18H), 0.86-0.72 (m, 27H), 0.55 (d, 9H), 0.47 (d, 18H).

Metal complex MC13

LC-MS (ESI, positive): m/z=1852.9 [M+K]⁺

¹H-NMR (300 MHz, CD₂Cl₂-d₂) δ (ppm)=7.96 (d, 1H), 7.46 (t, 1H), 7.37 (d, 1H), 7.29-6.36 (m, 41H), 6.22 (d, 1H), 2.62 (t, 2H), 2.53 (t, 2H), 2.48-2.31 (m, 4H), 2.21-2.06 (m, 1H), 1.90-1.74 (m, 1H), 1.67-1.57 (m, 2H), 1.37-1.15 (m, 27H), 1.04 (d, 3H), 0.96-0.91 (m, 6H), 0.87-0.73 (m, 15H), 0.65-0.51 (m, 12H), 0.35 (d, 3H), 0.26 (d, 3H).

Metal complex MC14

LC-MS (ESI, positive): m/z=1852.9 [M+K]⁺

¹H-NMR (300 MHz, CD₂Cl₂-d₂) δ (ppm)=7.47-7.33 (m, 4H), 7.28-7.18 (m, 4H), 7.11-6.78 (25H), 6.67-6.51 (m, 9H), 6.31 (d, 1H), 6.21 (d, 2H), 2.63-2.50 (m, 3H), 2.43-2.37 (m, 4H), 2.30-2.19 (m, 1H), 2.18-2.06 (m, 1H), 2.05-1.97 (m, 1H), 1.65-1.53 (m, 2H), 1.42-1.15 (m, 27H), 1.05-1.01 (m, 3H), 0.97-0.93 (m, 3H), 0.87-0.76 (m, 18H), 0.72-0.64 (m, 9H), 0.62-0.56 (m, 68), 0.43 (d, 3H).

### <Synthesis Example 1> Synthesis of Monomer CM1 (0497)

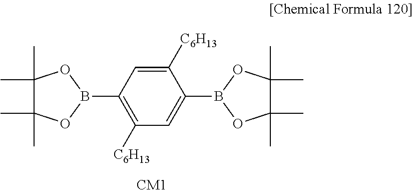

The monomer CM1 was synthesized according to a method described in JP-A No. 2010-189630.

### <Synthesis Example 2> Synthesis of Monomer CM2

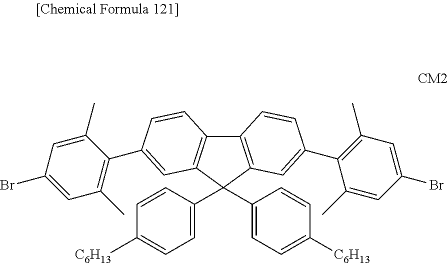

The monomer CM2 was synthesized according to a method described in International Publication WO2015/008851.

### <Synthesis Example 3> Synthesis of Polymer Compound P1

A nitrogen gas atmosphere was prepared in a reaction vessel, then, a compound CM1 (1.28 g), a compound CM2 (2.18 g) and toluene (55 mL) were added, and the mixture was heated at 80° C. Thereafter, to this were added bis[tris(2-methoxyphenyl)phosphine]palladium dichloride (2.34 mg) and a 20 wt % tetraethylammonium hydroxide aqueous solution (9.1 g), and the mixture was stirred for 4 hours under argon gas reflux. Thereafter, to this were added 2-isopropylphenylboronic acid (0.0630 g), bis[tris(2-methoxyphenyl)phosphine]palladium dichloride (2.17 mg) and a 20 wt % tetraethylammonium hydroxide aqueous solution (9.1 g), and the mixture was stirred for 15.5 hours under argon gas reflux. Thereafter, to this was added a solution prepared by dissolving sodium N,N-diethyldithiocarbamate trihydrate (0.72 g) in ion exchanged water (14 mL), and the mixture was stirred at 85° C. for 5 hours. The resultant organic layer was cooled, then, washed with 3.6 wt % hydrochloric acid twice, with 2.5 wt % ammonia water twice, and with ion exchanged water five times, in series. The resultant organic layer was dropped into methanol, thereby finding generation of a precipitate. The resultant precipitate was filtered, and dried, thereby obtaining a solid. The resultant solid was dissolved in toluene, and the solution was allowed to pass through a silica gel column and an alumina column through which toluene had passed previously. The resultant solution was dropped into methanol, thereby causing generation of a precipitate, and the precipitate was collected by filtration and dried, thereby obtaining a polymer compound P1 (2.279 g). The polymer compound P1 had a polystyrene equivalent number-average molecular weight (Mn) and a weight-average molecular weight (Mw) of Mn=7.4×10⁴ and Mw-2.3×10⁵, respectively.

The polymer compound P1 is a copolymer constituted of constitutional units derived from respective monomers at a molar ratio shown in Table 2 below according to the theoretical values calculated from charged raw materials.

TABLE 2

| | monomer | CM1 | CM2 |
|---|---|---|---|
| P1 | molar ratio | 50 | 50 |
| | [mol %] | | |

### <Measurement Example 1> Measurement of Light Emission Stability

A metal complex MC1 and a compound represented by the formula (H-113) (hereinafter, referred to also as “compound H-113”) (manufactured by Luminescence Technology, LT-N4013) were dissolved in toluene at a concentration of 2.0 wt %, thereby preparing a toluene solution (metal complex MC1:compound H-113=25 wt %:75 wt %).

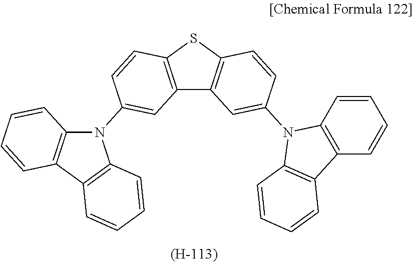 [SMILES: c1ccc2c(c1)c1ccccc1n2-c1ccc2sc3ccc(-n4c5ccccc5c5ccccc54)cc3c2c1]

On a glass substrate, the toluene solution obtained above was spin-coated to form a film with a thickness of 75 nm, and the film was heated at 130° C. for 10 minutes under a nitrogen gas atmosphere (oxygen concentration: 10 ppm or less, moisture concentration: 10 ppm or less), thereby forming an organic layer.

The substrate carrying the organic layer formed thereon was placed in a vapor deposition machine and the internal pressure was reduced to 1.0×10⁻⁴ Pa or lower, then, aluminum was vapor-deposited thereon with a thickness of about 80 nm. After vapor deposition, encapsulating with a glass substrate was carried out under a nitrogen gas atmosphere (oxygen concentration: 10 ppm or less, moisture concentration: 10 ppm or less), thereby fabricating a measurement sample FL-1.

The excitation light intensity of an excitation light source was regulated in such a manner that the light emission luminance of the measurement sample FL-1 was 2130 cd/m². Light emission observed from the measurement sample FL-1 showed the emission spectrum peak at 462 nm and had the chromaticity CIE (x, y) of (0.150, 0.224), indicating that the emission was light emission derived from the metal complex MC1.

Thereafter, the measurement sample FL-1 was allowed to emit light continuously while keeping the regulated excitation light intensity constant, and the time until the light emission luminance reached 85% based on the light emission luminance when initiating measurement (hereinafter, referred to as “LT85”) was measured. The results are shown in Table 3.

### <Measurement Example 2> Measurement of Light Emission Stability

A measurement sample FL-2 was fabricated in the same manner as in Measurement Example 1, excepting that a metal complex MC2 was used instead of the metal complex MC1 in Measurement Example 1, and light emission stability thereof was measured.

The light emission luminance of the measurement sample FL-2 generating the same photon number as that of light emission of the measurement sample FL-1 was calculated according to the above-described formula (17), thereby finding a value of 2290 cd/m².

The excitation light intensity of an excitation light source was regulated in such a manner that the light emission luminance of the measurement sample FL-2 was 2290 cd/m². Light emission observed from the measurement sample FL-2 showed the emission spectrum peak at 466 nm and had the chromaticity CIE (x, y) of (0.154, 0.251), indicating that the emission was light emission derived from the metal complex MC2.

Thereafter, the measurement sample FL-2 was allowed to emit light continuously while keeping the regulated excitation light intensity constant, and LT85 thereof was measured. The results are shown in Table 3.

### <Measurement Example 3> Measurement of Light Emission Stability

A measurement sample FL-3 was fabricated in the same manner as in Measurement Example 1, excepting that a metal complex MC3 was used instead of the metal complex MC1 in Measurement Example 1, and light emission stability thereof was measured.

The light emission luminance of the measurement sample FL-3 generating the same photon number as that of light emission of the measurement sample FL-1 was calculated according to the above-described formula (17), thereby finding a value of 2570 cd/m².

The excitation light intensity of an excitation light source was regulated in such a manner that the light emission luminance of the measurement sample FL-3 was 2570 cd/m². Light emission observed from the measurement sample FL-3 showed the emission spectrum peak at 473 nm and had the chromaticity CIE (x, y) of (0.150, 0.315), indicating that the emission was light emission derived from the metal complex MC3.

Thereafter, the measurement sample FL-3 was allowed to emit light continuously while keeping the regulated excitation light intensity constant, and LT85 thereof was measured. The results are shown in Table 3.

### <Measurement Example 4> Measurement of Light Emission Stability

A measurement sample FL-4 was fabricated in the same manner as in Measurement Example 1, excepting that a metal complex MC4 was used instead of the metal complex MC1 in Measurement Example 1, and light emission stability thereof was measured.

The light emission luminance of the measurement sample FL-4 generating the same photon number as that of light emission of the measurement sample FL-1 was calculated according to the above-described formula (17), thereby finding a value of 2010 cd/m².

The excitation light intensity of an excitation light source was regulated in such a manner that the light emission luminance of the measurement sample FL-4 was 2010 cd/m². Light emission observed from the measurement sample FL-4 showed the emission spectrum peak at 455 nm and had the chromaticity CIE (x, y) of (0.149, 0.204), indicating that the emission was light emission derived from the metal complex MC4.

Thereafter, the measurement sample FL-4 was allowed to emit light continuously while keeping the regulated excitation light intensity constant, and LT85 thereof was measured. The results are shown in Table 3.

### <Measurement Example 5> Measurement of Light Emission Stability

A measurement sample FL-5 was fabricated in the same manner as in Measurement Example 1, excepting that a metal complex MC5 was used instead of the metal complex MC1 in Measurement Example 1, and light emission stability thereof was measured.

The light emission luminance of the measurement sample FL-5 generating the same photon number as that of light emission of the measurement sample FL-1 was calculated according to the above-described formula (17), thereby finding a value of 2280 cd/m².

The excitation light intensity of an excitation light source was regulated in such a manner that the light emission luminance of the measurement sample FL-5 was 2280 cd/m². Light emission observed from the measurement sample FL-5 showed the emission spectrum peak at 464 nm and had the chromaticity CIE (x, y) of (0.150, 0.253), indicating that the emission was light emission derived from the metal complex MC5.

Thereafter, the measurement sample FL-5 was allowed to emit light continuously while keeping the regulated excitation light intensity constant, and LT85 thereof was measured. The results are shown in Table 3.

### <Measurement Example 6> Measurement of Light Emission Stability

A measurement sample FL-6 was fabricated in the same manner as in Measurement Example 1, excepting that a metal complex MC6 was used instead of the metal complex MC1 in Measurement Example 1, and light emission stability thereof was measured.

The light emission luminance of the measurement sample FL-6 generating the same photon number as that of light emission of the measurement sample FL-1 was calculated according to the above-described formula (17), thereby finding a value of 2460 cd/m².

The excitation light intensity of an excitation light source was regulated in such a manner that the light emission luminance of the measurement sample FL-6 was 2460 cd/m². Light emission observed from the measurement sample FL-6 showed the emission spectrum peak at 472 nm and had the chromaticity CIE (x, y) of (0.147, 0.296), indicating that the emission was light emission derived from the metal complex MC6.

Thereafter, the measurement sample FL-6 was allowed to emit light continuously while keeping the regulated excitation light intensity constant, and LT85 thereof was measured. The results are shown in Table 3.

### <Measurement Example 7> Measurement of Light Emission Stability

A measurement sample FL-7 was fabricated in the same manner as in Measurement Example 1, excepting that a metal complex MC7 was used instead of the metal complex MC1 in Measurement Example 1, and light emission stability thereof was measured.

The light emission luminance of the measurement sample FL-7 generating the same photon number as that of light emission of the measurement sample FL-1 was calculated according to the above-described formula (17), thereby finding a value of 2560 cd/m².

The excitation light intensity of an excitation light source was regulated in such a manner that the light emission luminance of the measurement sample FL-7 was 2560 cd/m². Light emission observed from the measurement sample FL-7 showed the emission spectrum peak at 474 nm and had the chromaticity CIE (x, y) of (0.150, 0.315), indicating that the emission was light emission derived from the metal complex MC7.

Thereafter, the measurement sample FL-7 was allowed to emit light continuously while keeping the regulated excitation light intensity constant, and LT85 thereof was measured. The results are shown in Table 3.

### <Measurement Example 8> Measurement of Light Emission Stability

A measurement sample FL-8 was fabricated in the same manner as in Measurement Example 1, excepting that a metal complex MC8 was used instead of the metal complex MC1 in Measurement Example 1, and light emission stability thereof was measured.

The light emission luminance of the measurement sample FL-8 generating the same photon number as that of light emission of the measurement sample FL-1 was calculated according to the above-described formula (17), thereby finding a value of 2480 cd/m².

The excitation light intensity of an excitation light source was regulated in such a manner that the light emission luminance of the measurement sample FL-8 was 2480 cd/m². Light emission observed from the measurement sample FL-8 showed the emission spectrum peak at 472 nm and had the chromaticity CIE (x, y) of (0.150, 0.300), indicating that the emission was light emission derived from the metal complex MC3.

Thereafter, the measurement sample FL-8 was allowed to emit light continuously while keeping the regulated excitation light intensity constant, and LT85 thereof was measured. The results are shown in Table 3.

### <Measurement Example 9> Measurement of Light Emission Stability

A measurement sample FL-9 was fabricated in the same manner as in Measurement Example 1, excepting that a metal complex MC9 was used instead of the metal complex MC1 in Measurement Example 1, and light emission stability thereof was measured.

The light emission luminance of the measurement sample FL-9 generating the same photon number as that of light emission of the measurement sample FL-1 was calculated according to the above-described formula (17), thereby finding a value of 1890 cd/m².

The excitation light intensity of an excitation light source was regulated in such a manner that the light emission luminance of the measurement sample FL-9 was 1890 cd/m². Light emission observed from the measurement sample FL-9 showed the emission spectrum peak at 454 nm and had the chromaticity CIE (x, y) of (0.149, 0.190), indicating that the emission was light emission derived from the metal complex MC9.

Thereafter, the measurement sample FL-9 was allowed to emit light continuously while keeping the regulated excitation light intensity constant, and LT85 thereof was measured. The results are shown in Table 3.

### <Measurement Example 10> Measurement of Light Emission Stability

A measurement sample FL-10 was fabricated in the same manner as in Measurement Example 1, excepting that a metal complex MC10 was used instead of the metal complex MC1 in Measurement Example 1, and light emission stability thereof was measured.

The light emission luminance of the measurement sample FL-10 generating the same photon number as that of light emission of the measurement sample FL-1 was calculated according to the above-described formula (17), thereby finding a value of 2530 cd/m².

The excitation light intensity of an excitation light source was regulated in such a manner that the light emission luminance of the measurement sample FL-10 was 2530 cd/m². Light emission observed from the measurement sample FL-10 showed the emission spectrum peak at 473 nm and had the chromaticity CIE (x, y) of (0.149, 0.309), indicating that the emission was light emission derived from the metal complex MC10.

Thereafter, the measurement sample FL-10 was allowed to emit light continuously while keeping the regulated excitation light intensity constant, and LT85 thereof was measured. The results are shown in Table 3.

### <Measurement Example 11> Measurement of Light Emission Stability

A measurement sample FL-11 was fabricated in the same manner as in Measurement Example 1, excepting that a metal complex MC12 was used instead of the metal complex MC1 in Measurement Example 1, and light emission stability thereof was measured.

The light emission luminance of the measurement sample FL-11 generating the same photon number as that of light emission of the measurement sample FL-1 was calculated according to the above-described formula (17), thereby finding a value of 1950 cd/m².

The excitation light intensity of an excitation light source was regulated in such a manner that the light emission luminance of the measurement sample FL-11 was 1950 cd/m². Light emission observed from the measurement sample FL-11 showed the emission spectrum peak at 455 nm and had the chromaticity CIE (x, y) of (0.157, 0.199), indicating that the emission was light emission derived from the metal complex MC12.

Thereafter, the measurement sample FL-11 was allowed to emit light continuously while keeping the regulated excitation light intensity constant, and LT85 thereof was measured. The results are shown in Table 3.

### <Measurement Example 12> Measurement of Light Emission Stability

A measurement sample FL-12 was fabricated in the same manner as in Measurement Example 1, excepting that a metal complex MC13 was used instead of the metal complex MC1 in Measurement Example 1, and light emission stability thereof was measured.

The light emission luminance of the measurement sample FL-12 generating the same photon number as that of light emission of the measurement sample FL-1 was calculated according to the above-described formula (17), thereby finding a value of 1870 cd/m².

The excitation light intensity of an excitation light source was regulated in such a manner that the light emission luminance of the measurement sample FL-12 was 1870 cd/m². Light emission observed from the measurement sample FL-12 showed the emission spectrum peak at 456 nm and had the chromaticity CIE (x, y) of (0.148, 0.192), indicating that the emission was light emission derived from the metal complex MC13.

Thereafter, the measurement sample FL-12 was allowed to emit light continuously while keeping the regulated excitation light intensity constant, and LT85 thereof was measured. The results are shown in Table 3.

### <Measurement Example 13> Measurement of Light Emission Stability

A measurement sample FL-13 was fabricated in the same manner as in Measurement Example 1, excepting that a metal complex MC14 was used instead of the metal complex MC1 in Measurement Example 1, and light emission stability thereof was measured.

The light emission luminance of the measurement sample FL-13 generating the same photon number as that of light emission of the measurement sample FL-1 was calculated according to the above-described formula (17), thereby finding a value of 1910 cd/m².

The excitation light intensity of an excitation light source was regulated in such a manner that the light emission luminance of the measurement sample FL-13 was 1910 cd/m². Light emission observed from the measurement sample FL-13 showed the emission spectrum peak at 455 nm and had the chromaticity CIE (x, y) of (0.148, 0.196), indicating that the emission was light emission derived from the metal complex MC14.

Thereafter, the measurement sample FL-13 was allowed to emit light continuously while keeping the regulated excitation light intensity constant, and LT85 thereof was measured. The results are shown in Table 3.

### <Comparative Measurement Example 1> Measurement of Light Emission Stability

A measurement sample CFL-1 was fabricated in the same manner as in Measurement Example 1, excepting that a metal complex MM1 was used instead of the metal complex MC1 in Measurement Example 1, and light emission stability thereof was measured.

The light emission luminance of the measurement sample CFL-1 generating the same photon number as that of light emission of the measurement sample FL-1 was calculated according to the above-described formula (17), thereby finding a value of 1980 cd/m².

The excitation light intensity of an excitation light source was regulated in such a manner that the light emission luminance of the measurement sample CFL-1 was 1980 cd/m². Light emission observed from the measurement sample CFL-1 showed the emission spectrum peak at 461 nm and had the chromaticity CIE (x, y) of (0.146, 0.203), indicating that the emission was light emission derived from the metal complex MM1.

Thereafter, the measurement sample CFL-1 was allowed to emit light continuously while keeping the regulated excitation light intensity constant, and LT85 thereof was measured. The results are shown in Table 3.

### <Comparative Measurement Example 2> Measurement of Light Emission Stability

A measurement sample CFL-2 was fabricated in the same manner as in Measurement Example 1, excepting that a metal complex MM2 was used instead of the metal complex MC1 in Measurement Example 1, and light emission stability thereof was measured.

The light emission luminance of the measurement sample CFL-2 generating the same photon number as that of light emission of the measurement sample FL-1 was calculated according to the above-described formula (17), thereby finding a value of 2490 cd/m².

The excitation light intensity of an excitation light source was regulated in such a manner that the light emission luminance of the measurement sample CFL-2 was 2490 cd/m². Light emission observed from the measurement sample CFL-2 showed the emission spectrum peak at 474 nm and had the chromaticity CIE (x, y) of (0.149, 0.299), indicating that the emission was light emission derived from the metal complex MM2.

Thereafter, the measurement sample CFL-2 was allowed to emit light continuously while keeping the regulated excitation light intensity constant, and LT85 thereof was measured. The results are shown in Table 3.

### <Comparative Measurement Example 3> Measurement of Light Emission Stability

A measurement sample CFL-3 was fabricated in the same manner as in Measurement Example 1, excepting that a metal complex MM3 was used instead of the metal complex MC1 in Measurement Example 1, and light emission stability thereof was measured.

The light emission luminance of the measurement sample CFL-3 generating the same photon number as that of light emission of the measurement sample FL-1 was calculated according to the above-described formula (17), thereby finding a value of 2070 cd/m².

The excitation light intensity of an excitation light source was regulated in such a manner that the light emission luminance of the measurement sample CFL-3 was 2070 cd/m². Light emission observed from the measurement sample CFL-3 showed the emission spectrum peak at 455 nm and had the chromaticity CIE (x, y) of (0.153, 0.214), indicating that the emission was light emission derived from the metal complex MM3.

Thereafter, the measurement sample CFL-3 was allowed to emit light continuously while keeping the regulated excitation light intensity constant, and LT85 thereof was measured. The results are shown in Table 3.

### <Measurement Example 14> Measurement of Light Emission Stability

A measurement sample FL-14 was fabricated in the same manner as in Measurement Example 1, excepting that a metal complex MC11 was used instead of the metal complex MC1 in Measurement Example 1, and light emission stability thereof was measured.

The excitation light intensity of an excitation light source was regulated so that the light emission luminance of the measurement sample FL-14 was 430 cd/m². Light emission observed from the measurement sample FL-14 showed the emission spectrum peak at 480 nm and had the chromaticity CIE (x, y) of (0.164, 0.300), indicating that the emission was light emission derived from the metal complex MC11.

Thereafter, the measurement sample FL-14 was allowed to emit light continuously while keeping the regulated excitation light intensity constant, and LT85 thereof was measured. The results are shown in Table 4.

### <Comparative Measurement Example 4> Measurement of Light Emission Stability

A measurement sample CFL-4 was fabricated in the same manner as in Measurement Example 1, excepting that a metal complex MM3 was used instead of the metal complex MC1 in Measurement Example 1, and light emission stability thereof was measured.

The light emission luminance of the measurement sample CFL-4 generating the same photon number as that of light emission of the measurement sample FL-14 was calculated according to the above-described formula (17), thereby finding a value of 430 cd/m².

The excitation light intensity of an excitation light source was regulated in such a manner that the light emission luminance of the measurement sample CFL-4 was 430 cd/m². Light emission observed from the measurement sample CFL-4 showed the emission spectrum peak at 455 nm and had the chromaticity CIE (x, y) of (0.153, 0.214), indicating that the emission was light emission derived from the metal complex MM3.

Thereafter, the measurement sample CFL-4 was allowed to emit light continuously while keeping the regulated excitation light intensity constant, and LT85 thereof was measured. The results are shown in Table 4.

### <Measurement Example 15> Measurement of Light Emission Stability

A measurement sample FL-15 was fabricated in the same manner as in Measurement Example 1, excepting that a metal complex MC6 and a polymer compound P1 were used instead of the metal complex MC1 and the compound H-113 in Measurement Example 1, and light emission stability thereof was measured.

The excitation light intensity of an excitation light source was regulated in such a manner that the light emission luminance of the measurement sample FL-15 was 2460 cd/m². Light emission observed from the measurement sample FL-15 showed the emission spectrum peak at 472 nm and had the chromaticity CIE (x, y) of (0.143, 0.265), indicating that the emission was light emission derived from the metal complex MC6.

Thereafter, the measurement sample FL-15 was allowed to emit light continuously while keeping the regulated excitation light intensity constant, and LT85 thereof was measured. The results are shown in Table 5.

### <Comparative Measurement Example 5> Measurement of Light Emission Stability

A measurement sample CFL-5 was fabricated in the same manner as in Measurement Example 1, excepting that a metal complex MM2 and a polymer compound P1 were used instead of the metal complex MC1 and the compound H-113 in Measurement Example 1, and light emission stability thereof was measured.

The light emission luminance of the measurement sample CFL-5 generating the same photon number as that of light emission of the measurement sample FL-15 was calculated according to the above-described formula (17), thereby finding a value of 2490 cd/m².

The excitation light intensity of an excitation light source was regulated in such a manner that the light emission luminance of the measurement sample CFL-5 was 2490 cd/m². Light emission observed from the measurement sample CFL-5 showed the emission spectrum peak at 474 nm and had the chromaticity CIE (x, y) of (0.147, 0.271), indicating that the emission was light emission derived from the metal complex MM2.

Thereafter, the measurement sample CFL-5 was allowed to emit light continuously while keeping the regulated excitation light intensity constant, and LT85 thereof was measured. The results are shown in Table 5.

TABLE 3

| | | | | | | light | | |
|---|---|---|---|---|---|---|---|---|
| | | | low | | | emission | | |
| | | | molecular | | | peak | chromaticity | |
| measurement | metal | weight | weight | weight | LT85 | wavelength | coordinate | |
| sample | complex | [%] | host | [%] | [hr] | [nm] | CIE (x, y) | |
| FL-1 | MC1 | 25 | compound | 75 | 10.5 | 462 | (0.150, | example |
| | | | H-113 | | | | 0.224) | |
| FL-2 | MC2 | 25 | compound | 75 | 8.88 | 466 | (0.154, | example |
| | | | H-113 | | | | 0.251) | |
| FL-3 | MC3 | 25 | compound | 75 | 29.0 | 473 | (0.150, | example |
| | | | H-113 | | | | 0.315) | |
| FL-4 | MC4 | 25 | compound | 75 | 6.27 | 455 | (0.149, | example |
| | | | H-113 | | | | 0.204) | |
| FL-5 | MC5 | 25 | compound | 75 | 8.90 | 464 | (0.150, | example |
| | | | H-113 | | | | 0.253) | |
| FL-6 | MC6 | 25 | compound | 75 | 29.7 | 472 | (0.147, | example |
| | | | H-113 | | | | 0.296) | |
| FL-7 | MC7 | 25 | compound | 75 | 13.8 | 474 | (0.150, | example |
| | | | H-113 | | | | 0.315) | |
| FL-8 | MC8 | 25 | compound | 75 | 5.27 | 472 | (0.150, | example |
| | | | H-113 | | | | 0.300) | |
| FL-9 | MC9 | 25 | compound | 75 | 4.78 | 454 | (0.149, | example |
| | | | H-113 | | | | 0.190) | |
| FL-10 | MC10 | 25 | compound | 75 | 27.2 | 473 | (0.149, | example |
| | | | H-113 | | | | 0.309) | |
| FL-11 | MC12 | 25 | compound | 75 | 2.23 | 455 | (0.157, | example |
| | | | H-113 | | | | 0.199) | |
| FL-12 | MC13 | 25 | compound | 75 | 5.79 | 456 | (0.146, | example |
| | | | H-113 | | | | 0.192) | |
| FL-13 | MC14 | 25 | compound | 75 | 3.38 | 455 | (0.148, | example |
| | | | H-113 | | | | 0.196) | |
| CFL-1 | MM1 | 25 | compound | 75 | 0.97 | 461 | (0.146, | comparative |
| | | | H-113 | | | | 0.203) | example |
| CFL-2 | MM2 | 25 | compound | 75 | 1.46 | 474 | (0.149, | comparative |
| | | | H-113 | | | | 0.299) | example |
| CFL-3 | MM3 | 25 | compound | 75 | 0.05 | 455 | (0.153, | comparative |
| | | | H-113 | | | | 0.214) | example |

TABLE 4

| | | | | | | light | | |
|---|---|---|---|---|---|---|---|---|
| | | | low | | | emission | | |
| | | | molecular | | | peak | chromaticity | |
| measurement | metal | weight | weight | weight | LT85 | wavelength | coordinate | |
| sample | complex | [%] | host | [%] | [hr] | [nm] | CIE (x, y) | |
| FL-14 | MC11 | 25 | compound | 75 | 23.3 | 480 | (0.164, | example |
| | | | H-113 | | | | 0.300) | |
| CFL-4 | MM3 | 25 | compound | 75 | 1.26 | 455 | (0.153, | Comparative |
| | | | H-113 | | | | 0.214) | example |

TABLE 5

| | | | | | | light | | |
|---|---|---|---|---|---|---|---|---|
| | | | | | | emission | | |
| | | | | | | peak | chromaticity | |
| measurement | metal | weight | polymer | weight | LT85 | wavelength | coordinate | |
| sample | complex | [%] | host | [%] | [hr] | [nm] | CIE (x, y) | |
| FL-15 | MC6 | 25 | P1 | 75 | 0.44 | 472 | (0.143, | example |
| | | | | | | | 0.265) | |
| CFL-5 | MM2 | 25 | P1 | 75 | 0.11 | 474 | (0.147, | Comparative |
| | | | | | | | 0.271) | example |

It is understood from these results that the metal complexes of the present invention (the metal complex MC1, the metal complex MC2, the metal complex MC3, the metal complex MC4, the metal complex MC5, the metal complex MC6, the metal complex MC7, the metal complex MC8, the metal complex MC9, the metal complex MC10, the metal complex MC11, the metal complex MC12, the metal complex MC13 and the metal complex MC14) are excellent in light emission stability as compared with the metal complex MM1, the metal complex MM2 and the metal complex MM3.

### INDUSTRIAL APPLICABILITY

According to the present invention, a metal complex excellent in light emission stability can be provided. Further, according to the present invention, a composition comprising the metal complex and a light emitting device produced by using the metal complex can be provided. A light emitting device obtained by using the metal complex has excellent luminance life because the metal complex of the present invention is excellent in light emission stability.

1. A metal complex represented by the following formula (1): 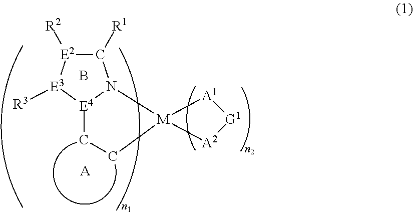
wherein
M represents an iridium atom or a platinum atom,
n₁ represents 1, 2 or 3, n₂ represents 0, 1 or 2, and n₁+n₂ is 3 when M is an iridium atom, while n₁+n₂ is 2 when M is a platinum atom,
E², E³ and E⁴ each independently represent a nitrogen atom or a carbon atom, and when a plurality of E², E³ and E⁴ are present, they may be the same or different at each occurrence, and R² and R³ may be either present or not present when E² and E³ are nitrogen atoms, and two selected from the group consisting of E², E³ and E⁴ are nitrogen atoms, and the remaining one is a carbon atom,
R¹ represents an aryl group or a monovalent heterocyclic group and these groups each optionally have a substituent, and when a plurality of R¹ are present, they may be the same or different,
R² and R³ each independently represent a hydrogen atom, an alkyl group, a cycloalkyl group, an alkoxy group, a cycloalkoxy group, an aryl group, an aryloxy group, a monovalent heterocyclic group or a halogen atom and these groups each optionally have a substituent, and when a plurality of R² and R³ are present, they may be the same or different at each occurrence,
the ring B represents a triazole ring,
the ring A represents an aromatic hydrocarbon ring or an aromatic heterocyclic ring and these rings optionally have a substituent, and
A¹-G¹-A² represents an anionic bidentate ligand, A¹ and A² each independently represent a carbon atom, an oxygen atom or a nitrogen atom and these atoms each may be an atom constituting a ring, G¹ represents a single bond or an atomic group constituting the bidentate ligand together with A¹ and A², and when a plurality of A¹-G¹-A² are present, they may be the same or different.

2. The metal complex according to claim 1 represented by the following formula (1-a): 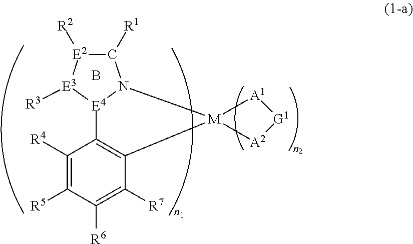
wherein
M, n₁, n₂, E², E³, E⁴, R¹, R², R³, the ring B and A¹-G¹-A² represent the same meaning as described above, and
R⁴, R⁵, R⁶ and R⁷ each independently represent a hydrogen atom, an alkyl group, a cycloalkyl group, an alkoxy group, a cycloalkoxy group, an aryl group, an aryloxy group, a monovalent heterocyclic group or a halogen atom and these groups each optionally have a substituent, and when a plurality of R⁴, R⁵, R⁶ and R⁷ are present, they may be the same or different at each occurrence, and R⁴ and R⁵ may be combined together to form a ring together with the carbon atoms to which they are attached, R⁵ and R⁶ may be combined together to form a ring together with the carbon atoms to which they are attached, and R⁶ and R⁷ may be combined together to form a ring together with the carbon atoms to which they are attached.

3. The metal complex according to claim 2 represented by the following formula (1-b): 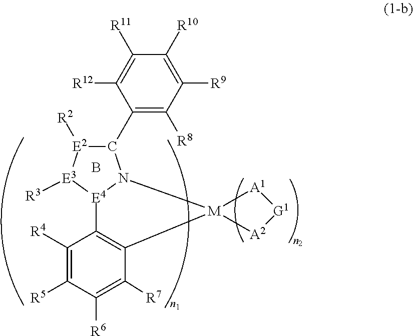
wherein
M, n₁, n₂, E², E³, E⁴, R², R³, R⁴, R⁵, R⁶, R⁷, the ring B and A¹-G¹-A² represent the same meaning as described above, and
R⁸, R⁹, R¹⁰, R¹¹ and R¹² each independently represent a hydrogen atom, an alkyl group, a cycloalkyl group, an alkoxy group, a cycloalkoxy group, an aryl group, an aryloxy group, a monovalent heterocyclic group or a halogen atom and these groups each optionally have a substituent, and when a plurality of R⁸, R⁹, R¹⁰, R¹¹ and R¹² are present, they may be the same or different at each occurrence, and R⁸ and R⁹ may be combined together to form a ring together with the carbon atoms to which they are attached, R⁹ and R¹⁰ may be combined together to form a ring together with the carbon atoms to which they are attached, R¹⁰ and R¹¹ may be combined together to form a ring together with the carbon atoms to which they are attached, and R¹¹ and R¹² may be combined together to form a ring together with the carbon atoms to which they are attached.

4. The metal complex according to claim 3 represented by the following formula (1-c): 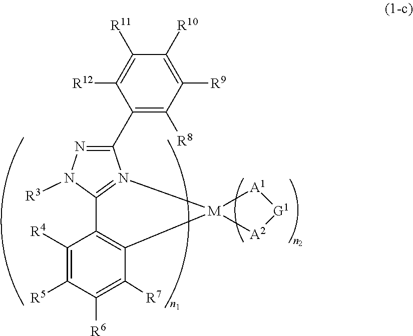
wherein M, n₁, n₂, R³, R⁴, R⁵, R⁶, R⁷, R⁸, R⁹, R¹⁰, R¹¹, R¹² and A¹-G¹-A² represent the same meaning as described above.

5. The metal complex according to claim 3 represented by the following formula (1-d): 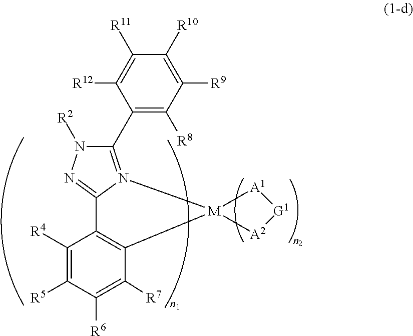
wherein M, n₁, n₂, R², R⁴, R⁵, R⁶, R⁷, R⁸, R⁹, R¹⁰, R¹¹, R¹² and A¹-G¹-A² represent the same meaning as described above.

6. The metal complex according to claim 4 represented by the following formula (1-e): 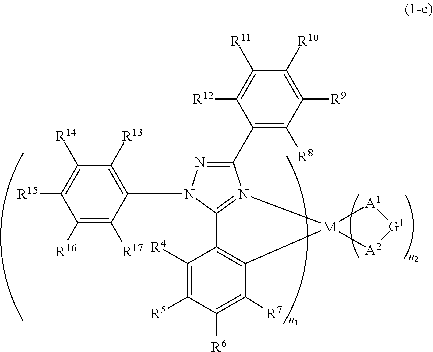
wherein
M, n₁, n₂, R⁴, R⁵, R⁶, R⁷, R⁸, R⁹, R¹⁰, R¹¹, R¹² and A¹-G¹-A² represent the same meaning as described above, and
R¹³, R¹⁴, R¹⁵, R¹⁶ and R¹⁷ each independently represent a hydrogen atom, an alkyl group, a cycloalkyl group, an alkoxy group, a cycloalkoxy group, an aryl group, an aryloxy group, a monovalent heterocyclic group or a halogen atom and these groups each optionally have a substituent, and when a plurality of R¹³, R¹⁴, R¹⁵, R¹⁶ and R¹⁷ are present, they may be the same or different at each occurrence, and R¹³ and R¹⁴ may be combined together to form a ring together with the carbon atoms to which they are attached, R¹⁴ and R¹⁵ may be combined together to form a ring together with the carbon atoms to which they are attached, R¹⁵ and R¹⁶ may be combined together to form a ring together with the carbon atoms to which they are attached, and R¹⁶ and R¹⁷ may be combined together to form a ring together with the carbon atoms to which they are attached.

7. The metal complex according to claim 3, wherein R⁹ and R¹¹ represent an alkyl group or an aryl group.

8. The metal complex according to claim 1, wherein at least one selected from the group consisting of R¹, R², R³, R⁵, R⁶, R¹⁰ and R¹⁵ is a dendron.

9. The metal complex according to claim 8, wherein at least one selected from the group consisting of R¹, R², R³, R⁵, R⁶, R¹⁰ and R¹⁵ is a group represented by the following formula (D-A) or (D-B): 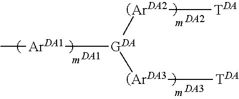
wherein
m^{DA1}, m^{DA2} and m^{DA3} each independently represent an integer of 0 or more,
G^{DA} represents an aromatic hydrocarbon group or a heterocyclic group and these groups each optionally have a substituent,
Ar^{DA1}, A^{DA2} and Ar^{DA3} each independently represent an arylene group or a divalent heterocyclic group and these groups each optionally have a substituent, and when a plurality of Ar^{DA1}, Ar^{DA2} and Ar^{DA3} are present, they may be the same or different at each occurrence, and
T^{DA} represents an aryl group or a monovalent heterocyclic group and these groups each optionally have a substituent, and the plurality of T^{DA} may be the same or different: 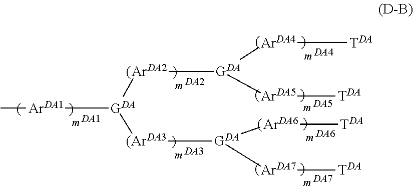
wherein
m^{DA1}, m^{DA2}, m^{DA3}, m^{DA4}, m^{DA5}, m^{DA6} and m^{DA7} each independently represent an integer of 0 or more,
G^{DA} represents an aromatic hydrocarbon group or a heterocyclic group and these groups each optionally have a substituent, and the plurality of G^{DA} may be the same or different,
Ar^{DA1}, Ar^{DA2}, Ar^{DA3}, Ar^{DA4}, Ar^{DA5}, Ar^{DA6} and Ar^{DA7} each independently represent an arylene group or a divalent heterocyclic group and these groups each optionally have a substituent, and when a plurality of Ar^{DA1}, Ar^{DA2}, Ar^{DA3}, Ar^{DA4}, Ar^{DA5}, Ar^{DA6} and Ar^{DA7} are present, they may be the same or different at each occurrence, and
T^{DA} represents an aryl group or a monovalent heterocyclic group and these groups each optionally have a substituent, and the plurality of T^{DA} may be the same or different.

10. The metal complex according to claim 9, wherein the group represented by the formula (D-A) is a group represented by the following formula (D-A1), (D-A2) or (D-A3): 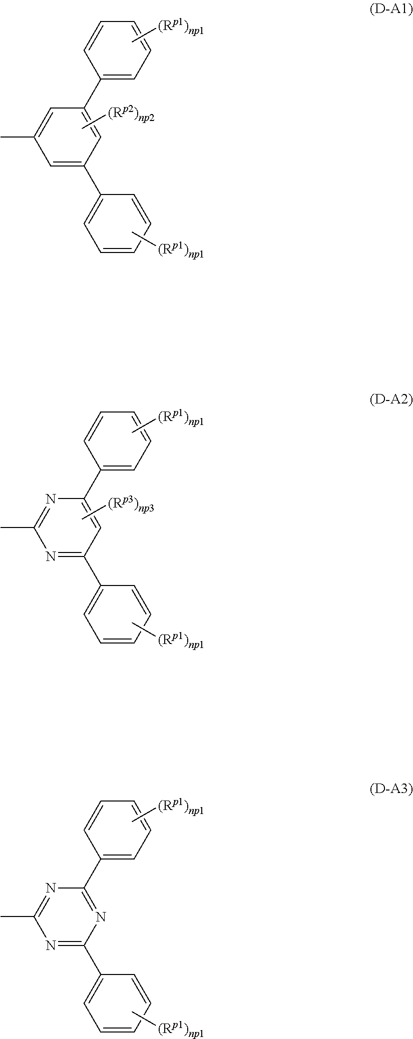
wherein
R^{p1}, R^{p2} and R^{p3} each independently represent an alkyl group, a cycloalkyl group or a halogen atom, and when a plurality of R^{p1} and R^{p2} are present, they may be the same or different at each occurrence, and at least one selected from among the plurality of R^{p1} is an alkyl group having 4 or more carbon atoms, and
np1 represents an integer of 1 to 5, np2 represents an integer of 0 to 3, and np3 represents 0 or 1, and the plurality of np1 may be the same or different.

11. The metal complex according to claim 10, wherein the group represented by the formula (D-A) is a group represented by the formula (D-A1).

12. The metal complex according to claim 1, wherein M is an iridium atom.

13. The metal complex according to claim 12, wherein n₁ is 3.

14. A composition comprising
the metal complex according claim 1 and
a compound represented by the following formula (H-1): 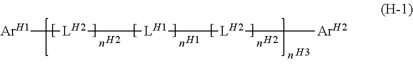
wherein
Ar^{H1} and Ar^{H2} each independently represent an aryl group or a monovalent heterocyclic group and these groups each optionally have a substituent,
n^{H1} and n^{H2} each independently represent 0 or 1, and when a plurality of n^{H1} are present, they may be the same or different, and the plurality of n^{H2} may be the same or different,
n^{H3} represents an integer of 0 or more,
L^{H1} represents an arylene group, a divalent heterocyclic group or a group represented by —[C(R^{H11})₂]n^{H11}-, and these groups each optionally have a substituent, and when a plurality of L^{H1} are present, they may be the same or different,
n^{H11} represents an integer of 1 to 10, and R^{H11} represents a hydrogen atom, an alkyl group, a cycloalkyl group, an alkoxy group, a cycloalkoxy group, an aryl group or a monovalent heterocyclic group and these groups each optionally have a substituent, and the plurality of R^{H11} may be the same or different and may be combined together to form a ring together with the carbon atoms to which they are attached,
L^{H2} represents a group represented by —N(-L^{H21}-R^{H21})—, and when a plurality of L^{H2} are present, they may be the same or different, and
L^{H21} represents a single bond, an arylene group or a divalent heterocyclic group and these groups each optionally have a substituent, and R^{H21} represents a hydrogen atom, an alkyl group, a cycloalkyl group, an aryl group or a monovalent heterocyclic group and these groups each optionally has a substituent.

15. A composition comprising
the metal complex according to claim 1 and
a polymer compound comprising a constitutional unit represented by the following formula (Y): 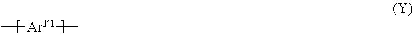
wherein Ar^{Y1} represents an arylene group, a divalent heterocyclic group or a divalent group in which at least one arylene group and at least one divalent heterocyclic group are bonded directly to each other, and these groups each optionally have a substituent.

16. A composition comprising
the metal complex according to claim 1 and
at least one material selected from the group consisting of a hole transporting material, a hole injection material, an electron transporting material, an electron injection material, a light emitting material, an antioxidant and a solvent.

17. A light emitting device produced by using the metal complex according to claim 1.
